(19) United States
(12) Patent Application Publication
(10) Pub. No.: US 2026/0282442 A1
(43) Pub. Date: Sep. 17, 2026

(54) SEMICONDUCTOR DEVICE AND METHOD FOR MANUFACTURING THE SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Masahiro WAKUDA, Isehara (JP); Naoto YAMADE, Isehara (JP); Tsutomu MURAKAWA, Isehara (JP); Hitoshi KUNITAKE, Machida (JP); Tomonori NAKAYAMA, Atsugi (JP)

(21) Appl. No.: 19/168,549

(22) PCT Filed: Apr. 1, 2024
(86) PCT No.: PCT/IB2024/053141

§ 371 Date: Sep. 24, 2025

(30) Foreign Application Priority Data
Apr. 7, 2023 (JP) 2023-062697

(51) Int. Cl. H10D 30/67; H10D 30/01; H10P 30/20

(52) U.S. Cl. CPC H10D 30/6728; H10D 30/025; H10D 30/6755; H10P 30/222

(57) ABSTRACT

A semiconductor device that can be miniaturized or highly integrated is provided. The semiconductor device includes a transistor and an insulator; the insulator is provided over one of a source and a drain of the transistor; the other of the source and the drain of the transistor is provided over the insulator; an opening portion reaching one of the source and the drain is provided in the insulator and the other of the source and the drain; an oxide semiconductor included in the transistor is in contact with a top surface of one of the source and the drain, a side surface of the insulator, and a side surface of the other of the source and the drain that are in the opening portion; a gate insulator of the transistor is provided over the oxide semiconductor; a gate of the transistor is provided over the gate insulator; the oxide semiconductor includes a first region in contact with one of the source and the drain, a second region in contact with the insulator, and a third region in contact with the other of the source and the drain; the first and third regions have lower resistance than the second region; and the second region has a lower potential than the first and third regions.

### TECHNICAL FIELD

One embodiment of the present invention relates to a semiconductor device, a memory device, and an electronic appliance. Another embodiment of the present invention relates to a method for manufacturing the semiconductor device.

Note that one embodiment of the present invention is not limited to the above technical field. Examples of the technical field of one embodiment of the present invention include a semiconductor device, a display device, a light-emitting device, a power storage device, a memory device, a lighting device, an input device (e.g., a touch sensor), an input/output device (e.g., a touch panel), an electronic appliance including any of them, a method for driving any of them, and a method for manufacturing any of them.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (e.g., a liquid crystal display device and a light-emitting display device), a projection device, a lighting device, an electro-optical device, a power storage device, a memory device, a semiconductor circuit, an imaging device, an electronic appliance, and the like include a semiconductor device.

### BACKGROUND ART

In recent years, semiconductor devices have been developed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a material of a semiconductor thin film that can be used for the transistor, and an oxide semiconductor has been attracting attention as another material.

It is known that a transistor using an oxide semiconductor has extremely low leakage current in an non-conduction state. For example, Patent Document 1 discloses a low-power-consumption CPU utilizing a feature of low leakage current of the transistor using an oxide semiconductor. Furthermore, for example, Patent Document 2 discloses a memory device that can retain stored contents for a long time by utilizing a feature of low leakage current of the transistor using an oxide semiconductor.

In recent years, demand for an integrated circuit with higher density has risen with reductions in size and weight of electronic appliances. In addition, the productivity of a semiconductor device including an integrated circuit is desired to be increased. For example, Patent Document 3 and Non-Patent Document 1 each disclose a technique to achieve an integrated circuit with higher density by making a plurality of memory cells overlap with each other by stacking a first transistor using an oxide semiconductor film and a second transistor using an oxide semiconductor film. Furthermore, for example, Patent Document 4 discloses a technique for achieving an integrated circuit with a higher density by placing a channel of a transistor using an oxide semiconductor film in the vertical direction.

### REFERENCE

### Patent Document

[Patent Document 1] Japanese Published Patent Application No. 2012-257187

[Patent Document 2] Japanese Published Patent Application No. 2011-151383

[Patent Document 3] PCT International Publication No. 2021/053473

[Patent Document 4] Japanese Published Patent Application No. 2013-211537

### Non-Patent Document

[Non-Patent Document 1] M. Oota et. al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be miniaturized or highly integrated and a method for manufacturing a semiconductor device. Another object of one embodiment of the present invention is to provide a semiconductor device with high on-state current and a method for manufacturing a semiconductor device. Another object of one embodiment of the present invention is to provide a semiconductor device that operates at high speed and a method for manufacturing a semiconductor device. Another object of one embodiment of the present invention is to provide a semiconductor device with high reliability and a method for manufacturing a semiconductor device. Another object of one embodiment of the present invention is to provide a semiconductor device with favorable electrical characteristics and a method for manufacturing a semiconductor device. Another object of one embodiment of the present invention is to provide a semiconductor device with a small variation in electrical characteristics of transistors and a method for manufacturing a semiconductor device. Another object of one embodiment of the present invention is to provide a semiconductor device with low power consumption and a method for manufacturing a semiconductor device. Another object of one embodiment of the present invention is to provide a novel semiconductor device and a method for manufacturing a semiconductor device. Another object of one embodiment of the present invention is to provide a method for manufacturing a semiconductor device with high productivity.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a transistor and an insulator; the transistor includes a first electrode, a second electrode, an oxide semiconductor, a gate insulator, and a gate electrode; the first electrode has a function of one of a source electrode and a drain electrode; the second electrode has a function of the other of the source electrode and the drain electrode; the first electrode and the second electrode are provided at different levels; the insulator is provided over the first electrode; the second electrode is provided over the insulator; an opening portion reaching the first electrode is provided in the insulator and the second electrode; the oxide semiconductor is provided in contact with a top surface of the first electrode in the opening portion, a side surface of the insulator in the opening portion, and a side surface of the second electrode in the opening portion; the gate insulator is provided over the oxide semiconductor; the gate electrode is provided over the gate insulator to fill the opening portion; the oxide semiconductor includes a first region in contact with the first electrode, a second region in contact with the insulator, and a third region in contact with the second electrode; the first region and the third region have lower resistance than the second region; the second region includes a halogen element; and the transistor has a threshold voltage higher than 0 V.

In the above, the halogen element is preferably one or more selected from chlorine, fluorine, bromine, and iodine.

In the above, the halogen element is preferably chlorine or fluorine.

In the above, the first region and the third region preferably contain a higher concentration of one or more of hydrogen, boron, carbon, nitrogen, phosphorus, sulfur, arsenic, aluminum, magnesium, silicon, and a noble gas than the second region.

In the above, the insulator preferably includes silicon and oxygen.

Another embodiment of the present invention is a method for manufacturing a semiconductor device, the method including the following steps: forming a first conductor; forming a first insulator over the first conductor; forming a first conductive film over the first insulator; processing the first conductive film and the first insulator to form a second conductor and an opening portion reaching the first conductor; forming an oxide semiconductor film in contact with a top surface of the first conductor in the opening portion, a side surface of the first insulator in the opening portion, and a side surface of the second conductor in the opening portion; and performing treatment for supplying chlorine or fluorine to a first region of the oxide semiconductor film, the first region being in contact with the side surface of the first insulator in the opening portion.

In the above, the treatment for supplying chlorine or fluorine is preferably performed by an ion implantation method in a state where the semiconductor device under manufacturing is inclined at an angle greater than or equal to 15° and less than or equal to 80° with one point in a substrate plane as a supporting point.

In the above, after the treatment for supplying chlorine or fluorine, heat treatment is preferably performed at higher than or equal to 250° C. and lower than or equal to 650° C.

In the above, it is preferable that the oxide semiconductor film be processed after the treatment for supplying chlorine or fluorine to form an oxide semiconductor, the second conductor be processed to form a third conductor, a second insulator be formed over the oxide semiconductor, and treatment for supplying one or more of hydrogen, boron, carbon, nitrogen, fluorine, phosphorus, sulfur, arsenic, aluminum, magnesium, silicon, and a noble gas to a second region and a third region of the oxide semiconductor, the second region being in contact with the first conductor in the opening portion, the third region being in contact with the third conductor outside the opening portion through the second insulator be performed.

### Effect of the Invention

One embodiment of the present invention can provide a semiconductor device that can be miniaturized or highly integrated and a method for manufacturing the semiconductor device. Another embodiment of the present invention can provide a semiconductor device with high on-state current and a method for manufacturing the semiconductor device. Another embodiment of the present invention can provide a semiconductor device that operates at high speed and a method for manufacturing the semiconductor device. Another embodiment of the present invention can provide a semiconductor device with high reliability and a method for manufacturing the semiconductor device. Another embodiment of the present invention can provide a semiconductor device with favorable electrical characteristics and a method for manufacturing the semiconductor device. Another embodiment of the present invention can provide a semiconductor device with a small variation in electrical characteristics of transistors and a method for manufacturing the semiconductor device. Another embodiment of the present invention can provide a semiconductor device with low power consumption and a method for manufacturing the semiconductor device. Another embodiment of the present invention can provide a novel semiconductor device and a method for manufacturing the semiconductor device. Another embodiment of the present invention can provide a method for manufacturing a semiconductor device with high productivity.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device. FIG. 1B and FIG. 1C are cross-sectional views illustrating the example of the semiconductor device.

FIG. 2A and FIG. 2B are cross-sectional views illustrating an example of a semiconductor device.

FIG. 3A is a diagram showing potentials applied to regions of a transistor. FIG. 3B and FIG. 3C are graphs showing electrical characteristics of the transistors.

FIG. 4A and FIG. 4B are cross-sectional views illustrating examples of semiconductor devices.

FIG. 5A to FIG. 5C are diagrams each illustrating a band diagram of an oxide semiconductor having a stacked-layer structure.

FIG. 6A and FIG. 6B are cross-sectional views illustrating examples of a semiconductor device.

FIG. 7A is a plan view illustrating an example of a semiconductor device. FIG. 7B to FIG. 7D are cross-sectional views illustrating an example of a semiconductor device.

FIG. 8A is a plan view illustrating an example of a semiconductor device. FIG. 8B is a cross-sectional view illustrating the example of the semiconductor device.

FIG. 9A to FIG. 9C are cross-sectional views illustrating an example of a method for manufacturing a semiconductor device.

FIG. 10A and FIG. 10B are cross-sectional views illustrating an example of a method for manufacturing a semiconductor device.

FIG. 11A and FIG. 11C are schematic cross-sectional views illustrating an example of a method for manufacturing a semiconductor device. FIG. 11B and FIG. 11D are schematic plan views illustrating an example of a method for manufacturing a semiconductor device.

FIG. 12A to FIG. 12C are cross-sectional views illustrating an example of a method for manufacturing a semiconductor device.

FIG. 13A and FIG. 13B are cross-sectional views illustrating an example of a method for manufacturing a semiconductor device.

FIG. 14 is a block diagram illustrating a structure example of a semiconductor device.

FIG. 15A to FIG. 15H are diagrams illustrating examples of circuit structures of memory cells.

FIG. 16A and FIG. 16B are perspective views illustrating structure examples of a semiconductor device.

FIG. 17 is a block diagram illustrating a CPU.

FIG. 18A and FIG. 18B are perspective views of a semiconductor device.

FIG. 19A and FIG. 19B are perspective views of semiconductor devices.

FIG. 20A and FIG. 20B are drawings showing hierarchies of a variety of memory devices.

FIG. 21A and FIG. 21B are diagrams illustrating examples of electronic appliances. FIG. 21C to FIG. 21E are diagrams illustrating examples of a large computer.

FIG. 22 is a diagram illustrating an example of a device for space.

FIG. 23 is a diagram illustrating an example of a storage system that can be used in a data center.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

Furthermore, especially in a plan view, a perspective view, or the like, the description of some components might be omitted for easy understanding of the invention. The description of some hidden lines is also omitted in some cases.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”. The term “conductor” can be interchanged with the term “conductive layer” or the term “conductive film” depending on the case or the circumstances. The term “insulator” can be interchanged with the term “insulating layer” or the term “insulating film” depending on the case or the circumstances. The term “oxide semiconductor” can be interchanged with the term “oxide semiconductor layer” or the term “oxide semiconductor film” depending on the case or the circumstances.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

The term “opening” includes a groove, a slit, and a depressed portion, for example. A region where an opening is formed is referred to as an opening portion in some cases.

In the drawings used in embodiments, a sidewall of an insulator in an opening portion in the insulator is illustrated as being perpendicular or substantially perpendicular to a substrate plane or a formation surface, but the sidewall may have a tapered shape.

Note that in this specification and the like, a tapered shape refers to a shape such that at least part of the side surface of a component is inclined with respect to a substrate plane or a formation surface. For example, the tapered shape refers to a shape including a region where the angle formed between the inclined side surface and the substrate plane or the formation surface (the angle is hereinafter referred to as a taper angle in some cases) is less than 90°. Note that the side surface of the component and the substrate plane are not necessarily completely flat and may be substantially flat with a slight curvature or substantially flat with slight unevenness. In this specification and the like, an inverse tapered shape refers to a shape in which a side portion or an upper portion extends beyond a bottom portion in the direction parallel to a substrate.

Note that in this specification and the like, the expression “level with” indicates a structure having the same level from a reference surface (e.g., a flat surface such as a substrate surface) in a cross-sectional view. For example, in a manufacturing process of a memory device, planarization treatment (typically, chemical mechanical polishing (CMP) treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the surfaces on which the CMP treatment is performed. This case is also regarded as being “level with” in this specification and the like. For example, the expression “level with” includes the case where two layers (here, given as a first layer and a second layer) having different levels with respect to the reference surface are included, and the difference between the top-surface level of the first layer and the top-surface level of the second layer is less than or equal to 20 nm.

Note that in this specification and the like, the expression “side end portions are aligned” means that outlines of stacked layers at least partly overlap with each other in a plan view. For example, the case of processing the upper layer and the lower layer with use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “side end portions are aligned”.

Note that in general, it is difficult to clearly differentiate “perfectly aligned” from “substantially aligned”. Thus, the expression “aligned” includes both “perfectly aligned” and “substantially aligned” in this specification and the like.

Note that in this specification and the like, the expression “the first thickness and the second thickness are equal to each other” means that a value obtained by dividing the absolute value of the difference between the first thickness and the second thickness by the first thickness is less than or equal to 0.1. Alternatively, the expression means that a value obtained by dividing the absolute value of the difference between the first thickness and the second thickness by the second thickness is less than or equal to 0.1.

Note that in this specification and the like, the expression “the distance A and the distance B are equal to each other” means that a value obtained by dividing the absolute value of the difference between the distance A and the distance B by the distance A is less than or equal to 0.1. Alternatively, the expression means that a value obtained by dividing the absolute value of the difference between the distance A and the distance B by the distance B is less than or equal to 0.1.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the term “connection” includes “electrical connection”.

The expression “A and B are electrically connected” means that, in the case where A and B are connected not through an insulator (i.e., A and B are connected through a conductor or a semiconductor or A and B are in contact with each other), transmission and reception of an electric signal or interaction of a potential occurs between A and B at any timing during a circuit operation. In other words, even when there is a timing in which neither transmission and reception of an electric signal nor interaction of a potential occurs between A and B during a circuit operation, the expression “A and B are electrically connected” can be used as long as transmission and reception of an electric signal or interaction of a potential occurs between A and B at another timing.

The term “electrical connection” includes direct connection that is connection not through a circuit element (e.g., a transistor, excluding a wiring) and indirect connection that is connection through at least one circuit element.

Examples where “A and B are electrically connected” include the case where A and B are connected not through a circuit element and the case where A and B are connected through a source and a drain of one or more transistors. Note that it is assumed that transmission and reception of an electric signal or interaction of a potential occurs between A and B at a timing.

Examples where the expression “A and B are electrically connected” cannot be used because A and B are connected through an insulator include the case where a dielectric of a capacitor, a gate insulating film of a transistor, or the like is present between A and B.

Examples where the expression “A and B are electrically connected” cannot be used because neither transmission and reception of an electric signal nor interaction of a potential occurs at any timing between A and B although A and B are connected not through an insulator include the case where a potential V is supplied from a power source, a signal source, or the like to a path from A to B (except for the case where the potential V is supplied through a circuit element), and the case where A and C are connected through a source and a drain of a transistor TrP and B and C are connected through a source and a drain of a transistor TrQ, but there is no timing in which both of the transistor TrP and the transistor TrQ are in an on state at the same time.

### Embodiment 1

In this embodiment, a semiconductor device of one embodiment of the present invention is described with reference to drawings.

The semiconductor device of one embodiment of the present invention includes a transistor. Each of the transistors has a structure in which a source electrode and a drain electrode are stacked at different levels with respect to a substrate plane and drain current flows in a height direction (vertical direction). Thus, these transistors can be miniaturized as compared with a transistor having a structure in which a source electrode and a drain electrode are provided on the same plane. The transistor having the above-described structure enables miniaturization and high integration of the semiconductor device.

The semiconductor device of one embodiment of the present invention includes an insulator between the source electrode and the drain electrode of the transistor. The insulator and one of the source electrode and the drain electrode of the transistor include an opening portion reaching the other of the source electrode and the drain electrode of the transistor in a region that overlaps with the other of the source electrode and the drain electrode of the transistor. An oxide semiconductor is provided as a semiconductor layer in contact with the sidewall and the bottom portion of the opening portion. Although the details are described later, a region of the oxide semiconductor that is sandwiched between the source electrode and the drain electrode of the transistor can function as a channel formation region.

Thus, in the transistor, the distance between the source electrode and the drain electrode can be controlled only by adjusting the thickness of the insulator. In other words, the channel length of the transistor can be controlled. Accordingly, the channel length is not affected by the performance of a light-exposure apparatus used for fabrication of the transistor; thus, the channel length can be smaller than the resolution limit of a light-exposure apparatus, and the transistor can have an extremely short channel length.

Meanwhile, when a transistor has a shorter channel length, the transistor tends to have normally-on characteristics by the influence of a what is called short-channel effect (also referred to as SCE). A transistor with normally-on characteristics has higher off-state current than a transistor with normally-off characteristics. Thus, for example, the use of a transistor with normally-on characteristics in a memory device shortens data retention time and requires a higher refresh frequency, leading to an increase in power consumption.

Thus, in the case where a transistor with an extremely short channel length is fabricated on the assumption of use in a memory device or the like, the transistor needs to be fabricated to have normally-off characteristics.

A method in which a substrate bias effect (also referred to as Body Effect) is used to obtain a transistor with normally-off characteristics is known. Specifically, a transistor with normally-off characteristics can be obtained by providing a back gate electrode (a second gate electrode) that faces a gate electrode (a first gate electrode) with a semiconductor layer therebetween and applying a reverse bias from the back gate electrode to the semiconductor layer. For example, in the case of an n-channel transistor, when drain current (Id)-gate voltage (Vg) characteristics are obtained by sweeping the voltage of the gate electrode (the first gate electrode) while a constant negative bias is applied to the back gate electrode, a threshold voltage can be positively shifted as compared with the case where a negative bias is not applied to the back gate electrode. Hence, the transistor can have normally-off characteristics.

However, in the case where the back gate is formed, the number of fabrication steps of the transistor is increased accordingly. In addition, a power supply for applying a negative bias to the back gate is necessary, and the number of components that come with the semiconductor device increases. Furthermore, application of a negative bias to the back gate leads to an increase in power consumption.

In view of this, in the semiconductor device of one embodiment of the present invention, treatment in which negative charge (negative fixed charge) can be formed in the oxide semiconductor (in particular, the channel formation region) functioning as the semiconductor layer is performed in the fabrication process of the transistor. For example, treatment in which a halogen element such as chlorine or fluorine is added to the oxide semiconductor (in particular, the channel formation region) by an ion implantation method and oxygen (also referred to as excess oxygen) is generated by substitution of the halogen element for the oxygen is performed, and then treatment in which oxygen contained in the insulator in contact with the oxide semiconductor is supplied from the insulator to the oxide semiconductor (in particular, the channel formation region) by heat treatment or the like is performed. Thus, when the oxygen traps electrons, negative charge can be formed in a region of the oxide semiconductor to which the halogen element is added. Accordingly, the transistor can exhibit an effect similar to the substrate bias effect; thus, the transistor can have normally-off characteristics even when no back gate electrode is provided.

Specific structure examples of a semiconductor device of one embodiment of the present invention are described below.

### <Structure Example of Semiconductor Device>

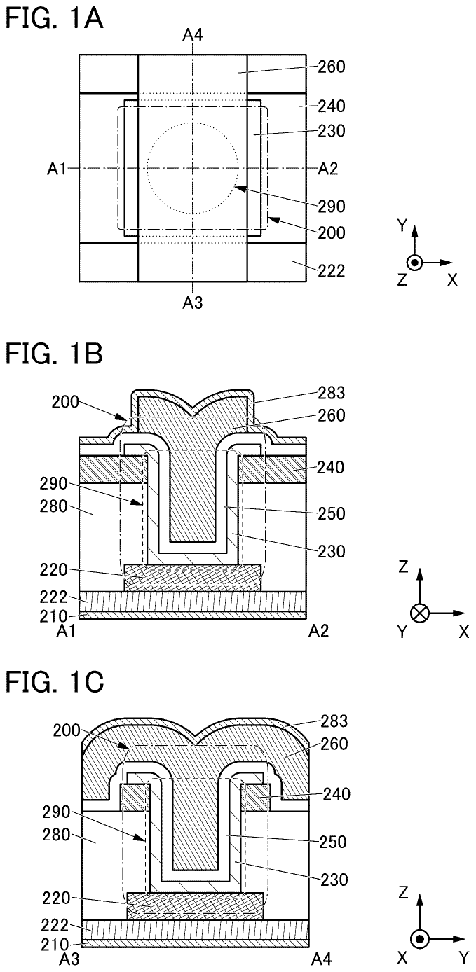

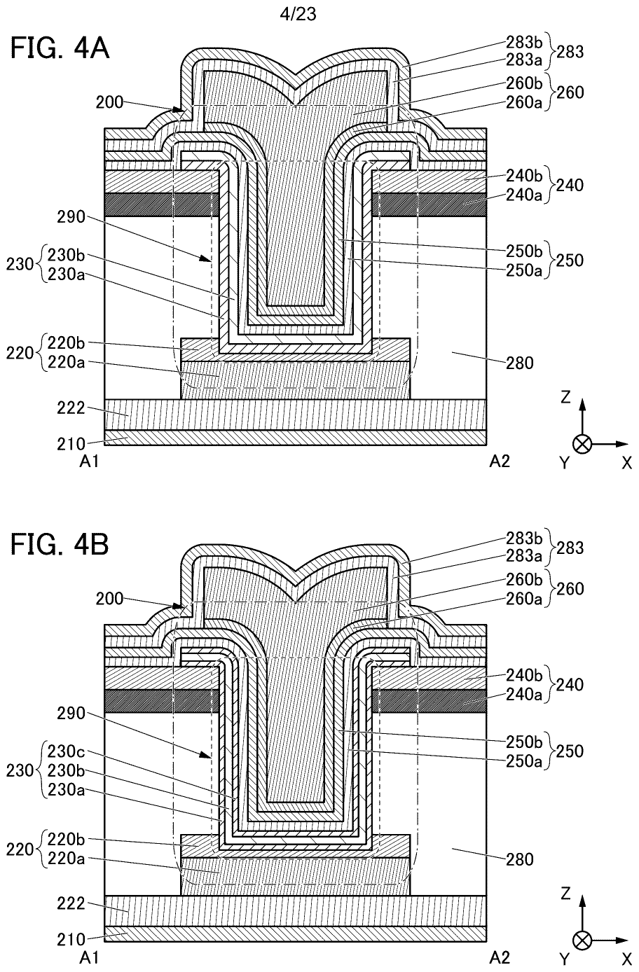

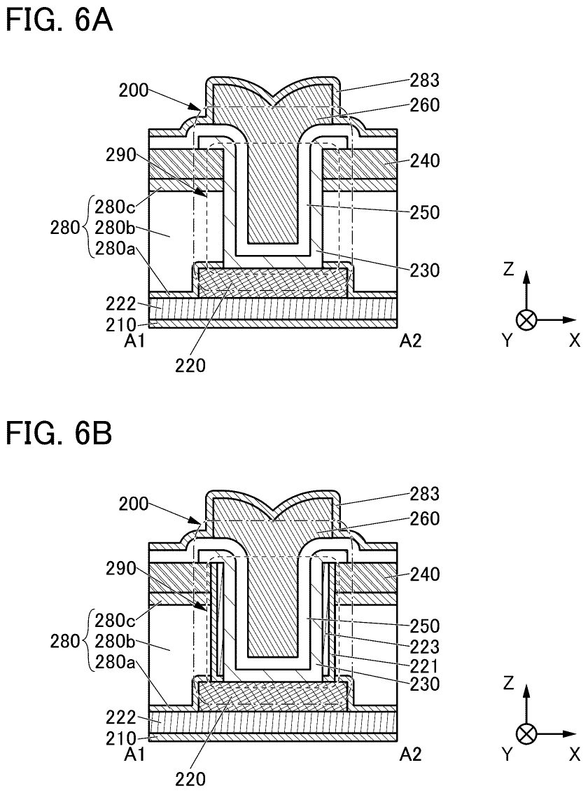

A structure example of the semiconductor device of one embodiment of the present invention is described with reference to FIG. 1A to FIG. 1C. FIG. 1A to FIG. 1C are a plan view and cross-sectional views of a semiconductor device including a transistor 200. FIG. 1A is a plan view of the semiconductor device. FIG. 1B and FIG. 1C are cross-sectional views of the semiconductor device. Here, FIG. 1B is a cross-sectional view of a portion indicated by the dashed-dotted line A1-A2 in FIG. 1A. FIG. 1C is a cross-sectional view of a portion indicated by the dashed-dotted line A3-A4 in FIG. 1A. Note that some components are omitted in the plan view in FIG. 1A for clarity of the drawing. FIG. 4A, FIG. 4B, FIG. 6A, and FIG. 6B are enlarged views corresponding to FIG. 1B.

Note that in the drawings and the like relating to this specification, arrows indicating the X direction, the Y direction, and the Z direction are shown in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

The semiconductor device illustrated in FIG. 1A to FIG. 1C includes an insulator 210 over a substrate (not illustrated), an insulator 222 over the insulator 210, the transistor 200 over the insulator 222, an insulator 280 over the insulator 222, and an insulator 283 over the transistor 200. The insulator 210 functions as an interlayer film.

The transistor 200 includes a conductor 220 over the insulator 222, a conductor 240 over the insulator 280, an oxide semiconductor 230 in contact with at least part of the top surface of the conductor 220, an insulator 250 over the oxide semiconductor 230, and a conductor 260 over the insulator 250.

As illustrated in FIG. 1B and FIG. 1C, an opening portion 290 reaching the conductor 220 is formed in the insulator 280 and the conductor 240. Here, the bottom portion of the opening portion 290 is the top surface of the conductor 220 and the sidewall of the opening portion 290 is the side surface of the insulator 280 and the side surface of the conductor 240. The opening portion 290 includes an opening portion of the insulator 280 and an opening portion of the conductor 240. In other words, the opening portion of the insulator 280 in a region overlapping with the conductor 220 is part of the opening portion 290, and the opening portion of the conductor 240 in a region overlapping with the conductor 220 is another part of the opening portion 290.

At least part of the components of the transistor 200 is placed in the opening portion 290. Specifically, at least part of each of the oxide semiconductor 230, the insulator 250, and the conductor 260 is placed in the opening portion 290.

Portions of the oxide semiconductor 230, the insulator 250, and the conductor 260 that are placed in the opening portion 290 reflect the shape of the opening portion 290. Therefore, the oxide semiconductor 230 is provided so as to cover the bottom portion and the sidewall of the opening portion 290, the insulator 250 is provided so as to cover the oxide semiconductor 230, and the conductor 260 is provided so as to be embedded in a depressed portion of the insulator 250 that reflects the shape of the opening portion 290.

In the transistor 200, the oxide semiconductor 230 functions as a semiconductor layer, the conductor 260 functions as a gate electrode, the insulator 250 functions as a gate insulator, the conductor 220 functions as one of a source electrode and a drain electrode, and the conductor 240 functions as the other of the source electrode and the drain electrode.

As described above, the oxide semiconductor 230 is provided inside the opening portion of the insulator 280. The transistor 200 has a structure in which current flows in the vertical direction since one of the source electrode and the drain electrode (here, the conductor 220) is positioned on the lower side and the other of the source electrode and the drain electrode (here, the conductor 240) is positioned on the upper side. That is, a channel is formed along the side surface of the opening portion of the insulator 280.

In the transistor 200, a metal oxide functioning as a semiconductor (also referred to as an oxide semiconductor (OS)) is preferably used for the oxide semiconductor 230 including a channel formation region. Hereinafter, a transistor using an oxide semiconductor for a semiconductor layer is sometimes referred to as an OS transistor, and a transistor using silicon for a semiconductor layer is sometimes referred to as a Si transistor. Thus, in the case where an oxide semiconductor is used for the semiconductor layer in the transistor 200, the transistor 200 is an OS transistor.

When oxygen vacancies (Vo) and impurities are in a channel formation region of an oxide semiconductor in an OS transistor, electrical characteristics of the OS transistor easily vary and the reliability thereof might worsen. In some cases, hydrogen in the vicinity of an oxygen vacancy forms a defect where hydrogen enters the oxygen vacancy (hereinafter, such defect is sometimes referred to as VoH), which generates an electron serving as a carrier. Thus, when the channel formation region in the oxide semiconductor includes oxygen vacancies, the OS transistor is likely to have normally-on characteristics. Therefore, oxygen vacancies and impurities are preferably reduced as much as possible in the channel formation region in the oxide semiconductor. In other words, the oxide semiconductor preferably includes an i-type (intrinsic) or substantially i-type channel formation region with a low carrier concentration.

Note that in this specification and the like, “normally-on characteristics” mean a state where a channel exists without application of a voltage to a gate and current flows between a source and a drain of a transistor. Furthermore, “normally-off characteristics” mean a state where current does not flow between a source and a drain of a transistor when no voltage or a ground potential is applied to a gate.

Meanwhile, a source region and a drain region of an OS transistor preferably include more oxygen vacancies, include more VoH, or have a higher concentration of an impurity such as hydrogen, nitrogen, or a metal element than a channel formation region, and thus are low-resistance regions with high carrier concentrations. In other words, the source region and the drain region of the OS transistor are preferably n-type regions with higher carrier concentrations and lower resistance than the channel formation region.

In order to improve the electrical characteristics and reliability of the OS transistor, it is important to sufficiently reduce the hydrogen concentration in the channel formation region of the oxide semiconductor and optimize the amount of oxygen supplied to the oxide semiconductor. For example, the hydrogen concentration in the channel formation region of the oxide semiconductor, which is measured by secondary ion mass spectrometry (SIMS), is preferably lower than 1×10²⁰ atoms/cm³, further preferably lower than 5×10¹⁹ atoms/cm³, still further preferably lower than 1×10¹⁹ atoms/cm³, yet further preferably lower than 5×10¹⁸ atoms/cm³, yet still further preferably lower than 1×10¹⁸ atoms/cm³, yet still further preferably lower than 1×10¹⁷ atoms/cm³.

In view of this, in one embodiment of the present invention, a barrier insulator against hydrogen is preferably used as each of the insulator 210 and the insulator 283. The insulator 210 and the insulator 283 are provided such that the transistor 200 including the oxide semiconductor 230 is sandwiched therebetween. When the insulator 210 and the insulator 283 provided outward from the oxide semiconductor 230 have a barrier property against hydrogen, diffusion of hydrogen into the oxide semiconductor 230 can be inhibited.

Note that in this specification and the like, a barrier insulator refers to an insulator having a barrier property. In addition, the barrier property refers to a property that does not easily allow diffusion of a target substance (also referred to as a property that does not easily allow passage of a target substance, a property with low permeability to a target substance, or a property of inhibiting diffusion of a target substance). Hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

Examples of the barrier insulator against hydrogen include aluminum oxide, magnesium oxide, hafnium oxide, gallium oxide, indium gallium zinc oxide, silicon nitride, silicon nitride oxide, and an oxide containing hafnium and silicon (hereinafter, referred to as hafnium silicate in some cases).

Note that in this specification and the like, an oxynitride refers to a material having a composition in which the oxygen content is higher than the nitrogen content, and a nitride oxide refers to a material having a composition in which the nitrogen content is higher than the oxygen content. For example, silicon oxynitride refers to a material that contains more oxygen than nitrogen in its composition, and silicon nitride oxide refers to a material that contains more nitrogen than oxygen in its composition.

For example, silicon nitride is preferably used for the insulator 210 and the insulator 283. In that case, the insulator 210 and the insulator 283 contain silicon and nitrogen.

Silicon nitride that can be used for the insulator 210 and the insulator 283 has a barrier property against hydrogen when the thickness is, for example, greater than or equal to 2 nm. In order to enhance the barrier property against hydrogen, the thickness of the silicon nitride is preferably greater than or equal to 3 nm, further preferably greater than or equal to 5 nm. Note that the silicon nitride has a barrier property against oxygen when the thickness is, for example, 1 nm or more. In order to enhance a barrier property against oxygen, the thickness of the silicon nitride is preferably greater than or equal to 2 nm. That is, silicon nitride formed to have a thickness that enables a barrier property against hydrogen also has a barrier property against oxygen.

As the insulator 222, an insulator having a function of capturing or fixing hydrogen is preferably used. When the insulator 222 has a function of capturing or fixing hydrogen, the hydrogen concentration in the oxide semiconductor 230 positioned inward from the insulator 210 and the insulator 283 can be reduced. Since hydrogen in the oxide semiconductor 230 is captured or fixed by the insulator 222 in that case, the hydrogen concentration in the insulator 222 increases. For example, the hydrogen concentration measured by SIMS, in at least part of a region of the insulator 222 that is between the oxide semiconductor 230 and the conductor 260 is higher than or equal to 1×10¹⁹ atoms/cm³ or higher than or equal to 1×10²⁰ atoms/cm³ in some cases. In this case, the hydrogen concentration in the at least part of the insulator 222 is higher than the hydrogen concentration in the oxide semiconductor 230. In other words, the oxide semiconductor 230 includes a region having a lower hydrogen concentration than that in the insulator 222.

Note that a function of capturing or fixing a target substance can also be referred to as a property that does not easily allow diffusion of a target substance. Thus, a function of capturing or fixing a target substance can be rephrased as a barrier property.

As the insulator having a function of capturing or fixing hydrogen, a metal oxide containing hafnium or the like (e.g., hafnium oxide) is preferable. The metal oxide preferably includes an oxygen atom having a dangling bond. Such a metal oxide has a property of capturing or fixing hydrogen with a dangling bond in some cases. For example, the metal oxide preferably has an amorphous structure. This is because some oxygen atoms in a metal oxide having an amorphous structure have dangling bonds. Although the metal oxide preferably has an amorphous structure, a crystal region is formed in part of the metal oxide in some cases. The metal oxide partly includes a crystal grain boundary in some cases.

Here, when silicon is added to hafnium oxide, crystallization of the hafnium oxide can be inhibited. That is, an oxide containing hafnium and silicon (hafnium silicate) is likely to have an amorphous structure. Thus, hafnium silicate has a property of capturing or fixing hydrogen, and so is suitable for the insulator 222. In that case, the insulator 222 contains hafnium, silicon, and oxygen.

When the insulator 222 has an amorphous structure, crystallization and formation of a crystal grain boundary due to polycrystallization can be inhibited. Inhibiting the formation of a crystal grain boundary can increase the planarity of the film of the insulator 222. This can make the thickness distribution of the insulator 222 uniform and reduce the number of extremely thin portions, so that the withstand voltage of the insulator 222 can be improved. In addition, the thickness distribution of a film provided over the insulator 222 can be uniform.

Moreover, inhibiting formation of a crystal grain boundary in the insulator 222 can reduce leakage current due to the defect states in the crystal grain boundary. Thus, the insulator 222 can function as an insulating film with low leakage current.

In the above, an oxide containing hafnium is given as an example of an insulator having a function of capturing or fixing hydrogen; however, the present invention is not limited thereto. An oxide containing magnesium, an oxide containing aluminum, and an oxide containing aluminum and hafnium (hafnium aluminate) can be given as examples. Alternatively, the above-described metal oxide further containing zirconium may be used. An oxide containing hafnium and zirconium is given as an example. Silicon is preferably added to these metal oxides and these metal oxides preferably have an amorphous structure.

When heat treatment is performed on the insulator 222, hydrogen released from the oxide semiconductor 230 can be captured or fixed. Here, the insulator 222 and the oxide semiconductor 230 are preferably provided in a closed system formed of the insulator 210 and the insulator 283 each having a barrier property against hydrogen. Accordingly, the frequency of hydrogen transfer between the inside and the outside of the closed system becomes extremely low; thus, diffusion of hydrogen from the outside to the inside or from the inside to the outside of the closed system during the heat treatment can be prevented. Thus, when hydrogen in the closed system is captured or fixed by the insulator 222, the hydrogen concentration in the oxide semiconductor 230 can be reduced. Here, the closed system refers to barrier insulators against hydrogen that covers at least part of the oxide semiconductor and inhibits hydrogen from diffusing from the outside to the inside or from the inside to the outside of the closed system. Here, in the closed system, a portion of the oxide semiconductor that functions as the channel formation region is preferably positioned inside the barrier insulators against hydrogen. For example, in the above closed system, it is preferable that the barrier insulators against hydrogen be provided to extend in the channel length direction of the oxide semiconductor, and the oxide semiconductor be surrounded or sandwiched by the barrier insulators against hydrogen. Note that the closed system does not completely block hydrogen transfer but lowers the frequency of hydrogen transfer. Therefore, in some cases, the closed system is not completely closed but is opened at a position or a plurality of positions.

With the above structure, an oxide semiconductor with few oxygen vacancies and impurities can be provided. Thus, the transistors can have favorable electrical characteristics and higher reliability. A semiconductor device with a small variation in electrical characteristics of the transistor can be provided.

With the above structure, formation of oxygen vacancies in the channel formation region and diffusion of hydrogen into the channel formation region can be inhibited. This can inhibit variations in the amount of oxygen vacancies and the hydrogen concentration in the channel formation region between transistors. Thus, variations in the electrical characteristics of the transistors can be reduced

As the insulator 280, an insulator containing oxygen that is released by heating (hereinafter, sometimes referred to as excess oxygen) is preferably used. By performing heat treatment on the insulator 280 containing excess oxygen, oxygen can be supplied from the insulator 280 to the channel formation region of the oxide semiconductor 230 and oxygen vacancies and VoH of the oxide semiconductor 230 can be reduced. Accordingly, the transistor can have stable electrical characteristics and higher reliability. As described later, in the channel formation region to which a halogen element such as chlorine or fluorine is added, excess oxygen is generated by substitution of the halogen element for the oxygen. Furthermore, when oxygen is supplied from the insulator 280 by heat treatment or the like, the oxygen can trap electrons and negative charge (negative fixed charge) can be formed in the channel formation region. Thus, a transistor with normally-off characteristics can be obtained.

As the insulator 280, the barrier insulator against hydrogen may be used. For example, silicon nitride may be used for the insulator 280. Such a structure can inhibit diffusion of hydrogen into the oxide semiconductor 230. The concentration of impurities such as water and hydrogen in the insulator 280 is preferably reduced. This can inhibit entry of impurities such as water and hydrogen into the channel formation region of the oxide semiconductor 230.

Note that a single layer or stacked layers of any of the insulators described later in the section [Insulator] may be used as the insulator 280.

Note that the sidewall of the opening portion 290 is preferably perpendicular to the top surface of the insulator 210. With such a structure, the semiconductor device can be miniaturized or highly integrated.

Although the opening portion 290 is provided such that the sidewall of the opening portion 290 is perpendicular to the top surface of the conductor 220 in FIG. 1B and FIG. 1C, the present invention is not limited thereto. For example, the sidewall of the opening portion 290 may not necessarily be strictly perpendicular to the top surface of the conductor 220 and may have a tapered shape. The sidewall of the opening portion 290 preferably has a tapered shape, in which case coverage with a film (e.g., the oxide semiconductor 230) formed to cover the sidewall of the opening portion 290 is improved.

The oxide semiconductor 230 includes a region in contact with the side surface of the conductor 240 in the opening portion 290 and a region in contact with at least part of the top surface of the conductor 240. When the oxide semiconductor 230 is in contact with not only the side surface but also the top surface of the conductor 240 in this manner, the area where the oxide semiconductor 230 and the conductor 240 are in contact with each other can be increased. The oxide semiconductor 230 includes a region in contact with the top surface of the conductor 220 that is exposed in the opening portion 290 and a region in contact with the side surface of the insulator 280 in the opening portion 290.

As illustrated in FIG. 1B and FIG. 1C, part of the oxide semiconductor 230 is positioned outside the opening portion 290, that is, over the conductor 240. Although FIG. 1B illustrates the structure in which the oxide semiconductor 230 is separated in the X direction, the present invention is not limited thereto. For example, the oxide semiconductor 230 may be provided to extend in the X direction. Also in this case, the oxide semiconductor 230 is divided in the Y direction.

FIG. 1C illustrates a structure in which the side end portion of the oxide semiconductor 230 is positioned inward from the side end portion of the conductor 240. Note that the present invention is not limited thereto. For example, a structure may be employed in which the side end portion of the oxide semiconductor 230 and the side end portion of the conductor 240 may be aligned with each other in the Y direction. Alternatively, the side end portion of the oxide semiconductor 230 may be positioned outward from the side end portion of the conductor 240.

The insulator 250 is provided in contact with the top surface of the oxide semiconductor 230. The insulator 250 includes a region in contact with the top surface of the conductor 240, a region in contact with the side surface of the conductor 240, and a region in contact with the top surface of the insulator 280.

As illustrated in FIG. 1B and FIG. 1C, part of the insulator 250 is positioned outside the opening portion 290, that is, over the conductor 240 and the insulator 280. In this case, the insulator 250 preferably covers the side end portion of the oxide semiconductor 230. This can prevent a short circuit between the conductor 260 and the oxide semiconductor 230. The insulator 250 preferably covers the side end portion of the conductor 240. This can prevent a short circuit between the conductor 260 and the conductor 240.

The conductor 260 is provided in contact with the top surface of the insulator 250.

As illustrated in FIG. 1B, the side end portion of the conductor 260 is preferably positioned inward from the side end portion of the oxide semiconductor 230. Thus, the parasitic capacitance formed between the conductor 260 and the conductor 240 can be reduced. The side end portion of the conductor 260 may be aligned with the side end portion of the oxide semiconductor 230 or positioned outward from the side end portion of the oxide semiconductor 230.

Although the conductor 260 is provided to fill the opening portion 290 in FIG. 1B and FIG. 1C, the present invention is not limited thereto. For example, a depressed portion reflecting the shape of the opening portion 290 is formed in the conductor 260 and part of the depressed portion is positioned in the opening portion 290 in some cases. In that case, the depressed portion may be filled with an inorganic insulating material or the like.

The conductor 240 includes the opening portion in a region overlapping with the conductor 220. It is preferable that the conductor 240 not be provided in the opening portion of the insulator 280. That is, it is preferable that the conductor 240 not include a region in contact with the side surface of the insulator 280 in the opening portion 290. With such a structure, the opening portion of the conductor 240 and the opening portion of the insulator 280 can be collectively formed. When the side surface of the conductor 240 in the opening portion 290 is substantially aligned with the side surface of the insulator 280 in the opening portion 290, the thickness distribution of the oxide semiconductor 230 provided in the opening portion 290 can be uniform. Furthermore, the oxide semiconductor 230 can be inhibited from being divided by a step generated between the side surface of the conductor 240 in the opening portion 290 and the side surface of the insulator 280 in the opening portion 290.

Although FIG. 1B and FIG. 1C illustrate a structure in which the side surface of the conductor 240 in the opening portion 290 is substantially aligned with the side surface of the insulator 280 in the opening portion 290, the present invention is not limited to the structure. For example, the side surface of the conductor 240 in the opening portion 290 and the side surface of the insulator 280 in the opening portion 290 may be discontinuous. The inclination of the side surface of the conductor 240 in the opening portion 290 and the inclination of the side surface of the insulator 280 in the opening portion 290 may be different from each other.

As the conductor 240, a single layer or stacked layers of any of conductors described in the later-described section [Conductor] can be used. A conductive material that is less likely to be oxidized, a conductive material having a function of inhibiting diffusion of oxygen, or the like is preferably used for the conductor 240. For example, titanium nitride, tantalum nitride, indium tin oxide to which silicon is added (also referred to as ITSO), or the like can be used.

As the conductor 220, a single layer or stacked layers of any of conductors described in the later-described section [Conductor] can be used, like the above-described insulator 240. A conductive material that is less likely to be oxidized, a conductive material having a function of inhibiting diffusion of oxygen, or the like is preferably used for the conductor 220. For example, a structure in which titanium nitride, tantalum nitride, and ITSO, or titanium nitride, tungsten, and ITSO are stacked in this order can be used.

Although FIG. 1B and FIG. 1C illustrate a structure in which the top surface of the conductor 220 is flat, the present invention is not limited to the structure. For example, a depressed portion overlapping with the opening portion 290 may be formed on the top surface of the conductor 220. When at least parts of the oxide semiconductor 230, the insulator 250, and the conductor 260 are formed to fill the depressed portion, the gate electric field of the conductor 260 can be easily applied to a portion of the oxide semiconductor 230 close to the conductor 220.

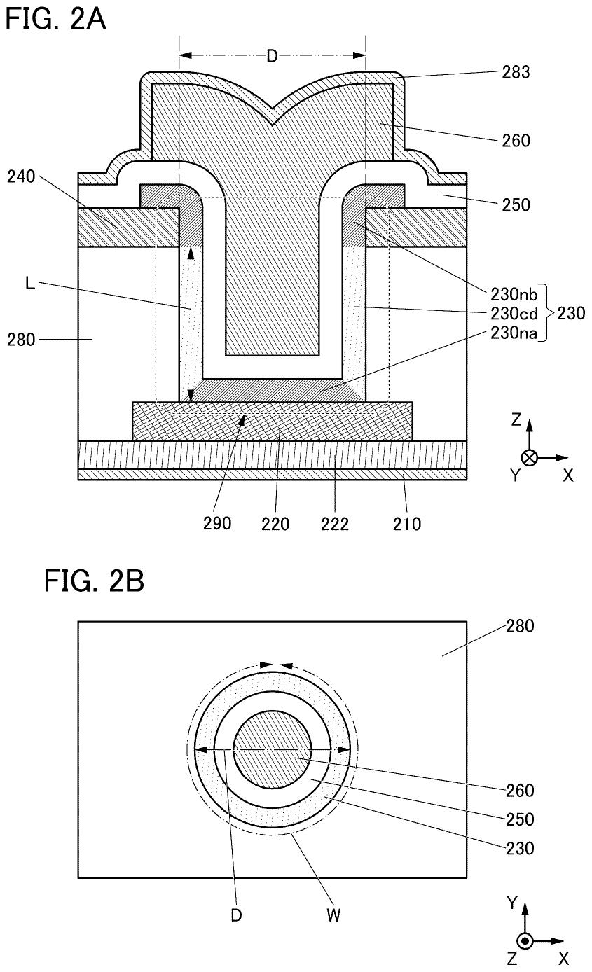

FIG. 2A is an enlarged view of the cross-sectional view of the semiconductor device on the XZ plane in FIG. 1B. FIG. 2B is a cross-sectional view in which the semiconductor device illustrated in FIG. 2A is cut along the XY plane to include the channel formation region of the oxide semiconductor 230.

As illustrated in FIG. 2A, the oxide semiconductor 230 includes a region 230cd and a region 230na and a region 230nb that are provided such that the region 230cd is sandwiched therebetween.

The region 230na is a region of the oxide semiconductor 230 that is in contact with the conductor 220. At least part of the region 230na functions as one of the source region and the drain region of the transistor. The region 230nb is a region of the oxide semiconductor 230 that is in contact with the conductor 240. At least part of the region 230nb functions as the other of the source region and the drain region of the transistor. As illustrated in FIG. 1A, the conductor 240 is in contact with the entire outer circumference of the opening portion 290 overlapping with the oxide semiconductor 230. Thus, the other of the source region and the drain region of the transistor can be formed along the entire outer circumference of a portion of the oxide semiconductor 230 that is formed on the same level as the conductor 240.

The region 230na and the region 230nb functioning as the source region and the drain region are each a region having a lower resistance than the region 230cd functioning as the channel formation region. That is, 230na and the region 230nb can each be regarded as a region having a higher oxygen vacancy density or having a higher impurity concentration than the region 230cd.

In the transistor of one embodiment of the present invention, the concentration of the impurity element, for example, the concentration of one or more of hydrogen, boron, carbon, nitrogen, phosphorus, sulfur, arsenic, aluminum, magnesium, silicon, and a noble gas in the region 230na and the region 230nb is higher than the concentration of the impurity element in the region 230cd. Typical examples of the noble gas include helium, neon, argon, krypton, and xenon. In the region 230na and the region 230nb, in particular, the concentration of one or more of boron, phosphorus, aluminum, magnesium, and silicon is preferably higher than the concentration of the impurity element in the region 230cd. In that case, the resistance of the region 230na and the region 230nb can be reduced, so that the on-state current of the transistor can be increased.

The region 230cd is a region of the oxide semiconductor 230 between the region 230na and the region 230nb. At least part of the region 230cd functions as the channel formation region of the transistor. That is, the channel formation region of the transistor is positioned in a region of the oxide semiconductor 230 between the conductor 220 and the conductor 240. It can also be said that the channel formation region of the transistor is positioned in a region of the oxide semiconductor 230 that is in contact with the insulator 280 or a region in the vicinity thereof.

The channel length of the transistor is a distance between the source region and the drain region. In other words, the channel length of the transistor is determined by the thickness of the insulator 280 over the conductor 220. In FIG. 2A, a channel length L of the transistor is indicated by the dashed double-headed arrow. In the cross-sectional view, the channel length L is a distance between the end portion of a region where the oxide semiconductor 230 is in contact with the conductor 220 and the end portion of a region where the oxide semiconductor 230 is in contact with the conductor 240. That is, the channel length L corresponds to the length of the side surface of the insulator 280 on the opening portion 290 side in the cross-sectional view.

In a planar transistor, for example, the channel length is determined by the light exposure limit of photolithography. Meanwhile, in the present invention, the channel length can be determined by the thickness of the insulator 280. Thus, the transistor can have an extremely small channel length below the light exposure limit of photolithography (e.g., greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, greater than or equal to 1 nm and less than or equal to 10 nm, or greater than or equal to 5 nm and less than or equal to 10 nm). Accordingly, the transistor can have higher on-state current and improved frequency characteristics. Thus, a semiconductor device with high operating speed can be provided.

In addition, as described above, the channel formation region, the source region, and the drain region can be formed in the opening portion 290. Thus, the area occupied by the transistor can be reduced as compared with a planar transistor in which a channel formation region, a source region, and a drain region are provided separately on the XY plane. Accordingly, miniaturization and higher integration of the semiconductor device can be achieved.

Furthermore, as illustrated in FIG. 2B, in the XY plane including the channel formation region of the oxide semiconductor 230, the oxide semiconductor 230, the insulator 250, and the conductor 260 are provided concentrically. Thus, the side surface of the conductor 260 provided at the center faces the side surface of the oxide semiconductor 230 with the insulator 250 therebetween. That is, in the plan view, the entire inner circumference of the oxide semiconductor 230 serves as the channel formation region. In that case, for example, the channel width of the transistor is determined by the length of the outer circumference of the oxide semiconductor 230. In other words, the channel width of the transistor is determined by the maximum width of the opening portion 290 (the diameter in the case where the opening portion 290 is circular in the plan view). In FIG. 2A and FIG. 2B, a maximum width D of the opening portion 290 is indicated by the dashed double-dotted double-headed arrow. In FIG. 2B, a channel width W of the transistor is indicated by the dashed-dotted double-headed arrow. By increasing the maximum width D of the opening portion 290, the channel width per unit area can be increased and the on-state current can be increased.

The maximum width D of the opening portion 290 is preferably, for example, greater than or equal to 5 nm and less than or equal to 100 nm, greater than or equal to 10 nm and less than or equal to 100 nm, greater than or equal to 20 nm and less than or equal to 100 nm, greater than or equal to 20 nm and less than or equal to 60 nm, greater than or equal to 20 nm and less than or equal to 50 nm, greater than or equal to 20 nm and less than or equal to 40 nm, or greater than or equal to 30 nm and less than or equal to 40 nm. In that case, the semiconductor device can be more miniaturized and more highly integrated than that in the case of using a planar transistor. As described above, in the case where the opening portion 290 is circular in the plan view, the maximum width D of the opening portion 290 corresponds to the diameter of the opening portion 290, and the channel width W can be calculated to be “D×π”.

Although this embodiment describes the example where the opening portion 290 has a circular shape in the plan view, the present invention is not limited thereto. For example, the opening portion 290 in the plan view may have a substantially circular shape such as an elliptical shape, a polygonal shape such as a quadrangular shape, or a polygonal shape such as a quadrangular shape with rounded corners. In that case, the maximum width of the opening portion 290 is calculated as appropriate in accordance with the shape of the uppermost portion of the opening portion 290. For example, in the case where the opening portion is quadrangular in the plan view, the maximum width of the opening portion 290 is preferably the length of a diagonal line of the uppermost portion of the opening portion 290.

In the semiconductor device of one embodiment of the present invention, the channel length L of the transistor is preferably shorter than at least the channel width W of the transistor. The channel length L of the transistor in one embodiment of the present invention is greater than or equal to 0.1 times and less than or equal to 0.99 times, preferably greater than or equal to 0.5 times and less than or equal to 0.8 times the channel width W of the transistor. Such a structure enables the transistor to have favorable electrical characteristics and high reliability.

When the oxide semiconductor 230, the insulator 250, and the conductor 260 are provided concentrically, the distance between the conductor 260 and the oxide semiconductor 230 becomes substantially uniform. Thus, a gate electric field can be substantially uniformly applied to the oxide semiconductor 230 from the conductor 260.

For example, the sidewall of the opening portion 290 is preferably perpendicular to the top surface of the conductor 220. With such a structure, the semiconductor device can be miniaturized or highly integrated. Note that the sidewall of the opening portion 290 may have a tapered shape. In the case where the sidewall of the opening portion 290 has a tapered shape, coverage with a film (e.g., the oxide semiconductor 230) formed to cover the sidewall of the opening portion 290 can be improved.

Here, when the transistor has a shorter channel length, the on-state current increases whereas what is called a short-channel effect becomes significant and the transistor is likely to have normally-on characteristics. A transistor with normally-on characteristics has higher off-state current than a transistor with normally-off characteristics. Thus, for example, the use of a transistor with normally-on characteristics in a memory device can induce various defects such as a reduction in data retention time, an increase in frequency of refresh, and an increase in power consumption.

Thus, in the case where a transistor with an extremely short channel length is fabricated on the assumption of use in a memory device or the like, the transistor needs to be fabricated to have normally-off characteristics.

The transistor of one embodiment of the present invention can be an OS transistor including a metal oxide in a semiconductor layer. An OS transistor has higher resistance against a short-channel effect than a Si transistor. Thus, even in the case of fabricating a transistor with an extremely short channel length as described above, the influence of the short-channel effect can be inhibited.

The transistor of one embodiment of the present invention has negative charge (negative fixed charge) in the region 230cd functioning as the channel formation region in the oxide semiconductor 230, and the potential of the region is lower than the potentials of the region 230na and the region 230nb functioning as the source region and the drain region. The negative charge can be generated in the following manner: in fabrication of the transistor, a halogen element such as chlorine or fluorine is added to the region 230cd in the oxide semiconductor 230 (particularly the region 230cd) by an ion implantation method or the like to generate excess oxygen, and then oxygen contained in the insulator 280 is supplied to the oxide semiconductor 230 (particularly the region 230cd) by heat treatment or the like, so that the oxygen traps electrons. As a result, the substrate bias effect enables the transistor to have normally-off characteristics.

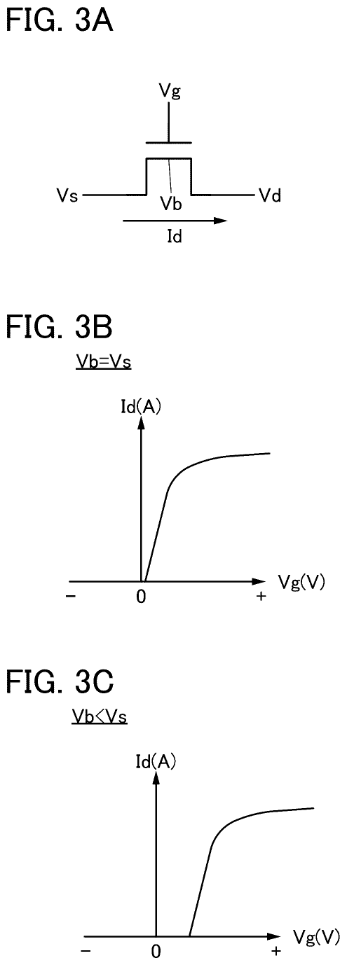

FIG. 3A to FIG. 3C are schematic diagrams illustrating a state where the electrical characteristics (Id-Vg characteristics) of the transistor are brought normally off due to the substrate bias effect.

FIG. 3A is a diagram illustrating potentials applied to the regions of the transistor (n-channel transistor). In the diagram, Vs is a potential applied to the source of the transistor, Vd is a potential applied to the drain of the transistor, Vg is a potential applied to the gate of the transistor, Vb is a potential applied to the semiconductor layer (channel formation region) of the transistor, and Id is drain current.

FIG. 3B is a schematic diagram illustrating an example of Id-Vg characteristics of the transistor in a state where Vb and Vs are the same potential (Vb=Vs). FIG. 3B illustrates an example in which Id starts to flow at Vg of approximately 0 V.

FIG. 3C is a schematic diagram illustrating an example of Id-Vg characteristics of the transistor in a state where Vb is a potential lower than Vs (Vb<Vs). In this case, when a reverse bias is applied between the source region and the channel formation region of the transistor (a negative potential is applied to the channel formation region side in the case of an n-channel transistor), the substrate bias effect is brought about and the transistor can have normally-off Id-Vg characteristics as compared with that in FIG. 3B.

Here, a potential corresponds to the potential energy of a charge of 1C charge. Thus, in other words, the magnitude of the potentials (Vs, Vd, Vg, and Vb) applied to the respective regions of the transistor corresponds to the magnitude of charge (the amount of charge) in the respective regions of the transistor. Thus, it can be said that the case where a region of the transistor, e.g., the channel formation region, has a certain amount of negative charge is equivalent to the case where a negative potential (Vb) with a level corresponding to the amount of the negative charge is applied to the channel formation region.

Thus, it can also be said that the transistor having negative charge (negative fixed charge) in the channel formation region shows the same behavior (electrical characteristics) as a transistor in which a negative potential (Vb) corresponding to the negative charge is applied to the channel formation region. For example, it can be said that a transistor that has a certain amount of negative charge (negative fixed charge) in the channel formation region is acted on by the effect similar to the substrate bias effect that acts when a negative potential (Vb) with a level corresponding to the amount of the negative charge is applied.

As described above, in the transistor of one embodiment of the present invention, negative charge (negative fixed charge) is formed in the channel formation region (the region 230cd), whereby the potential of the region is lower than that of the source region and the drain region (the region 230na and the region 230nb). Thus, the substrate bias effect can be exhibited, so that the transistor can have normally-off characteristics.

In the transistor of one embodiment of the present invention, there is no need to provide a back gate for making the substrate bias effect act. Thus, the number of fabrication steps of the transistor can be reduced. In addition, a power supply for applying a negative bias to the back gate is unnecessary so that the transistor with normally-off characteristics can be obtained without increasing the number of components that come with the semiconductor device. Furthermore, since there is no need to apply a negative bias to the back gate, the transistor with normally-off characteristics can be obtained without increasing power consumption.

As the oxide semiconductor 230, a single layer or stacked layers of any of the metal oxides in the later-described section [Metal oxide] can be used.

Specifically, as the oxide semiconductor 230, a metal oxide with a composition of In:M:Zn 32 1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio. It is preferable to use one or more of gallium, aluminum, and tin as an element M.

The oxide semiconductor 230 may have a structure not containing the element M. For example, a metal oxide used as the oxide semiconductor 230 may be an In—Zn oxide. Specifically, the oxide semiconductor 230 can have a composition of In:Zn=1:1 [atomic ratio] or in the neighborhood thereof or a composition of In:Zn=4:1 [atomic ratio] or in the neighborhood thereof. Alternatively, as the oxide semiconductor 230, an indium oxide may be used. The oxide semiconductor 230 may contain a slight amount of the element M. Specifically, for example, the oxide semiconductor 230 can have a composition of In:Sn:Zn=4:0.1:1 [atomic ratio] or in the neighborhood thereof.

As an analysis method of the composition of a metal oxide used as the oxide semiconductor 230, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis is lower than the actual content percentage in some cases.

For the formation of a metal oxide, a sputtering method or an atomic layer deposition (ALD) method can be suitably used. Note that in the case where the metal oxide is formed by a sputtering method, the composition of the formed metal oxide may be different from the composition of a sputtering target. In particular, the content percentage of zinc in the formed metal oxide is reduced to approximately 50% of that of the sputtering target in some cases.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

The ALD method enables atomic layers to be deposited one by one, and has advantages such as formation of an extremely thin film, formation on a component with a high aspect ratio or on a surface with a large step, formation of a film with few defects such as pinholes, formation with excellent coverage, and low-temperature formation. The use of plasma in a PEALD method is sometimes preferable because it enables formation at a lower temperature. Note that some precursors used in an ALD method contain an element such as carbon or chlorine. Thus, in some cases, a film provided by an ALD method contains a larger amount of an element such as carbon or chlorine than a film provided by another formation method. Note that these elements can be quantified by XPS or SIMS. The film formation method of a metal oxide of one embodiment of the present invention, which employs an ALD method and one or both of a film formation condition with a high substrate temperature and impurity removal treatment, sometimes forms a film with smaller amounts of carbon and chlorine than a method employing an ALD method without the film formation condition with a high substrate temperature or the impurity removal treatment.

Unlike a formation method in which particles ejected from a target or the like are deposited, an ALD method is a formation method in which a film is formed by reaction at a surface of an object to be processed. Thus, the ALD method is a formation method that enables favorable step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low formation rate, and thus is preferably used in combination with another formation method with a high formation rate, such as a sputtering method or a chemical vapor deposition (CVD) method, in some cases. For example, in the case where a metal oxide has a stacked-layer structure of a first metal oxide and a second metal oxide, a method in which a sputtering method is used to form the first metal oxide and an ALD method is used to form the second metal oxide over the first metal oxide can be given. For example, in the case where the first metal oxide has a crystal part, crystal growth occurs in the second metal oxide with the use of the crystal part as a nucleus.

In the ALD method, the composition of a film to be formed can be controlled with the amount of introduced source gas. For example, a film with a certain composition can be formed in the ALD method by adjusting the amount of introduced source gas, the number of times of introduction (also referred to as the number of pulses), the time required for one pulse (also referred to as the pulse time), and the like. Moreover, a film with a continuously changed composition can be formed in the ALD method by, for example, changing the source gas during the film formation. In the case where the film is formed while the source gas is changed, as compared to the case where the film is formed using a plurality of film formation chambers, the time taken for the film formation can be shortened because the time taken for transfer and pressure adjustment is not required. Thus, the productivity of the semiconductor device can be increased in some cases.

Note that there is no particular limitation on the method for forming the oxide semiconductor film to be the oxide semiconductor 230. For example, the oxide semiconductor film may be formed by a CVD method, an MBE method, a PLD method, or the like.

The oxide semiconductor 230 preferably has crystallinity. Examples of an oxide semiconductor having crystallinity include a CAAC-OS (C-axis Aligned Crystalline Oxide Semiconductor), an nc-OS (nanocrystalline Oxide Semiconductor), a polycrystalline oxide semiconductor, and a single crystal oxide semiconductor. As the oxide semiconductor 230, the CAAC-OS or the nc-OS is preferably used, and the CAAC-OS is particularly preferably used.

The CAAC-OS preferably includes a plurality of layered crystal regions and the c-axis is preferably aligned in a normal direction of a surface where the CAAC-OS is formed. For example, the oxide semiconductor 230 preferably includes layered crystals substantially parallel to the sidewall of the opening portion 290, particularly the side surface of the insulator 280. With this structure, the layered crystals of the oxide semiconductor 230 are formed substantially in parallel with the channel length direction of the transistor, so that the on-state current of the transistor can be increased.

The CAAC-OS is a metal oxide having a dense structure with high crystallinity and a small number of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor is stable with respect to high temperatures in the manufacturing process (what is called thermal budget).

The crystallinity of the oxide semiconductor 230 can be analyzed with X-ray diffraction (XRD), a transmission electron microscope (TEM), or electron diffraction (ED), for example. Alternatively, any of these methods may be combined with each other for the analysis.

When a conductive oxide having an amorphous structure is used as the conductor 240 and the conductor 220, the oxide semiconductor 230 in contact with the top surfaces of the conductor 240 and the conductor 220 can be a CAAC-OS relatively easily. For example, indium tin oxide to which silicon is added is preferably used as the conductor 240 and the conductor 220.

Note that the present invention is not limited to the above. For example, the oxide semiconductor 230 can be polycrystallized by using polycrystallized indium tin oxide as the conductor 240.

### <Modification Example of Semiconductor Device>

Although the oxide semiconductor 230 being a single layer is illustrated in FIG. 1B and FIG. 1C, the present invention is not limited thereto. The oxide semiconductor 230 may have a stacked-layer structure of a plurality of oxide layers with different chemical compositions. For example, a structure in which a plurality of kinds of metal oxides selected from the metal oxides described in the later-described section [Metal oxide] are stacked as appropriate may be used.

For example, as illustrated in FIG. 4A, the oxide semiconductor 230 may have a stacked-layer structure of an oxide semiconductor 230a and an oxide semiconductor 230b over the oxide semiconductor 230a.

The conductivity of a material used for the oxide semiconductor 230a is preferably different from the conductivity of a material used for the oxide semiconductor 230b.

For example, a material having higher conductivity than a material for the oxide semiconductor 230b can be used for the oxide semiconductor 230a. The use of the material having high conductivity for the oxide semiconductor 230a, which is in contact with the conductor 220 and the conductor 240 functioning as the source electrode and the drain electrode, can reduce the contact resistance between the oxide semiconductor 230 and the conductor 220 and the contact resistance between the oxide semiconductor 230 and the conductor 240, and thus the transistor can have high on-state current.

Here, in the case where a material having high conductivity is used for the oxide semiconductor 230b provided on the side of the conductor 260 functioning as the gate electrode, the threshold voltage of the transistor shifts and drain current flowing when the gate voltage is 0 V (hereinafter also referred to as cutoff current) becomes large in some cases. Specifically, the threshold voltage might be low when the transistor 200 is an n-channel transistor. Thus, a material having lower conductivity than a material for the oxide semiconductor 230a is preferably used for the oxide semiconductor 230b. Accordingly, the transistor 200 can have a high threshold voltage in the case where the transistor 200 is an n-channel transistor, in which case the transistor 200 can have low cut-off current. Note that low cut-off current is sometimes referred to as normally-off.

When the oxide semiconductor 230 has a stacked-layer structure and the material having higher conductivity than the material for the oxide semiconductor 230b is used for the oxide semiconductor 230a as described above, the transistor can have normally-off characteristics and high on-state current. Consequently, the semiconductor device can have both low power consumption and high performance.

The carrier concentration of the oxide semiconductor 230a is preferably higher than the carrier concentration of the oxide semiconductor 230b. Increasing the carrier concentration of the oxide semiconductor 230a results in higher conductivity thereof, which can reduce the contact resistance between the oxide semiconductor 230 and the conductor 220 and the contact resistance between the oxide semiconductor 230 and the conductor 240, and thus the transistor can have high on-state current. When the carrier concentration of the oxide semiconductor 230b is reduced, the conductivity is reduced, and thus the transistor can have normally-off characteristics.

Although the example in which a material having higher conductivity than a material for the oxide semiconductor 230b is used for the oxide semiconductor 230a is described here, the present invention is not limited thereto. A material having lower conductivity than a material for the oxide semiconductor 230b may be used for the oxide semiconductor 230a. The carrier concentration of the oxide semiconductor 230a may be lower than the carrier concentration of the oxide semiconductor 230b.

The band gap of the first metal oxide used for the oxide semiconductor 230a and the band gap of the second metal oxide used for the oxide semiconductor 230b are preferably different from each other. For example, the difference between the band gap of the first metal oxide and the band gap of the second metal oxide is preferably larger than or equal to 0.1 eV, further preferably larger than or equal to 0.2 eV, still further preferably larger than or equal to 0.3 eV.

The band gap of the first metal oxide used for the oxide semiconductor 230a can be smaller than the band gap of the second metal oxide used for the oxide semiconductor 230b. Thus, the contact resistance between the oxide semiconductor 230 and the conductor 220 and the contact resistance between the oxide semiconductor 230 and the conductor 240 can be reduced, and thus the transistor can have high on-state current. Furthermore, the transistor 200 can have a high threshold voltage in the case where the transistor is an n-channel transistor; accordingly, the transistor 200 can have normally-off characteristics.

Although the example in which the band gap of the first metal oxide is smaller than the band gap of the second metal oxide is described here, the present invention is not limited thereto. The band gap of the first metal oxide can be larger than that of the second metal oxide.

As described above, the band gap of the first metal oxide used for the oxide semiconductor 230a can be smaller than the band gap of the second metal oxide used for the oxide semiconductor 230b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each In—M—Zn oxide, the first metal oxide can have a composition of In:M:Zn=1:1:1 [atomic ratio] or in the neighborhood thereof, and the second metal oxide can have a composition of In:M:Zn=1:3:2 [atomic ratio] or in the neighborhood thereof. It is particularly preferable to use one or more of gallium, aluminum, and tin as the element M.

The first metal oxide may have a composition not including the element M. For example, the first metal oxide used for the oxide semiconductor 230a can be In—Zn oxide, and the second metal oxide used for the oxide semiconductor 230b can be an In—M—Zn oxide. Specifically, the first metal oxide can be In—Zn oxide, and the second metal oxide can be an In—Ga—Zn oxide. More specifically, the first metal oxide can have a composition of In:Zn=1:1 [atomic ratio] or in the neighborhood thereof or a composition of In:Zn=4:1 [atomic ratio] or in the neighborhood thereof, and the second metal oxide can have a composition of In:Ga:Zn=1:1:1 [atomic ratio] or in the neighborhood thereof. The first metal oxide may contain a slight amount of the element M. For example, the first metal oxide can have a composition of In:Sn:Zn=4:0.1:1 [atomic ratio] or in the neighborhood thereof.

Although the example in which the content percentage of the element M in the first metal oxide is lower than the content percentage of the element M in the second metal oxide is described here, one embodiment of the present invention is not limited thereto. The content percentage of the element M in the first metal oxide may be higher than the content percentage of the element M in the second metal oxide. As long as the compositions of the first metal oxide and the second metal oxide are different from each other, the content percentages of elements other than the element M may be different from each other.

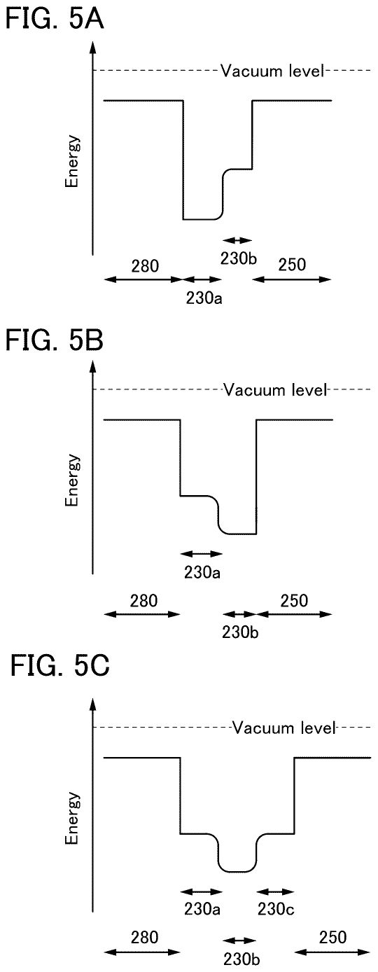

FIG. 5A and FIG. 5B each illustrate an example of a band diagram (a diagram of the conduction band minimum) of the case where the oxide semiconductor 230 has a stacked-layer structure of two layers of the oxide semiconductor 230a and the oxide semiconductor 230b. FIG. 5A is an example of a band diagram of the case where a material having higher conductivity than the oxide semiconductor 230b is used for the oxide semiconductor 230a. In this case, the energy level of the conduction band minimum of the oxide semiconductor 230a is lower than the energy level of the conduction band minimum of the oxide semiconductor 230b; thus, electrons serving as carriers mainly flow through the oxide semiconductor 230a serving as a carrier path.

FIG. 5B is an example of a band diagram of the case where a material having lower conductivity than the oxide semiconductor 230b is used for the oxide semiconductor 230a. In this case, the energy level of the conduction band minimum of the oxide semiconductor 230b is lower than the energy level of the conduction band minimum of the oxide semiconductor 230a; thus, electrons serving as carriers mainly flow through the oxide semiconductor 230b serving as a carrier path.

In the case where the oxide semiconductor 230 has a stacked-layer structure of two layers as described above, by using materials with different conductivity and bandgaps for the oxide semiconductor 230a and the oxide semiconductor 230b, the band shape of the oxide semiconductor 230 is changed, so that the carrier path in the oxide semiconductor 230 can be changed.

The thickness of the oxide semiconductor 230 is preferably greater than or equal to 1 nm and less than or equal to 20 nm, greater than or equal to 3 nm and less than or equal to 15 nm, greater than or equal to 5 nm and less than or equal to 12 nm, or greater than or equal to 5 nm and less than or equal to 10 nm, for example

The thicknesses of the layers included in the oxide semiconductor 230 (here, the oxide semiconductor 230a and the oxide semiconductor 230b) are determined in such a manner that the thickness of the oxide semiconductor 230 is within the above-described range. The thickness of the oxide semiconductor 230a can be determined in such a manner that the contact resistance between the oxide semiconductor 230a and the conductor 220 and the contact resistance between the oxide semiconductor 230a and the conductor 240 are within required ranges. The thickness of the oxide semiconductor 230b can be determined in such a manner that the threshold voltage of the transistor is within a required range. Note that the thickness of the oxide semiconductor 230a may be the same as or different from the thickness of the oxide semiconductor 230b.

The oxide semiconductor 230a and the oxide semiconductor 230b differ in the ratio between the thickness of a portion formed over the top surface of the conductor 240 and the thickness of a portion formed along the side surface of the conductor 240 and the side surface of the insulator 280 in some cases.

Although FIG. 4A illustrates a structure in which the oxide semiconductor 230 has a stacked-layer structure of two layers, the oxide semiconductor 230a and the oxide semiconductor 230b, the present invention is not limited thereto. The oxide semiconductor 230 may have a stacked-layer structure of three or more layers.

For example, as illustrated in FIG. 4B, the oxide semiconductor 230 may have a stacked-layer structure of the oxide semiconductor 230a, the oxide semiconductor 230b over the oxide semiconductor 230a, and an oxide semiconductor 230c over the oxide semiconductor 230b. In other words, in the structure illustrated in FIG. 4A, the oxide semiconductor 230c may be provided between the conductor 260 and the oxide semiconductor 230b.

The atomic ratio of the element M to In in the metal oxide used as the oxide semiconductor 230a is preferably greater than the atomic ratio of the element M to In in the metal oxide used as the oxide semiconductor 230b. With such a structure, impurities and oxygen can be inhibited from being diffused into the oxide semiconductor 230b from the components formed outside the oxide semiconductor 230a. In addition, diffusion of the element contained in the insulator 280, the conductor 220, or the conductor 240 into the oxide semiconductor 230b can be inhibited.

In the case where the insulator 280 has a function of inhibiting diffusion of hydrogen and oxygen, the oxide semiconductor 230a is not necessarily provided. In that case, the oxide semiconductor 230 may have a stacked-layer structure of the oxide semiconductor 230b and the oxide semiconductor 230c over the oxide semiconductor 230b.

For example, in the case where an oxide semiconductor film is formed by a formation method that causes less damage to the insulator 280, the oxide semiconductor 230a is not necessarily provided. For example, in the case where an oxide semiconductor film to be the oxide semiconductor 230b is formed by an ALD method or a CVD method, the oxide semiconductor 230a is not necessarily provided. In the case where the oxide semiconductor film is formed by an ALD method or a CVD method, damage to the insulator 280 is reduced, so that diffusion of the element contained in the insulator 280 into the oxide semiconductor film can be inhibited.

Here, in the case where a material having high conductivity is used for the oxide semiconductor 230c provided on the side of conductor 260 functioning as the gate electrode, the threshold voltage of the transistor 200 shifts and cut-off current becomes large in some cases. Specifically, the threshold voltage may be low when the transistor 200 is an n-channel transistor. Thus, a material having lower conductivity than a material for the oxide semiconductor 230b is preferably used for the oxide semiconductor 230c. Accordingly, the transistor 200 can have a high threshold voltage in the case where the transistor 200 is an n-channel transistor, in which case the transistor 200 can have low cut-off current.

When a material having higher conductivity than the material for the oxide semiconductor 230c is used for the oxide semiconductor 230b as described above, the transistor can have normally-off characteristics and high on-state current. Consequently, the semiconductor device can have both low power consumption and high performance.

The carrier concentration of the oxide semiconductor 230b is preferably higher than the carrier concentration of the oxide semiconductor 230c. Increasing the carrier concentration of the oxide semiconductor 230b results in higher conductivity thereof, which enables the transistor to have high on-state current. When the carrier concentration of the oxide semiconductor 230c is reduced, the conductivity is reduced, and thus the transistor can have normally-off characteristics.

Although the example in which a material having higher conductivity than the material for the oxide semiconductor 230c is used for the oxide semiconductor 230b is described here, one embodiment of the present invention is not limited thereto. A material having lower conductivity than a material for the oxide semiconductor 230c may be used for the oxide semiconductor 230b. The carrier concentration of the oxide semiconductor 230b may be lower than the carrier concentration of the oxide semiconductor 230c.

The band gap of the second metal oxide used for the oxide semiconductor 230b and the band gap of the third metal oxide used for the oxide semiconductor 230c are preferably different from each other. For example, the difference between the band gap of the second metal oxide and the band gap of the third metal oxide is preferably greater than or equal to 0.1 eV, further preferably greater than or equal to 0.2 eV, still further preferably greater than or equal to 0.3 eV.

The band gap of the second metal oxide used for the oxide semiconductor 230b can be smaller than the band gap of the third metal oxide used for the oxide semiconductor 230c. Thus, the contact resistance between the oxide semiconductor 230 and the conductor 220 and the contact resistance between the oxide semiconductor 230 and the conductor 240 can be reduced, and thus the transistor can have high on-state current. Furthermore, the transistor 200 can have a high threshold voltage in the case where the transistor is an n-channel transistor; accordingly, the transistor 200 can have normally-off characteristics.

Although the example in which the band gap of the second metal oxide is smaller than the band gap of the third metal oxide is described here, one embodiment of the present invention is not limited thereto. The band gap of the second metal oxide may be larger than the band gap of the third metal oxide in some cases.

The first metal oxide used for the oxide semiconductor 230a and the third metal oxide used for the oxide semiconductor 230c may have the same composition or different compositions.

For example, a metal oxide with a composition of In:Ga:Zn=1:1:1 [atomic ratio] or in the neighborhood thereof may be used for the oxide semiconductor 230a, a metal oxide with a composition of In:Zn=1:1 [atomic ratio] or in the neighborhood thereof, a metal oxide with a composition of In:Zn=4:1 [atomic ratio] or in the neighborhood thereof, a metal oxide with a composition of In:Sn:Zn=4:0.1:1 [atomic ratio] or in the neighborhood thereof, or an indium oxide may be used for the oxide semiconductor 230b, and a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof may be used for the oxide semiconductor 230c. With this structure, the transistor 200 can have high on-state current and high reliability with small variations.

FIG. 5C illustrates an example of a band diagram (a diagram of the conduction band minimum) of the case where the oxide semiconductor 230 has a three-layer stacked structure of the oxide semiconductor 230a, the oxide semiconductor 230b, and the oxide semiconductor 230c. FIG. 5C shows an example of a band diagram of the case where, among the three layers, the oxide semiconductor 230b is formed using a material having the highest conductivity and the oxide semiconductor 230a and the oxide semiconductor 230c are formed using materials having substantially the same conductivity.

In that case, the energy level of the conduction band minimum of the oxide semiconductor 230b is lower than the energy levels of the conduction band minimums of the oxide semiconductor 230a and the oxide semiconductor 230c, so that what is called a buried channel can be formed. Thus, electrons serving as carriers mainly flow through the oxide semiconductor 230b serving as a carrier path. Accordingly, with use of the transistor having a buried-channel structure, the transistor can operate while the influence at the interface between the oxide semiconductor 230 and the insulator 250 and the interface between the oxide semiconductor 230 and the insulator 280 (e.g., an electron trap by an interface state) is inhibited. Consequently, a transistor with favorable electrical characteristics and reliability can be obtained.

The semiconductor device illustrated in FIG. 4A and FIG. 4B is different from the semiconductor device illustrated in FIG. 1A to FIG. 1C in the structures of the conductor 240, the conductor 220, the insulator 250, the conductor 260, and the insulator 283 in addition to the above-described structure of the oxide semiconductor 230.

As illustrated in FIG. 4A and FIG. 4B, the conductor 240 preferably has a stacked-layer structure. For example, the conductor 240 preferably has a stacked-layer structure of a conductor 240a and a conductor 240b in contact with the top surface of the conductor 240a.

The bottom surface (the surface on the insulator 210 side) of the conductor 240a is in contact with the insulator 280, one of the side surfaces (the side surface on the side facing the opening portion 290) of the conductor 240a is in contact with the oxide semiconductor 230 in the Y direction (not illustrated), and the other of the side surfaces (the side surface on the side not facing the opening portion 290) of the conductor 240a is in contact with the insulator 250. The conductor 240a is preferably formed using a metal having higher conductivity than the conductor 240b. The conductor 240a is preferably formed using a metal having lower sheet resistance than the conductor 240b. With such a structure, the conductor 240 including the conductor 240a can function as a wiring connected to the one of the source electrode and the drain electrode.

For the conductor 240a, one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum, an alloy including one or more of these metals as its components, or the like can be used.

Part of the conductor 240a contains a metal oxide of the above metal in some cases. In that case, a layer of the metal oxide is sometimes formed in the vicinity of an interface between the conductor 240a and the conductor 240b and in the vicinity of an interface between the conductor 240a and the oxide semiconductor 230. Here, ruthenium and an alloy of ruthenium are preferable because they are materials that maintain relatively low electric resistance even after being oxidized.

One of the side surfaces (the side surface on the side facing the opening portion 290) of the conductor 240b and part of the top surface of the conductor 240b are in contact with the oxide semiconductor 230. In the Y direction (not illustrated), the other side surface (the side surface on the side not facing the opening portion 290) of the conductor 240b and another part of the top surface of the conductor 240b are in contact with the insulator 250. The conductor 240b is preferably in ohmic contact with the oxide semiconductor 230 and the contact resistance between the conductor 240b and the oxide semiconductor 230 is preferably low. For example, the contact resistance between the conductor 240b and the oxide semiconductor 230 is preferably lower than the contact resistance between the oxide semiconductor 230 and the metal layer used for the conductor 240a. Thus, the conductor 240b is preferably formed using a metal oxide having conductivity (sometimes referred to as a conductive oxide). When the conductor 240b has the above-described structure, the on-state current, the field-effect mobility, and the frequency characteristics of the transistor 200 can be improved.

As a conductive oxide (OC: Oxide Conductor, also referred to as a conductive material containing oxygen) used for the conductor 240b, a conductive oxide containing indium is preferable. As the conductive oxide containing indium, indium oxide, indium tin oxide (also referred to as ITO in some cases), indium zinc oxide, ITSO, or the like is preferably used. Alternatively, tungsten, titanium, or the like may be contained in indium oxide; for example, In—W oxide, In—W—Zn oxide, In—Ti oxide, In—Ti—Sn oxide, or the like may be used. Alternatively, a conductive oxide containing zinc may be used; for example, zinc oxide, zinc oxide to which gallium is added, In—Ga—Zn oxide, or the like can be used. As the conductive oxide, ruthenium oxide, an oxide including strontium and ruthenium, an oxide including lanthanum and nickel, or the like can be used. A conductive oxide containing indium is particularly preferable because of its high conductivity.

For example, indium tin oxide to which silicon is added can be used for the conductor 240b. In that case, the conductor 240b contains indium, tin, silicon, and oxygen. Here, when silicon is added to the indium tin oxide, polycrystallization of the indium tin oxide can be inhibited. That is, the indium tin oxide to which silicon is added is likely to have an nc structure (a nanocrystal structure) or an amorphous structure. Note that the present invention is not limited to the above. Polycrystallized indium tin oxide can also be used for the conductor 240b. In that case, the conductor 240b contains indium, tin, and oxygen.

As described above, heat treatment is performed with the conductor 240a including a metal and the conductor 240b including a conductive oxide, whereby oxygen in the conductor 240b is diffused to the vicinity of the interface with the conductor 240a, and oxygen vacancies (Vo) are formed in the conductor 240b. Furthermore, oxygen in the oxide semiconductor 230 in the vicinity of the conductor 240 is diffused to the vicinity of the interface with each of the conductor 240b where the oxygen vacancies (Vo) are formed and the conductor 240a, so that oxygen vacancies (Vo) are formed in a region of the oxide semiconductor 230 that is in the vicinity of the conductor 240. When hydrogen enters the oxygen vacancy (Vo) and VoH is formed, the resistance of the region of the oxide semiconductor 230 that is in the vicinity of the conductor 240 is lowered in a self-aligned manner. The low-resistance region functions as one of the source region and the drain region of the transistor 200.

Although the example in which the conductor 240 has a stacked-layer structure of two layers of the conductor 240a and the conductor 240b is described above, the present invention is not limited thereto. The conductor 240 may have a stacked-layer structure of three or more layers.

As illustrated in FIG. 4A and FIG. 4B, the conductor 220 may have a stacked-layer structure of a conductor 220a and a conductor 220b over the conductor 220a. Here, a metal having high conductivity, like the conductor 240a, is preferably used for the conductor 220a. Thus, a metal that can be used for the conductor 240a can be used for the conductor 220a. For example, tungsten can be used for the conductor 220a. With such a structure, the conductor 220 including the conductor 220a can function as a wiring connected to the other of the source electrode and the drain electrode.

A conductive oxide like the conductor 240b is preferably used for the conductor 220b. Thus, a conductive oxide that can be used for the conductor 240b can be used for the conductor 220b. For example, indium tin oxide to which silicon is added can be used for the conductor 220b. In this case, the conductor 220b contains indium, tin, silicon, and oxygen. Such a structure can improve the on-state current, the field-effect mobility, and the frequency characteristics of the transistor 200.

As described above, heat treatment is performed on a structure of the conductor 220a including a metal and the conductor 220b including a conductive oxide, whereby oxygen in the conductor 220b is diffused to the vicinity of the interface with the conductor 220a, and oxygen vacancies (Vo) are formed in the conductor 220b. Furthermore, oxygen in the oxide semiconductor 230 in the vicinity of the conductor 220 is diffused to the vicinity of the interface between the conductor 220b where oxygen vacancies (Vo) are formed and the conductor 220a, so that oxygen vacancies (Vo) are formed in a region of the oxide semiconductor 230 in the vicinity of the conductor 220. When hydrogen enters the oxygen vacancy (Vo) and VoH is formed, the resistance of the region of the oxide semiconductor 230 that is in the vicinity of the conductor 220 is lowered in a self-aligned manner. The low-resistance region functions as the other of the source region and the drain region of the transistor 200. As described above, the insulator 222 placed under the conductor 220 captures hydrogen in the oxide semiconductor 230 through the conductor 220 by the heat treatment. At this time, hydrogen in the channel formation region of the oxide semiconductor 230 is diffused to the other of the source region and the drain region, so that VoH can be formed more efficiently in the other of the source region and the drain region.

As described above, a metal oxide having conductivity is preferably used for the conductor 240b and the conductor 220b. Accordingly, the conductor 240b and the oxide semiconductor 230a can be in ohmic contact with each other, and the conductor 220b and the oxide semiconductor 230a can be in ohmic contact with each other. For example, indium tin oxide to which silicon is added is preferably used for the conductor 240b and the conductor 220b, and a metal oxide having relatively high conductivity with a composition of In:Ga:Zn=1:1:1 [atomic ratio] or in the neighborhood thereof is preferably used for the oxide semiconductor 230a. Accordingly, the on-state current, field-effect mobility, and frequency characteristics of the transistor 200 can be improved.

As illustrated in FIG. 4A and FIG. 4B, the insulator 250 may have a stacked-layer structure of an insulator 250a and an insulator 250b over the insulator 250a. The insulator 250a is provided in contact with the top surface of the oxide semiconductor 230. The insulator 250a preferably includes a region in contact with the top surface of the conductor 240, a region in contact with the side surface of the conductor 240, and a region in contact with the insulator 280. The insulator 250b is provided in contact with the top surface of the insulator 250a.

As the insulator 250a, an insulator having a function of capturing or fixing hydrogen is preferably used. By providing the insulator 250a, hydrogen contained in the oxide semiconductor 230 can be captured or fixed more effectively. Thus, the hydrogen concentration in the oxide semiconductor 230 can be lowered. As the insulator 250a, an insulator that can be used as the insulator 222 can be used. For the insulator 250a, for example, hafnium silicate or the like is preferably used. The insulator 250a in this case contains at least hafnium, silicon and oxygen. Alternatively, the insulator 250a preferably have an amorphous structure. As the insulator 250a, a single layer or stacked layers of any of the insulators described in the later-described section [Insulator] may be used.

When the insulator 250a has an amorphous structure, formation of a crystal grain boundary can be inhibited. Inhibiting the formation of a crystal grain boundary can increase the planarity of the film of the insulator 250a. This can make the thickness distribution of the insulator 250a uniform and reduce the number of extremely thin portions, so that the withstand voltage of the insulator 250a can be improved. In addition, the thickness distribution of a film provided over the insulator 250a can be uniform.

Moreover, inhibiting the formation of a crystal grain boundary in the insulator 250a can reduce leakage current due to the defect states in the crystal grain boundary. Thus, the insulator 250a can function as an insulating film with low leakage current.

Since hafnium oxide is a high permittivity (high-k) material, hafnium silicate becomes a high permittivity (high-k) material depending on the content of silicon. Accordingly, in the case where the insulator 250a is used as a gate insulator, a gate potential applied during the operation of the transistor can be reduced while the physical thickness of the gate insulator is maintained. In addition, the equivalent oxide thickness (EOT) of the insulator functioning as the gate insulator can be reduced.

The thickness of the insulator 250a is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 250a has a region with the above-described thickness. Here, since the insulator 250a has an amorphous structure, formation of a crystal grain boundary is reduced and the insulator 250a has high planarity. Thus, the insulator 250a can be a thin film with a high withstand voltage and reduced leakage current. Therefore, the insulator 250a is suitable for a gate insulator.

As the insulator 250b, a barrier insulator against hydrogen is preferably used. Accordingly, diffusion of impurities contained in the conductor 260 into the oxide semiconductor 230 can be inhibited. As the insulator 250b, an insulator that can be used as the insulator 210 and the insulator 283 can be used. For example, silicon nitride is suitable for the insulator 250b because of its high barrier property against hydrogen. In this case, the insulator 250b contains at least nitrogen and silicon. As the insulator 250b, a single layer or stacked layers of any of the insulators described in the later-described section [Insulator] may be used.

In the case where silicon nitride is used for the insulator 250b, the thickness of the insulator 250b is preferably greater than or equal to 2 nm, further preferably greater than or equal to 3 nm. Although there is no particular limitation on the upper limit of the thickness of the insulator 250b, for miniaturization or high integration of the semiconductor device, increased productivity of the semiconductor device, and the like, the thickness of the insulator 250b is preferably less than or equal to 20 nm, less than or equal to 10 nm, or less than or equal to 5 nm. Thus, the insulator 250b preferably includes a region with a thickness greater than or equal to 2 nm and less than or equal to 10 nm, further preferably includes a region with a thickness greater than or equal to 2 nm and less than or equal to 5 nm. The insulator 250b preferably includes a region with a thickness greater than or equal to 3 nm and less than or equal to 10 nm, further preferably includes a region with a thickness greater than or equal to 3 nm and less than or equal to 5 nm.

When the insulator 250b has a barrier property against hydrogen, the insulator 250b has a barrier property also against oxygen. The insulator 250b includes a region in contact with the conductor 260. Accordingly, the insulator 250b having a barrier property against oxygen can inhibit diffusion of oxygen contained in the oxide semiconductor 230 or the insulator 250a into the conductor 260 and thus oxidization of the conductor 260 can be inhibited. Furthermore, diffusion of oxygen contained in the oxide semiconductor 230 into the conductor 260 can be inhibited, and thus formation of oxygen vacancies in the oxide semiconductor 230 can be inhibited.

As the conductor 260, a single layer or stacked layers of any of the conductors described in the later-described section [Conductor] can be used. For example, a conductive material with high conductivity such as tungsten can be used for the conductor 260.

In addition, a conductive material that is less likely to be oxidized, a conductive material having a function of inhibiting diffusion of oxygen, or the like is preferably used for the conductor 260. Examples of the conductive material include a conductive material containing nitrogen (e.g., titanium nitride or tantalum nitride) and a conductive material containing oxygen (e.g., ruthenium oxide). This can inhibit a decrease in the conductivity of the conductor 260.

As illustrated in FIG. 4A and FIG. 4B, the conductor 260 may have a stacked-layer structure of a conductor 260a and a conductor 260b over the conductor 260a. In this case, titanium nitride may be used as the conductor 260a, and tungsten may be used as the conductor 260b, for example. When a layer including tungsten is provided in this manner, the conductivity of the conductor 260 can be improved and can serve well as the wiring.

Although FIG. 4A and FIG. 4B illustrate a structure in which the conductor 260 has a stacked-layer structure of two layers of the conductor 260a and the conductor 260b, the present invention is not limited thereto. The conductor 260 may have a stacked-layer structure of three or more layers.

As the insulator 283, a barrier insulator against hydrogen is preferably used. This can inhibit diffusion of hydrogen into the oxide semiconductor 230 from above the insulator 283. A silicon nitride film and a silicon nitride oxide film can be suitably used for the insulator 283 because the silicon nitride film and the silicon nitride oxide film release fewer impurities (e.g., water and hydrogen) and are less likely to transmit oxygen and hydrogen.

Silicon nitride formed by a sputtering method is particularly preferably used for the insulator 283. In that case, the insulator 283 contains silicon and nitrogen. Since a sputtering method does not need to use a molecule containing hydrogen in a film formation gas, the hydrogen concentration of the insulator 283 can be reduced. When the insulator 283 is formed by a sputtering method, high-density silicon nitride can be formed.

As illustrated in FIG. 4A and FIG. 4B, the insulator 283 may have a stacked-layer structure of an insulator 283a and an insulator 283b over the insulator 283a. Here, as the insulator 283a, an insulator having a function of capturing or fixing hydrogen is preferably used, and an insulator that can be used as the insulator 222 can be used as appropriate. For example, hafnium silicate can be used for the insulator 283a. As the insulator 283b, any of the above-described insulators having a barrier property against hydrogen is preferably used. That is, the insulator 283 has a stacked-layer structure of the insulator 283a having a function of capturing or fixing hydrogen and the insulator 283b that is a barrier insulator against hydrogen.

Such a structure can inhibit diffusion of hydrogen into the oxide semiconductor 230 from above the insulator 283. Here, the insulator 283a and the insulator 222 each having a function of capturing or fixing hydrogen are provided in a closed system formed of the insulator 283b and the insulator 210 each having a barrier property against hydrogen; thus, the hydrogen concentration in the oxide semiconductor 230 can be reduced.

Although the insulator 280 being a single layer is illustrated in FIG. 1B, FIG. 1C, FIG. 4A, and FIG. 4B, the present invention is not limited thereto. The insulator 280 may have a stacked-layer structure.

For example, as illustrated in FIG. 6A, the insulator 280 may have a stacked-layer structure of an insulator 280a, an insulator 280b over the insulator 280a, and an insulator 280c over the insulator 280b.

The insulator 280a includes a region in contact with the top surface of the insulator 210, a region in contact with the side surface of the conductor 220, and a region in contact with the top surface of the conductor 220. The insulator 280c includes a region in contact with the bottom surface of the conductor 240.

FIG. 6B illustrates an example in which an insulator 223 having a function of capturing or fixing hydrogen and an insulator 221 having a barrier property against hydrogen are provided between the oxide semiconductor 230 and the insulator 280 in addition to the structure illustrated in FIG. 6A.

As the insulator 223, an insulator that can be used as the insulator 222 can be used. For example, hafnium silicate can be used. Accordingly, diffusion of hydrogen into the oxide semiconductor 230 can be inhibited, and the hydrogen concentration in the oxide semiconductor 230 can be further reduced.

The thickness of the insulator 223 (e.g., the width of the insulator 223 in the A1-A2 direction) is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 223 has a region with the above-described width.

As illustrated in FIG. 6B, the insulator 221 is provided between the insulator 280 and the insulator 223. Portions of the insulator 221, the insulator 223, the oxide semiconductor 230, the insulator 250, and the conductor 260 that are placed in the opening portion 290 reflect the shape of the opening portion 290. Thus, the insulator 221 is provided to cover the sidewall of the opening portion 290, the insulator 223 is provided to cover the side surface of the insulator 221, the oxide semiconductor 230 is provided to cover the side surface of the insulator 223 and the bottom portion of the opening portion 290, the insulator 250 is provided to cover the oxide semiconductor 230, and the conductor 260 is provided to fill a depressed portion of the insulator 250 reflecting the shape of the opening portion 290.

As the insulator 221, an insulator that can be used as the insulator 210 can be used. For example, silicon nitride can be used. Accordingly, diffusion of hydrogen into the oxide semiconductor 230 can be inhibited, and the hydrogen concentration in the oxide semiconductor 230 can be further reduced.

In the case where silicon nitride is used for the insulator 221, the thickness of the insulator 221 (e.g., the width of the insulator 221 in the A1-A2 direction) is preferably greater than or equal to 2 nm, further preferably greater than or equal to 3 nm. Although there is no particular limitation on the upper limit of the thickness of the insulator 221, for miniaturization or high integration of the semiconductor device, increased productivity of the semiconductor device, and the like, the thickness of the insulator 221 is preferably less than or equal to 20 nm, less than or equal to 10 nm, or less than or equal to 5 nm. Thus, the insulator 221 preferably includes a region with a thickness greater than or equal to 2 nm and less than or equal to 10 nm, further preferably includes a region with a thickness greater than or equal to 2 nm and less than or equal to 5 nm. The insulator 221 preferably includes a region with a thickness greater than or equal to 3 nm and less than or equal to 10 nm, further preferably includes a region with a thickness greater than or equal to 3 nm and less than or equal to 5 nm.

In the case of the structure illustrated in FIG. 6B, the insulator 280b may be formed using a material with a low relative permittivity, for example. When a material with a low relative permittivity is used for the insulator 280b, the parasitic capacitance between wirings that sandwich insulator 280b can be reduced. As the insulator 280b, a single layer or stacked layers of any of insulators each including a material with a low relative permittivity described in the later-described section of [Insulator] can be used. Specifically, for the insulator 280b, silicon oxide or silicon oxynitride can be used. The concentration of impurities such as water and hydrogen in the insulator 280b is preferably reduced. This can inhibit entry of impurities such as water and hydrogen into the channel formation region of the oxide semiconductor 230.

In the case where an insulator containing oxygen is used as the insulator 280b, any of barrier insulators against oxygen in the later-described section [Insulator] is preferably used as each of the insulator 280a and the insulator 280c. The insulator 280a provided between the insulator 280b and the conductor 220 can inhibit oxidation of the conductor 220 and an increase in the resistance of the conductor 220. Furthermore, the insulator 280c provided between the insulator 280b and the conductor 240 can inhibit oxidation of the conductor 240 and an increase in the resistance of the conductor 240.

As each of the insulator 280a and the insulator 280c, a barrier insulator against hydrogen is preferably used. Thus, the insulator 280b can be surrounded by barrier insulators against hydrogen (here, the insulator 280a, the insulator 280c, and the insulator 221). This can inhibit diffusion of hydrogen contained in the insulator 280b into the oxide semiconductor 230. A silicon nitride film and a silicon nitride oxide film can be suitably used for the insulator 280a and the insulator 280c because the silicon nitride film and the silicon nitride oxide film release fewer impurities (e.g., water and hydrogen) and are less likely to transmit oxygen and hydrogen. For the insulator 280a and the insulator 280c, the same material or different materials may be used.

As the insulator 280a, an insulator having a function of capturing or fixing hydrogen may be used. With such a structure, diffusion of hydrogen from below the insulator 280a into the oxide semiconductor 230 can be inhibited, and hydrogen contained in the oxide semiconductor 230 can be captured or fixed. Thus, the hydrogen concentration in the oxide semiconductor 230 can be reduced. For the insulator 280a, magnesium oxide, aluminum oxide, hafnium oxide, an oxide containing hafnium and silicon, or the like can be used. For another example, a stacked-layer film of aluminum oxide and silicon nitride over the aluminum oxide may be used as the insulator 280a. Note that an insulator having a function of capturing or fixing hydrogen may be used as the insulator 280c.

For example, silicon nitride can be used for the insulator 280a and the insulator 280c, and silicon oxide can be used for the insulator 280b. In that case, each of the insulator 280a and the insulator 280c contains at least silicon and nitrogen. The insulator 280b contains at least silicon and oxygen.

Although FIG. 6A and FIG. 6B illustrate the structure in which the insulator 280c is provided over the planarized insulator 280b, the present invention is not limited thereto. For example, the insulator 280c may be formed without performing planarization treatment on the insulator 280b. When planarization treatment is not performed, the manufacturing cost can be reduced and the production yield can be increased. In addition, the insulator 280a, the insulator 280b, and the insulator 280c can be successively formed without exposure to the air. By the formation without exposure to the air, impurities or moisture from the atmospheric environment can be prevented from being attached onto the insulator 280a to the insulator 280c, so that the vicinity of the interface between the insulator 280a and the insulator 280b and the vicinity of the interface between the insulator 280b and the insulator 280c can be kept clean.

Although FIG. 6A and FIG. 6B illustrate a structure in which the insulator 280 has a stacked-layer structure of three layers, the present invention is not limited thereto. The insulator 280 may have a stacked-layer structure of two layers or four or more layers.

In FIG. 6A, the insulator 280b is in contact with at least part of the oxide semiconductor 230. As the insulator 280b, an insulator containing oxygen is preferably used. The insulator 280b preferably includes a region having a higher oxygen content than at least one of the insulator 280a and the insulator 280c. In particular, the insulator 280b preferably includes a region having a higher oxygen content than each of the insulator 280a and the insulator 280c. When the insulator 280b has a high oxygen content, an i-type region can be easily formed in the oxide semiconductor 230 in the vicinity of the insulator 280b. Furthermore, oxygen supplied from the insulator 280b to the channel formation region of the oxide semiconductor 230 can trap electrons and form negative charge (negative fixed charge) in the channel formation region. Thus, the substrate bias effect can be exhibited, so that the transistor can have normally-off characteristics.

It is further preferable that a film from which oxygen is released by heating be used as the insulator 280b. When the insulator 280b releases oxygen by being heated during the fabrication process of the transistor 200, the oxygen can be supplied to the oxide semiconductor 230. Supply of oxygen from the insulator 280b to the oxide semiconductor 230, particularly to the channel formation region of the oxide semiconductor 230, can reduce oxygen vacancies and VoH in the oxide semiconductor 230, so that the transistors can have favorable electrical characteristics and high reliability. As described above, oxygen supplied from the insulator 280b to the oxide semiconductor 230 can form negative charge (negative fixed charge) in the channel formation region; thus, the transistor can have normally-off characteristics.

In order to improve the electrical characteristics and reliability of the OS transistor, it is important to sufficiently reduce the hydrogen concentration in the oxide semiconductor and optimize the amount of oxygen supplied to the oxide semiconductor.

For example, the amount of oxygen molecules released from the insulator 280b is preferably greater than or equal to 1.0×10¹⁴ molecules/cm² and less than 1.0×10¹⁵ molecules/cm². Note that the amount of released oxygen molecules can be measured by thermal desorption spectrometry.

Particularly in the case where the channel length of the transistor 200 is short, oxygen vacancies and VoH in the channel formation region significantly affect electrical characteristics and reliability. Accordingly, when the amount of oxygen supplied to the oxide semiconductor 230 is optimized while the hydrogen concentration in the oxide semiconductor 230 is sufficiently reduced, the transistor can have a short channel length, favorable electrical characteristics, and high reliability.

The insulator 280b is preferably formed by a film formation method such as a sputtering method or a PECVD method. It is particularly preferable to employ a sputtering method, in which a hydrogen gas does not need to be used as a film formation gas, to form a film having an extremely low hydrogen content. Thus, supply of hydrogen to the oxide semiconductor 230 is inhibited and the electrical characteristics of the transistor 200 can be stabilized.

In the case where the amount of oxygen supplied to the oxide semiconductor 230 is increased, heat treatment in an oxygen-containing atmosphere or plasma treatment in an oxygen-containing atmosphere is preferably performed after formation of the insulator 280b, for example. Alternatively, an oxide film may be formed over the top surface of the insulator 280b by a sputtering method in an oxygen atmosphere to supply oxygen. After that, the oxide film may be removed. Such treatment can supply oxygen to the insulator 280b and increase the amount of oxygen supplied to the oxide semiconductor 230.

A region of the oxide semiconductor 230 that is in contact with the insulator 280a and a region of the oxide semiconductor 230 that is in contact with the insulator 280c are supplied with a smaller amount of oxygen than a region of the oxide semiconductor 230 that is in contact with the insulator 280b. Thus, the region of the oxide semiconductor 230 that is in contact with the insulator 280a and the region of the oxide semiconductor 230 that is in contact with the insulator 280c have lower resistance than the region of the oxide semiconductor 230 that is in contact with the insulator 280b in some cases. That is, by adjusting the thickness of the insulator 280a, the range of the region functioning as one of the source region and the drain region can be controlled. Similarly, by adjusting the thickness of the insulator 280c, the range of the region functioning as the other of the source region and the drain region can be controlled. Accordingly, the thicknesses of the insulator 280a and the insulator 280c can be set as appropriate in accordance with the characteristics required for the transistor 200.

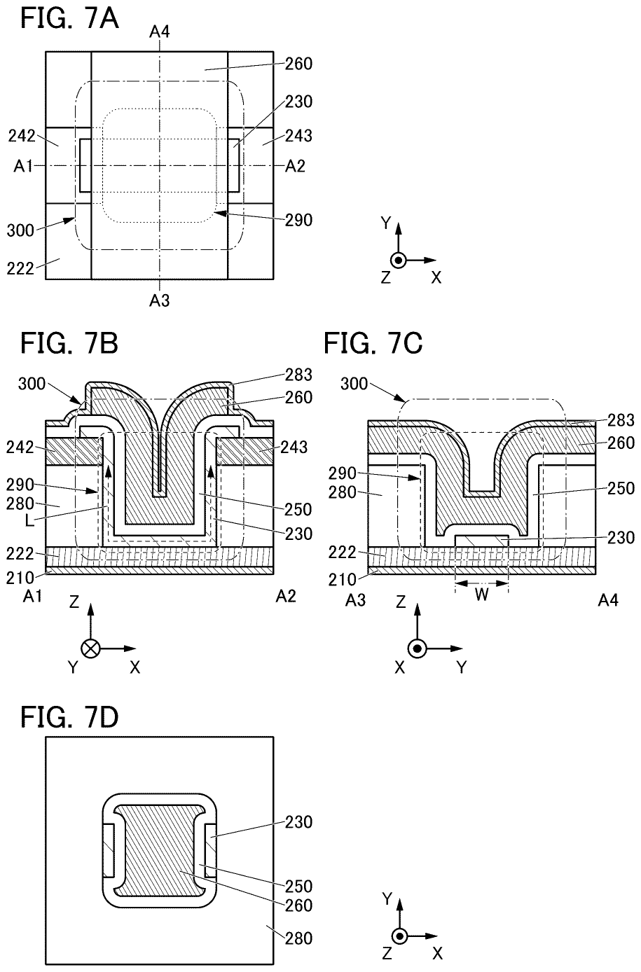

FIG. 7A to FIG. 7D illustrate another example of the semiconductor device of one embodiment of the present invention. FIG. 7A to FIG. 7D are a top view and cross-sectional views of the semiconductor device including a transistor 300. FIG. 7A is a plan view of the semiconductor device. FIG. 7B to FIG. 7D are cross-sectional views of the semiconductor device. FIG. 7B is a cross-sectional view of a portion indicated by the dashed-dotted line A1-A2 in FIG. 7A. FIG. 7C is a cross-sectional view of a portion indicated by the dashed-dotted line A3-A4 in FIG. 7A. FIG. 7D is a cross-sectional view along the XY plane including the insulator 280. Note that some components are omitted in the plan view of FIG. 7A for clarity of the drawing.

The semiconductor device illustrated in FIG. 7A to FIG. 7D includes the insulator 210 over a substrate (not illustrated), the insulator 222 over the insulator 210, the transistor 300 over the insulator 222, the insulator 280 over the insulator 210, and the insulator 283 over the transistor 300.

The transistor 300 includes an conductor 242 and an conductor 243 over the insulator 280, the oxide semiconductor 230, the insulator 250 over the oxide semiconductor 230, and the conductor 260 over the insulator 250.

The shape of the oxide semiconductor 230 in the semiconductor device illustrated in FIG. 7A to FIG. 7D is different from that in the semiconductor device illustrated in FIG. 1A to FIG. 1C. The semiconductor device illustrated in FIG. 7A to FIG. 7D is different from the semiconductor device illustrated in FIG. 1A to FIG. 1C in that the conductor 220 is not provided and the conductor 242 and the conductor 243 are provided instead of the conductor 240. Differences from the description with reference to FIG. 1A to FIG. 1C are mainly described below; the description is referred to for the same portions and the description of the same portion is omitted in some cases.

The oxide semiconductor 230, the insulator 250, and the conductor 260 are provided in the opening portion 290 of the insulator 280. In the opening portion 290, the side surface of the insulator 280 includes a region in contact with the oxide semiconductor 230 and a region in contact with the insulator 250. Here, in the case where the insulator 250 has a stacked-layer structure of the insulator 250a and the insulator 250b as in FIG. 4A and the like, part of the side surface of the insulator 280 is in contact with the insulator 250a having a function of capturing or fixing hydrogen.

As illustrated in FIG. 7B and FIG. 7C, the oxide semiconductor 230 includes a region in contact with the bottom portion of the opening portion 290. In other words, the bottom surface of the oxide semiconductor 230 in the opening portion 290 is in contact with the insulator 222.

Although the conductor 242 and the conductor 243 each have a single-layer structure in FIG. 7B and FIG. 7C, the present invention is not limited thereto. The conductor 242 and the conductor 243 can each have a stacked-layer structure of two or more layers. For example, in the case where the conductor 242 and the conductor 243 each have a two-layer structure, the first-layer conductor can have a structure similar to that of the conductor 240a. The second-layer conductor can have a structure similar to that of the conductor 240b.

In the transistor 300, the oxide semiconductor 230 functions as a semiconductor layer, the conductor 260 functions as a gate electrode, the insulator 250 functions as a gate insulator, the conductor 242 functions as one of a source electrode and a drain electrode, and the conductor 243 functions as the other of the source electrode and the drain electrode.

In the semiconductor device illustrated in FIG. 7A to FIG. 7D, the oxide semiconductor 230, the insulator 250, and the conductor 260 are provided in this order in the opening portion of the insulator 280.

The oxide semiconductor 230 is provided to be at least partly positioned in the opening portion 290. The transistor 300 has a structure in which current flows from one of the source electrode and the drain electrode (e.g., the conductor 242) to the other of the source electrode and the drain electrode (e.g., the conductor 243). That is, the channel length of the transistor 300 (a length L indicated by the dashed double-headed arrow in FIG. 7B) is the sum of the double of the length of the side surface of the insulator 280 in the opening portion 290 and the length of the bottom portion of the opening portion 290. Note that the length of the side surface of the insulator 280 in the opening portion 290 is the thickness of the insulator 280. The length of the bottom portion of the opening portion 290 is, for example, the shortest distance between the conductor 242 and the conductor 243. Thus, the channel length (the length L) of the transistor 300 can be adjusted by the length of the side surface of the insulator 280 in the opening portion 290 and the length of the bottom portion of the opening portion 290. For example, in the case where the channel length is increased while miniaturization or high integration of the semiconductor device is achieved, the thickness of the insulator 280 is preferably made large.

The channel width of the transistor 300 (a length W indicated by the dashed double-dotted double-headed arrow in FIG. 7C) corresponds to the width of the oxide semiconductor 230 in the Y direction in a plan view. Thus, the channel width of the transistor 300 is preferably smaller than the width of the bottom portion of the opening portion 290.

Note that FIG. 7A and FIG. 7D illustrate an example in which the opening portion of the insulator 280 has a quadrangular shape with rounded corners in a plan view. In that case, the maximum width of the opening portion is calculated as appropriate in accordance with the shape of the uppermost portion of the opening portion. For example, in the case where the opening portion has a quadrangular shape with rounded corners in a plan view, the maximum width of the opening portion is preferably the length of a diagonal line or the distance between opposite sides of the uppermost portion of the opening portion, assuming it to be a rectangle. Note that the present invention is not limited thereto. For example, the opening portion 290 in the plan view may have a circular shape, a substantially circular shape such as an elliptical shape, a polygonal shape, or a polygonal shape with rounded corners.

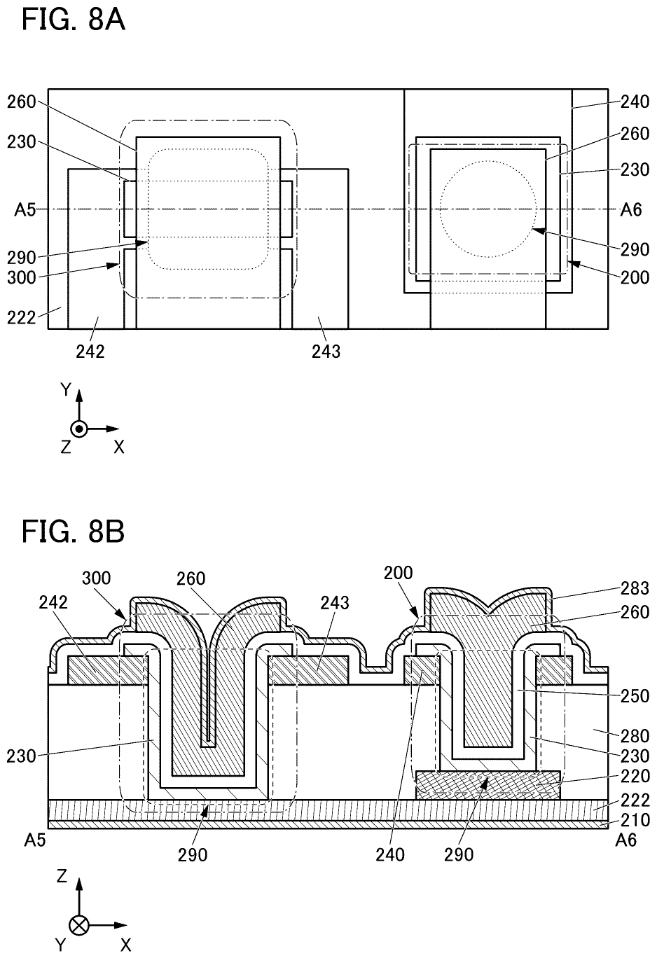

Note that as illustrated in FIG. 8A and FIG. 8B, the transistor 300 illustrated in FIG. 7A to FIG. 7D and the transistor 200 illustrated in FIG. 1A to FIG. 1C can be fabricated over the same layer (here, the insulator 222). That is, the transistor 300 can be fabricated at the same time as the fabrication process of the transistor 200. Thus, two transistors with different channel lengths and different channel widths can be provided over the same layer. As described above, the semiconductor device of one embodiment of the present invention offers such an excellent effect that transistors with different channel lengths over the same layer can be freely designed by the thickness of the insulating layer and patterning. When the transistor 200 and the transistor 300 are fabricated at the same time, negative charge can be concurrently formed not only in the channel formation region of the transistor 200 but also in part of the channel formation region (a region where the oxide semiconductor 230 and the insulator 280 are in contact with each other in the channel length direction) of the transistor 300. FIG. 8A is a plan view of the semiconductor device. FIG. 8B is a cross-sectional view of the semiconductor device, and is a cross-sectional view of a portion indicated by the dashed-dotted line A5-A6 in FIG. 8A.

### <Material for Semiconductor Device>

Materials that can be used for the semiconductor device are described below.

### [Substrate]

As the substrate where the transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material, or a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a material with a low relative permittivity is used for the insulator functioning as an interlayer film, parasitic capacitance generated between wirings can be reduced. Thus, a material is preferably selected in accordance with the function of the insulator. Note that the material with a low relative permittivity is a material with high dielectric strength.

Examples of the material with a high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low relative permittivity include silicon oxide to which fluorine is added, silicon oxide to which carbon is added, and silicon oxide to which carbon and nitrogen are added. Another example is porous silicon oxide. These silicon oxides may contain nitrogen.

Alternatively, a material that can have ferroelectricity may be used for the insulator. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or in the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may also be used.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used.

Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor layer or provided in the vicinity of the semiconductor layer, such as a gate insulator, preferably includes a region containing oxygen that is released by heating (excess oxygen). For example, when an insulator including a region including excess oxygen is in contact with the semiconductor layer or provided in the vicinity of the semiconductor layer, the number of oxygen vacancies in the semiconductor layer can be reduced. Moreover, when oxygen supplied to the semiconductor layer (in particular, the channel formation region) traps electrons, negative charge (negative fixed charge) can be formed in the channel formation region. Examples of an insulator in which a region containing excess oxygen is easily formed include silicon oxide, silicon oxynitride, and porous silicon oxide.

Examples of the barrier insulator against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate)

The above description can be referred to for a barrier insulator against hydrogen.

The barrier insulator against oxygen and the barrier insulator against hydrogen can each be regarded as a barrier insulator against one or both of oxygen and hydrogen.

The above description can be referred to for an insulator having a function of capturing or fixing hydrogen.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting diffusion of oxygen, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. A stacked-layer structure combining a material containing the above metal element and a conductive material containing nitrogen may also be employed. A stacked-layer structure combining a material containing the above metal element, a conductive material containing oxygen, and a conductive material containing nitrogen may also be employed.

In the case where a metal oxide is used for the channel formation region of the transistor, the conductor functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor may cause unstable electrical characteristics of the transistor. Hence, a metal oxide used in a semiconductor layer of a transistor preferably has a small number of lattice defects.

The kind of a lattice defect that is likely to exist in a metal oxide and the number of lattice defects that exist vary depending on the structure of the metal oxide, a method for forming the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. An a-like structure has a structure between an nc structure and an amorphous structure.

A metal oxide having an a-like structure and a metal oxide having an amorphous structure each include a void or a low-density region. That is, the metal oxide having the a-like structure and the metal oxide having the amorphous structure have lower crystallinity than a metal oxide having an nc structure and a metal oxide having a CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Therefore, a metal oxide with high crystallinity is preferably used for a semiconductor layer of a transistor. For example, it is preferable to use the metal oxide having the CAAC structure or the metal oxide having the single crystal structure. The use of such a metal oxide for a transistor enables the transistor having favorable electrical characteristics. In addition, a transistor with high reliability can be obtained.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, and a CAAC-OS.

The c-axis of the above crystal is preferably aligned in the normal direction with respect to the surface where the metal oxide is formed or the film surface of the metal oxide. This enables the plurality of layers to be placed parallel or substantially parallel to the surface where the metal oxide is formed or the film surface of the metal oxide. That is, the plurality of layers extend in the channel length direction.

The above three-layer crystal structure is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal include a YbFe₂O₄ type structure, a Yb₂Fe₃O₇ type structure, and variant structures of these structures.

Each of the first layer to the third layer is preferably composed of oxygen and one metal element or a plurality of metal elements with the same valence. The valences of the one or plurality of metal elements included in the first layer are preferably equal to the valences of the one or plurality of metal elements included in the second layer. The first layer and the second layer may include the same metal element. The valences of the one or plurality of metal elements included in the first layer are preferably different from the valences of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, the element M, and zinc. Note that the element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may include a metalloid element.

For example, as the metal oxide of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table of the elements. Alternatively, the metal oxide may contain, in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, an In—Ga—Zn oxide is sometimes taken as an example of the metal oxide.

For the formation of a metal oxide having the layered crystal structure, an atomic layer is preferably deposited one by one. Since an ALD method is used as the film formation method of a metal oxide in one embodiment of the present invention, a metal oxide having the layered crystal structure is easily formed.

### [[Transistor Including Metal Oxide]]

Next, the case where a metal oxide (oxide semiconductor) is used for a transistor is described.

When a metal oxide (oxide semiconductor) of one embodiment of the present invention is used for a transistor, a transistor with high field-effect mobility can be achieved. In addition, a transistor with high reliability can be obtained. Furthermore, a miniaturized or highly integrated transistor can be achieved. For example, a transistor with a channel length greater than or equal to 2 nm and less than or equal to 30 nm can be fabricated.

An oxide semiconductor with a low carrier concentration is preferably used for a channel formation region of the transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

Meanwhile, as in the transistor of one embodiment of the present invention, a transistor having normally-off characteristics can sometimes be obtained in such a manner that fixed charge is formed by addition of impurities to the oxide semiconductor and the substrate bias effect is exhibited by the fixed charge.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current of the transistor (also referred to as Ioff) can be reduced.

In a Si transistor, a short-channel effect is exhibited as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a large band gap, and thus the short-channel effect can be suppressed. In other words, a short-channel effect does not appear or hardly appears in an OS transistor.

Note that the short-channel effect refers to degradation of electrical characteristics which becomes obvious along with miniaturization (a decrease in channel length) of a transistor. Specific examples of the short-channel effect include a decrease in threshold voltage, an increase in subthreshold swing value (sometimes referred to as an S value), and an increase in leakage current. Here, the S value means the amount of change in gate voltage in the subthreshold region when the drain voltage keeps constant and the drain current changes by one order of magnitude. The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be fabricated, the OS transistor is more suitable than the Si transistor.

Even in the case where the carrier concentration of the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor having the above structure enables a semiconductor device to have favorable electrical characteristics even when the semiconductor device is miniaturized or highly integrated. For example, favorable electrical characteristics can be obtained even when the OS transistor has a channel length or a gate length greater than or equal to 1 nm and less than or equal to 20 nm, greater than or equal to 3 nm and less than or equal to 15 nm, greater than or equal to 5 nm and less than or equal to 10 nm, greater than or equal to 5 nm and less than or equal to 7 nm, or greater than or equal to 5 nm and less than or equal to 6 nm. In contrast, it is sometimes difficult for the Si transistor to have a gate length less than or equal to 20 nm or less than or equal to 15 nm due to appearance of the short-channel effect. Therefore, the OS transistor can be used as a transistor having a short channel length more suitably the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor is advantageous over the Si transistor in that the off-state current is low and a transistor having a short channel length can be fabricated.

### [[Impurity in Metal Oxide]]

Here, the influence of each impurity in the metal oxide (oxide semiconductor) is described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, further preferably lower than or equal to 3×10¹⁸ atoms/cm³, and further preferably lower than or equal to 1×10¹⁸ atoms/cm³ . The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, further preferably lower than or equal to 3×10¹⁸ atoms/cm³, and further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen for a semiconductor layer is likely to have normally-on characteristics. When the oxide semiconductor contains nitrogen, trap states are sometimes formed. This might make the electrical characteristics of the transistor unstable. Therefore, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, and further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Thus, a transistor including an oxide semiconductor that contains an alkali metal or an alkaline earth metal is likely to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### [Other Semiconductor Materials]

The oxide semiconductor 230 can be rephrased as a semiconductor layer including a channel formation region of the transistor. The semiconductor material that can be used for the semiconductor layer is not limited to the above metal oxides. A semiconductor material that has a band gap (a semiconductor material that is not a zero-gap semiconductor) may be used for the semiconductor layer. For example, a semiconductor material such as a single element semiconductor, a compound semiconductor, or a layered substance (also referred to as an atomic layer substance, a two-dimensional material, or the like) is preferably used.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon atoms, nitrogen atoms, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide which can be used for a semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a semiconductor device with a high on-state current to be provided.

### <Example of Method for Manufacturing Semiconductor Device>

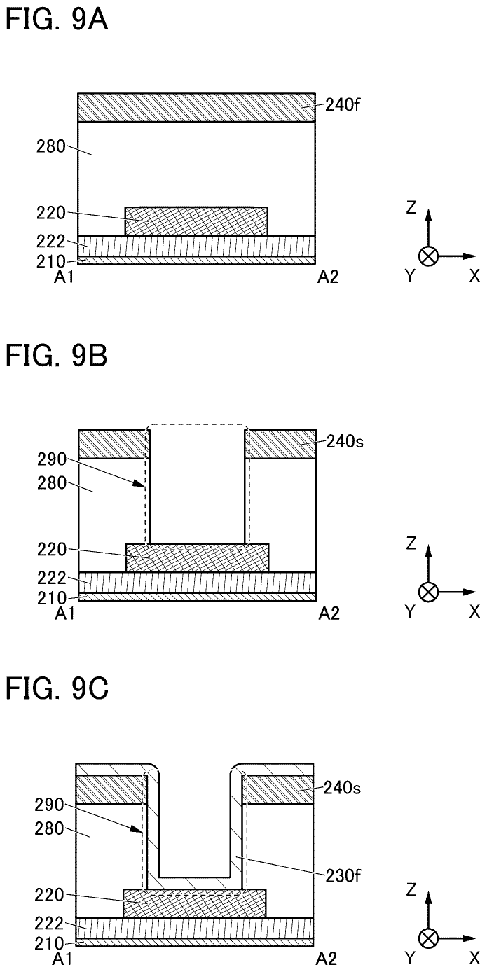

Next, a method for fabricating the transistor 200 illustrated in FIG. 1A to FIG. 1C and the like is described with reference to FIG. 9A to FIG. 13B. Note that FIG. 9A to FIG. 10B and FIG. 12A to FIG. 13B correspond to FIG. 1B.

Hereinafter, an insulating material for forming an insulator, a conductive material for forming a conductor, or a semiconductor material for forming a semiconductor can be formed by a sputtering method, a CVD method, a molecular beam epitaxy (MBE) method, a pulsed laser deposition (PLD) method, an ALD method, and the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is formed by a reactive sputtering method.

Note that the CVD method can be classified into a plasma enhanced CVD (PECVD) method utilizing plasma, a thermal CVD (TCVD) method utilizing heat, a photo CVD method utilizing light, and the like. Moreover, the CVD method can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, a thermal CVD method, which does not use plasma, does not cause such plasma damage, and thus can increase the yield of the semiconductor device. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are film formation methods that enable favorable step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low film formation rate, and thus is preferably used in combination with another film formation method with a high film formation rate, such as a CVD method, in some cases.

By a CVD method, a film with a certain composition can be formed depending on the flow rate ratio of the source gases. For example, by the CVD method, a film whose composition is continuously changed can be formed by changing the flow rate ratio of the source gases during film formation. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By an ALD method, a film with a certain composition can be formed by introducing different kinds of precursors. For example, in the case where different kinds of precursors are introduced, a film with a certain composition can be formed by controlling the number of cycles for each of the precursors.

In the case where different kinds of precursors are introduced by an ALD method, the kind of oxidizer may be changed depending on each precursor. For example, in the case where at least a first precursor and a second precursor are introduced, ozone (O₃) may be used as an oxidizer for the first precursor and oxygen (O₂) may be used as an oxidizer for the second precursor.

In addition, heat treatment may be performed before formation of a film. This heat treatment may be performed under reduced pressure, and the film may be successively formed without exposure to the air. Such treatment can remove moisture and hydrogen adsorbed onto the surface over which the film is to be formed, and further can reduce the moisture concentration and the hydrogen concentration in a structural element that serves as the surface over which the film is to be formed. The temperature of the heat treatment is preferably higher than or equal to 100° C. and lower than or equal to 600° C.

First, a substrate (not illustrated) is prepared, and the insulator 210 is formed over the substrate (see FIG. 9A). The insulator 210 can be formed by a sputtering method, a CVD method, an MBE method, a PLD method, an ALD method, or the like as appropriate. A silicon nitride film can be formed as the insulator 210 by a sputtering method, for example.

Next, the insulator 222 is formed over the insulator 210 (see FIG. 9A). The insulator 222 can be formed by a sputtering method, a CVD method, an MBE method, a PLD method, an ALD method, or the like as appropriate. A hafnium silicate can be formed as the insulator 222 by a sputtering method, for example. In that case, a film formation target containing hafnium and silicon can be used. For example, a co-sputtering method using a silicon oxide target and a hafnium oxide target can be used. Alternatively, the insulator 222 may be formed by a thermal ALD method. For example, hafnium tetrachloride and silicon tetrachloride can be used as precursors. For another example, after a hafnium oxide film is formed, silicon may be added to the hafnium oxide film to form a hafnium silicate film. As a method for adding silicon, an ion implantation method in which an ionized source gas is subjected to mass separation and then added, an ion doping method in which an ionized source gas is added without mass separation, or the like can be used, for example.

Next, the conductor 220 is formed over the insulator 222 (see FIG. 9A). As the conductor 220, a conductive film is formed over the insulator 222 and the conductive film is patterned by a lithography method. The conductive film can be formed by a sputtering method, a CVD method, an MBE method, a PLD method, an ALD method, or the like as appropriate. For example, as the conductive film, a tungsten film can be formed by a sputtering method, and an ITSO film is formed thereover by a sputtering method.

Next, the insulator 280 is formed over the insulator 222 and the conductor 220 (see FIG. 9A). Any of the above-described insulating materials can be used for the insulator 280 as appropriate. The insulator 280 can be formed by a sputtering method, a CVD method, an MBE method, a PLD method, an ALD method, or the like as appropriate. For example, as the insulator 280, a silicon nitride film can be formed by a sputtering method. The top surface of the formed insulator 280 is preferably planarized by CMP treatment. The planarization treatment for the insulator 280 enables favorable formation of the conductor 240 functioning as a wiring.

The CMP treatment may be skipped in some cases. In that case, the top surface of the insulator 280 has an upward-convex curved surface shape. By not performing planarization treatment, manufacturing cost can be reduced and production yield can be increased.

Note that in the case where the insulator 280 has a three-layer structure of the insulator 280a, the insulator 280b, and the insulator 280c as illustrated in FIG. 6A and FIG. 6B, planarization treatment is not necessarily performed after the insulator 280a to the insulator 280c are formed. For example, planarization treatment may be performed after the insulator 280a and the insulator 280b are formed, and then the insulator 280c may be formed.

By using a sputtering method that does not need to use a molecule containing hydrogen as a film formation gas for the formation of the insulator 280, the hydrogen concentration in the insulator 280 can be reduced. When the insulator 280 is formed in this manner, the amount of hydrogen diffused from the insulator 280 into the oxide semiconductor 230 can be reduced, and thus oxygen vacancies and VoH in the channel formation region can be reduced.

Next, a conductive film 240f is formed over the insulator 280 (see FIG. 9A). Any of the above-described conductive materials can be used for the conductive film 240f as appropriate. The conductive film 240f can be formed by a sputtering method, a CVD method, an MBE method, a PLD method, an ALD method, or the like as appropriate. For example, as the conductive film 240f, a ruthenium film is formed by a sputtering method, and an ITSO film can be formed thereover by a sputtering method.

Next, part of the conductive film 240f and part of the insulator 280 are processed to form the opening portion 290 reaching the conductor 220 (see FIG. 9B). The opening portion 290 can be formed by a lithography method. By the processing, a conductor 240s is formed from the conductive film 240f.

In the lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that the use of a mask may be unnecessary in the case of using an electron beam or an ion beam.

A dry etching method is preferably used for the etching treatment for forming the opening portion 290. A dry etching method enables anisotropic etching and thus is suitable for forming the opening portion 290 with a high aspect ratio.

Here, as an etching gas for the dry etching treatment, an etching gas containing a halogen can be used, and specifically, an etching gas containing one or more of fluorine, chlorine, and bromine can be used. As the etching gas, for example, a C₄F₆ gas, a CsF₆ gas, a C₄F₈ gas, a CF₄ gas, an SF₆ gas, a CHF₃ gas, a CH₂F₂ gas, a CH₃F gas, a Cl₂ gas, a BCl₃ gas, a SiCl₄ gas, a CCl₄ gas, an HBr gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. Depending on an object to be subjected to the dry etching treatment, a gas that contains a hydrocarbon gas or a hydrogen gas and does not contain a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure where a high-frequency voltage is applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Such a CCP etching apparatus is referred to as a dual frequency capacitively coupled plasma (DF-CCP) etching apparatus. In the DF-CCP etching apparatus, high-frequency voltages with different frequencies are applied to the parallel plate electrodes. Alternatively, a structure may be employed in which high-frequency voltages with different frequencies are applied to one of the parallel plate electrodes. Alternatively, a dry etching apparatus including a high-density plasma source can be used. As the dry etching apparatus including a high-density plasma source, an inductively coupled plasma (ICP) etching apparatus or the like can be used, for example. The etching apparatus can be set as appropriate depending on an object to be etched.

Note that the formation of the opening portion 290 (the processing of part of the conductive film 240f and the processing of part of the insulator 280) is preferably performed successively without exposure to the air. For example, the processing is performed without exposure to the air by using a multi-chamber etching apparatus.

Note that the opening portion 290 is not necessarily formed such that the top surface of the conductor 220 is flat. In that case, a depressed portion overlapping with the opening portion 290 is formed on the top surface of the conductor 220, whereby the transistor 200 illustrated in FIG. 4A to FIG. 4B can be formed.

Next, microwave treatment may be performed in an oxygen-containing atmosphere to reduce the impurity concentration in the insulator 280. Here, the microwave treatment refers to, for example, treatment using an apparatus including a power source that generates high-density plasma with the use of a microwave. In this specification and the like, a microwave refers to an electromagnetic wave having a frequency higher than or equal to 300 MHz and lower than or equal to 300 GHz. Specific examples of the impurity include hydrogen and carbon. When the insulator 280 is subjected to microwave treatment in an oxygen-containing atmosphere, hydrogen contained in the insulator 280 can be released as H₂O to the outside. Release of hydrogen from the insulator 280 positioned in the vicinity of the oxide semiconductor 230 enables formation of a highly reliable semiconductor device.

The microwave treatment in an oxygen-containing atmosphere converts an oxygen gas into plasma using a high-frequency wave such as a microwave or RF and the oxygen plasma can be applied. When oxygen plasma is applied to the insulator 280 in this manner, hydrogen contained in the insulator 280 can be released as H₂O to the outside. In addition, the side surface of the insulator 280 in the opening portion 290 is oxidized by the oxygen plasma treatment in some cases. In such cases, when the oxide semiconductor 230 is formed in contact with the insulator 280, heat treatment or the like can be performed to supply oxygen from the insulator 280 to the channel formation region of the oxide semiconductor 230. Thus, oxygen vacancies and VoH in the channel formation region of the oxide semiconductor 230 can be reduced. Thus, the transistor 200 can have stable electrical characteristics and increased reliability. Oxygen that acts on the insulator 280 has any of a variety of forms such as an oxygen atom, an oxygen molecule, an oxygen ion, and an oxygen radical (also referred to as O radical, which is an atom, a molecule, or an ion having an unpaired electron). The oxygen that acts on the insulator 280 has any one or more of the above forms, particularly suitably an oxygen radical.

The above-described microwave treatment in an oxygen-containing atmosphere is preferably performed while the substrate is heated, in which case the impurity concentration in the insulator 280 can be further reduced. The substrate heating temperature is higher than or equal to 100° C. and lower than or equal to 650° C., preferably higher than or equal to 200° C. and lower than or equal to 600° C., further preferably higher than or equal to 300° C. and lower than or equal to 450° C. The microwave treatment is preferably performed under reduced pressure, and the pressure is preferably higher than or equal to 10 Pa and lower than or equal to 1000 Pa, further preferably higher than or equal to 300 Pa and lower than or equal to 700 Pa.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The impurity concentration in the insulator 280 can be reduced by thus performing the microwave treatment in an oxygen-containing atmosphere. In addition, preventing introduction of an excess amount of oxygen into the insulator 280 in the microwave treatment can prevent an excessive reduction of the carrier concentration in the oxide semiconductor 230.

Here, the frequency of the microwave treatment apparatus is preferably higher than or equal to 300 MHz and lower than or equal to 300 GHz, further preferably higher than or equal to 2.4 GHz and lower than or equal to 2.5 GHz, and can be set to 2.45 GHz, for example. Oxygen radicals at a high density can be generated with high-density plasma. The electric power of the power source that applies microwaves of the microwave treatment apparatus is preferably higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the insulator 280.

Next, heat treatment may be performed. After the microwave treatment is performed, heat treatment may be successively performed without exposure to the air. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more after heat treatment is performed in a nitrogen gas or inert gas atmosphere. By the above-described heat treatment, impurities such as water contained in the insulator 280 or the like can be reduced before formation of the later-described oxide semiconductor film to be the oxide semiconductor 230. Note that the heat treatment is preferably performed under the condition where the conductor 220 and the conductor 240s are not excessively oxidized.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the insulator 280 and the like as much as possible.

Although the heat treatment is performed after the microwave treatment in the above description, the present invention is not limited thereto. The microwave treatment may be performed after the heat treatment.

Next, an oxide semiconductor film 230f to be the oxide semiconductor 230 is formed in contact with the top surface of the conductor 220, the side surface of the insulator 280, and the top surface and the side surface of the conductor 240s (see FIG. 9C). For the oxide semiconductor film 230f, a metal oxide that can be used for the oxide semiconductor 230 can be used as appropriate. The oxide semiconductor film 230f can be formed by a sputtering method, a CVD method, an MBE method, a PLD method, an ALD method, or the like as appropriate. Here, the oxide semiconductor film 230f is preferably formed in contact with the top surface of the conductor 220, the side surface of the insulator 280, and the side surface of the conductor 240s. Thus, the oxide semiconductor film 230f is preferably formed by a film formation method providing favorable coverage, and is further preferably formed by a CVD method, an ALD method, or the like. For example, an In—Ga—Zn oxide film can be formed by an ALD method as the oxide semiconductor film 230f.

Note that the method that can be used for formation of the oxide semiconductor film 230f is not limited to a CVD method or an ALD method. For example, a sputtering method may also be used. In the case where the oxide semiconductor 230 has a stacked-layer structure as illustrated in FIG. 4A and FIG. 4B, the layers included in the oxide semiconductor 230 may be formed by the same method or different methods.

Here, the oxide semiconductor film 203f is preferably formed in contact with the top surface of the conductor 220 in the opening portion 290, the side surface of the insulator 280 in the opening portion 290, the side surface of the conductor 240s in the opening portion 290, and the top surface of the conductor 240s. When the oxide semiconductor film 230f is formed in contact with the conductor 220, the conductor 220 functions as one of a source electrode and a drain electrode of the transistor 200. When the oxide semiconductor film 230f is formed in contact with the conductor 240s, the conductor 240 formed later from the conductor 240s functions as the other of the source electrode and the drain electrode of the transistor 200.

Note that the microwave treatment and the heat treatment may be performed after the formation of the oxide semiconductor film 230f.

Next, treatment for supplying an impurity 160 to the oxide semiconductor film 230f is performed. As the impurity 160, for example, one or more selected from halogen elements such as chlorine, fluorine, bromine, and iodine can be given. The impurity 160 can be supplied by, for example, an ion implantation method, an ion doping method, a plasma immersion ion implantation method, or plasma treatment. In particular, an ion implantation method is preferable because an ionized source gas is subjected to mass separation and only a desired element can be supplied to the oxide semiconductor film 230f. For example, with the use of an ion implantation method, an impurity such as hydrogen can be supplied into the oxide semiconductor film 230f (in particular, the region 230cd to be the channel formation region) and the hydrogen generates an electron serving as a carrier, so that the negative shift of the threshold voltage (normally-on characteristics) of the transistor can be inhibited.

For example, in this manufacturing method example, by an ion implantation method using boron trifluoride (BF3) as a source gas, fluorine (F) obtained by mass separation is supplied to the oxide semiconductor film 230f as the impurity 160. For example, as the impurity 160, fluorine with a dose greater than or equal to 1.0×10¹² ions/cm² and less than or equal to 1.0×10¹⁷ ions/cm² is supplied to the oxide semiconductor film 230f at an acceleration voltage greater than or equal to 1 keV and less than or equal to 80 keV by an ion implantation method. For example, fluorine is supplied to the oxide semiconductor film 230f by an ion implantation method under the condition where the fluorine concentration in the oxide semiconductor film 230f is higher than or equal to 1.0×10¹⁷ atoms/cm³ and lower than or equal to 1.0×10²² atoms/cm³.

Note that the impurity 160 is not limited to fluorine and may be a halogen element other than fluorine, such as chlorine, as described above.

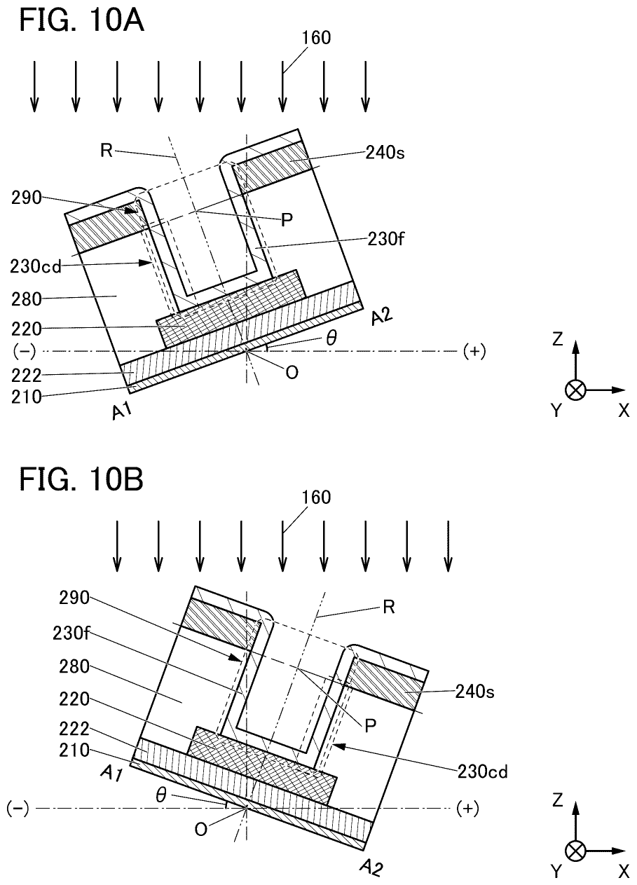

Note that the above-described treatment for supplying impurities is performed on at least a region of the oxide semiconductor film 230f that is to be the channel formation region. Here, as illustrated in FIG. 2A and the like, in the transistor 200 of one embodiment of the present invention, the region 230cd functioning as the channel formation region of the oxide semiconductor 230 is provided in contact with the sidewall of the opening portion 290 substantially perpendicular to the substrate plane. Thus, in order to supply impurities to the region 230cd to be the channel formation region, the treatment is preferably performed in a state where a structure under manufacturing is inclined with respect to the XY plane as illustrated in FIG. 10A and FIG. 10B.

In this manufacturing method example, first, the treatment for supplying the impurity 160 is performed in a state where the above-described structure is inclined by an angle θ to the −X direction with the point O in the XY plane (in the substrate plane) as a supporting point (see FIG. 10A), and then the treatment for supplying the impurity 160 is performed in a state where the above-described structure is inclined by the angle θ to the +X direction with the point O as a supporting point (see FIG. 10B). Here, the angle θ is preferably an angle at which at least part of the region 230cd can be seen exposed from the opening portion 290 when the structure under manufacturing is seen from the Z-axis direction. For example, the angle θ is preferably greater than 0° and less than 90°, further preferably greater than or equal to 15° and less than or equal to 80°. Thus, the impurity 160 can be supplied to the region 230cd to be the channel formation region in the oxide semiconductor film 230f at the plane cut along the dashed-dotted line A1-A2. Note that in FIG. 10A and FIG. 10B, the direction orthogonal to the dashed-dotted line A1-A2 is indicated by the dashed double-dotted line as the axis R. The intersection between the axis R and a plane by which the upper end portion of the region 230cd to be the channel formation region in the oxide semiconductor film 230f is cut (also referred to as a plane parallel to the interface between the insulator 280 and the conductor 240s) is indicated by the point P.

Note that in this manufacturing method example, the sidewall of the opening portion 290 in the structure under manufacturing is substantially perpendicular to the bottom portion thereof; however, in the case where the sidewall of the opening portion 290 is inclined with respect to the bottom portion (in the case where the opening portion has a tapered shape), the impurity 160 can be supplied to the region 230cd even when the treatment for supplying the impurity 160 is performed without inclining the structure (i.e., the angle θ=0°) in some cases.

For example, when the treatment illustrated in FIG. 10A or FIG. 10B is performed while the axis R is rotated by 360° in the XY plane with the Z-axis passing through the point O as a rotation axis, the impurity 160 can be surely supplied to the entire surface of the region 230cd formed on the sidewall of the opening portion 290.

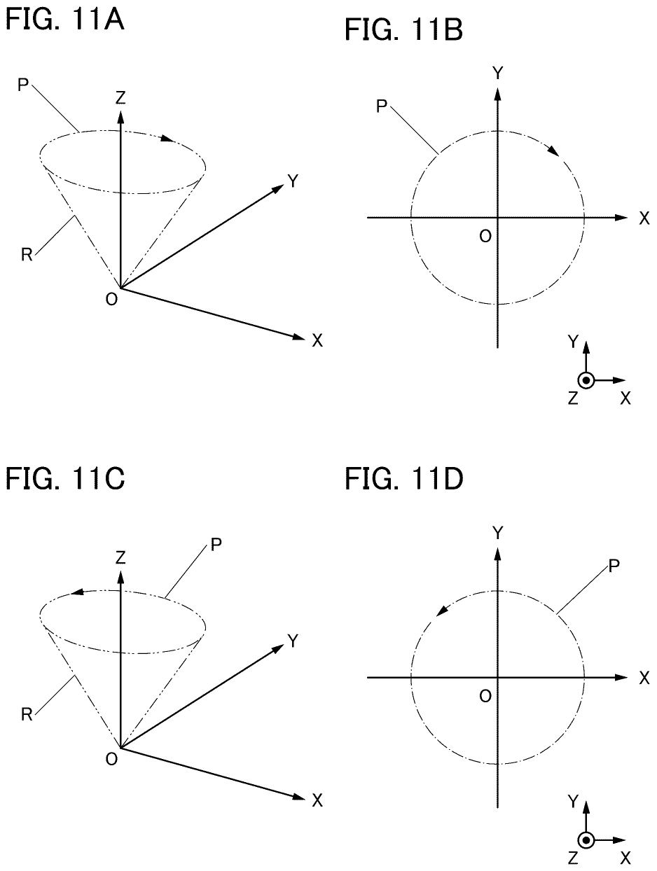

FIG. 11A is a schematic view (a schematic perspective view) illustrating the path of the point P when the axis R is rotated by 360° in the XY plane with the point O as a supporting point. FIG. 11B is a schematic plan view of the path of the point P illustrated in FIG. 11A seen from the direction perpendicular to the XY plane. FIG. 11A and FIG. 11B illustrate an example in which the axis R is rotated clockwise in a plan view.

Note that the rotational direction of the axis R is not necessarily clockwise. As illustrated in FIG. 11C and FIG. 11D, the axis R may be rotated counterclockwise in a plan view.

Note that rotation of the axis R and supply of the impurity 160 are not necessarily performed at the same time. For example, after the treatment for supplying the impurity 160 is performed in a state where the axis R is fixed to one direction, the axis R is rotated by a given angle and fixed thereto, and then the next treatment for supplying the impurity 160 is performed. Such a series of treatments may be repeatedly performed.

For example, the treatment for supplying the impurity 160 is performed in a state where the axis R is fixed to one direction, the axis R is rotated by 90° and fixed thereto, and then the next treatment for supplying the impurity 160 is performed. In this case, when each of the rotation of the axis R and the treatment for supplying the impurity 160 is performed four times, the axis R is rotated by 360°, so that the impurity 160 can be supplied to the entire surface of the region 230cd formed on the sidewall of the opening portion 290. The rotation angle of the axis R is determined as appropriate in consideration of the shape of the opening portion 290 in the plan view, the angle formed between the sidewall and the bottom portion of the opening portion 290, the required amount of supply of the impurity 160 to the region 230cd, the specifications of the semiconductor manufacturing apparatus, the productivity of the semiconductor device, and the like.

Note that in the case where the oxide semiconductor 230 has a stacked-layer structure of two or more layers as illustrated in FIG. 4A and FIG. 4B, the impurity 160 may be supplied to all layers in the oxide semiconductor or may be supplied mainly to some layers in the oxide semiconductor.

For example, in the case where the oxide semiconductor 230 has a two-layer structure of the oxide semiconductor 230a and the oxide semiconductor 230b as illustrated in FIG. 4A, the impurity 160 may be supplied to both the oxide semiconductor 230a and the oxide semiconductor 230b, or the impurity 160 may be supplied mainly to either of them. For example, in the case where the band structure of the oxide semiconductor 230 of the transistor 200 illustrated in FIG. 4A is the structure illustrated in FIG. 5A, electrons serving as carriers flow mainly through the oxide semiconductor 230a serving as a carrier path. In that case, when the treatment for supplying the impurity 160 is performed mainly on the oxide semiconductor 230b, which is the layer on the oxide semiconductor 230a, the impurity 160 can be supplied to the oxide semiconductor 230 without causing damage to the oxide semiconductor 230a side to be a carrier path. As a result, the transistor 200 with favorable electrical characteristics and reliability can be obtained.

For example, in the case where the oxide semiconductor 230 has a three-layer structure of the oxide semiconductor 230a, the oxide semiconductor 230b, and the oxide semiconductor 230c as illustrated in FIG. 4B, the impurity 160 may be supplied to all of the oxide semiconductor 230a to the oxide semiconductor 230c or the impurity 160 may be supplied mainly to a specific layer. For example, in the case where the band structure of the oxide semiconductor 230 of the transistor 200 illustrated in FIG. 4B is the structure (the embedded channel structure) illustrated in FIG. 5C, electrons serving as carriers flow mainly through the oxide semiconductor 230b serving as a carrier path. In that case, when the treatment for supplying the impurity 160 is performed mainly on the oxide semiconductor 230c, which is the layer on the oxide semiconductor 230b, the impurity 160 can be supplied to the oxide semiconductor 230 without causing damage to the oxide semiconductor 230b side to be a carrier path. As a result, the transistor 200 with favorable electrical characteristics and reliability can be obtained.

In this manufacturing method example, although an example in which the impurity 160 is supplied to the oxide semiconductor film 230f after the formation of the oxide semiconductor film 230f is described, the present invention is not limited thereto. For example, after the formation of the opening portion 290 (see FIG. 9B), the treatment for supplying the impurity 160 to the side surface of the insulator 280 in the opening portion 290 may be performed. In that case, as illustrated in FIG. 10A to FIG. 11D, when the treatment for supplying the impurity 160 is performed while the axis R is rotated by 360° in the XY plane with the point O as a supporting point in a state where the structure under manufacturing is inclined by the angle θ, the impurity 160 can be surely supplied to the entire side surface of the insulator 280 in the opening portion 290. Accordingly, the impurity 160 can be supplied to the insulator 280 in contact with the region 230cd without causing damage to the oxide semiconductor film 230f to be formed later.

Note that both the treatment for supplying the impurity 160 to the insulator 280 and the treatment for supplying the impurity 160 to the oxide semiconductor film 230f may be performed. In this embodiment, although an example of a method for performing the treatment for supplying the impurity 160 in a state where the structure is inclined is described, the present invention is not limited thereto. For example, by rotating an apparatus or equipment for the treatment for supplying the impurity 160 is performed while the structure is fixed, the impurity 160 may be supplied to the region 230cd to be the channel formation region in the oxide semiconductor film 230f at the plane cut along the dashed-dotted line A1-A2.

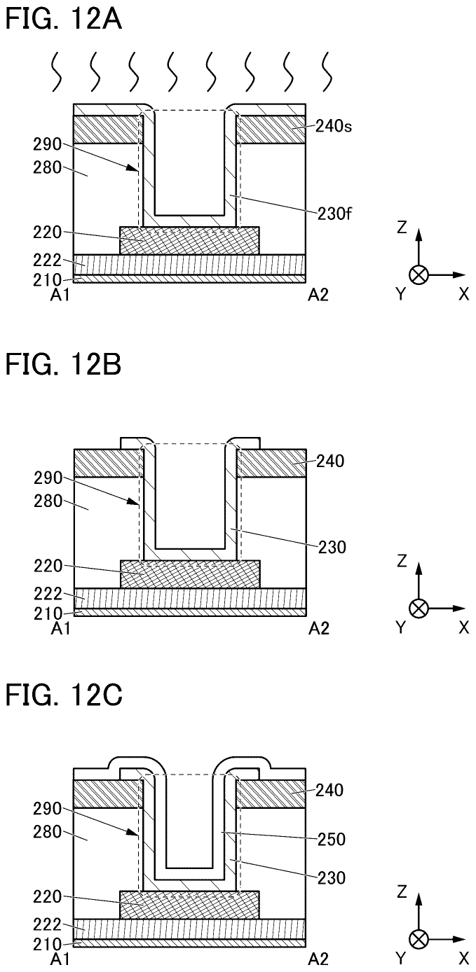

Next, heat treatment is performed (see FIG. 12A). The above description can be referred to for the heat treatment. By the heat treatment, oxygen contained in the insulator 280 can be supplied to the oxide semiconductor film 230f (mainly, a channel formation region in contact with the insulator 280). Accordingly, oxygen enters oxygen vacancies (Vo) in the oxide semiconductor film 230f, so that oxygen vacancies can be reduced. In addition, damage to the oxide semiconductor film 230f that is caused by the above-mentioned treatment for supplying the impurity 160 can be compensated for and the crystallinity can be recovered. Furthermore, when oxygen is supplied mainly to the channel formation region, the oxygen traps electrons, so that negative charge (negative fixed charge) can be formed in the channel formation region and the vicinity thereof. In addition, the substrate may be heated when the treatment for supplying the impurity 160 is performed. The temperature for heating the substrate can be higher than or equal to 200° C. and lower than or equal to 500° C. By heating the substrate when the treatment for supplying the impurity 160 is performed, the effect similar to that of the above-described heat treatment can be obtained. Furthermore, the above-described heat treatment can be omitted; thus, the manufacturing process can be simplified.

Next, the oxide semiconductor film 230f is processed by a lithography method to form the oxide semiconductor 230 (see FIG. 12B). Accordingly, part of the oxide semiconductor 230 is formed in the opening portion 290. For the processing of the oxide semiconductor 230, a dry etching method or a wet etching method can be employed. Processing by a dry etching method is suitable for microfabrication.

Next, the conductor 240s is processed to form the conductor 240 extending in the X direction as illustrated in FIG. 1A and FIG. 1C (see FIG. 12B). For the conductor 240, a lithography method can be employed. For the processing of the conductor 240s, a dry etching method or a wet etching method can be employed. Processing by a dry etching method is suitable for microfabrication.

Next, the insulator 250 is formed over the oxide semiconductor 230, the conductor 240, and the insulator 280 (see FIG. 12C). Any of the above-described insulating materials can be used for the insulator 250 as appropriate. The insulator 250 can be formed by a sputtering method, a CVD method, an MBE method, a PLD method, an ALD method, or the like as appropriate. The insulator 250 is preferably formed in contact with the oxide semiconductor 230 provided in the opening portion 290. Thus, the insulator 250 is preferably formed by a film formation method providing favorable coverage, and is further preferably formed by a CVD method, an ALD method, or the like. For example, silicon oxide film can be formed as the insulator 250 by a PEALD method. Note that the method for forming the insulator 250 is not limited to a CVD method or an ALD method. For example, a sputtering method may be employed.

As illustrated in FIG. 4A to FIG. 4B, the insulator 250 can have a stacked-layer structure of the insulator 250a and the insulator 250b. For example, hafnium silicate can be formed as the insulator 250a by a thermal ALD method. For example, a silicon nitride film can be formed as the insulator 250b by a PEALD method.

When the insulator 250 is formed after the formation of the oxide semiconductor 230, the side end portion of the oxide semiconductor 230 is covered with the insulator 250. Thus, a short circuit between the oxide semiconductor 230 and the conductor 260 can be prevented. Furthermore, in the above-described structure, the side end portion of the conductor 240 is covered with the insulator 250. Thus, a short circuit between the conductor 240 and the conductor 260 can be prevented.

The microwave treatment and the heat treatment may be performed after the film formation of the insulator 250. For example, in the case where the insulator 250 has a stacked-layer structure of the insulator 250a and the insulator 250b, silicon nitride is used for the insulator 210 and the insulator 250b, and hafnium silicate is used for the insulator 222 and the insulator 250a, heat treatment can be performed in a state where the insulator 222 and the insulator 250a are provided in a closed system formed of the insulator 210 and the insulator 250b. Accordingly, hydrogen in the closed system can be captured or fixed by the insulator 222 and the insulator 250a. Thus, the hydrogen concentration in the channel formation region of the oxide semiconductor 230 can be reduced. Therefore, the transistor can have favorable electrical characteristics and improved reliability. Also, a semiconductor device with a small variation in electrical characteristics of the transistors can be provided.

Furthermore, the above-described microwave treatment can remove impurities such as carbon in the oxide semiconductor 230. With the removal of carbon, which is an impurity in the oxide semiconductor 230, the crystallinity of the oxide semiconductor 230 can be improved. Accordingly, the oxide semiconductor 230 can be a CAAC-OS. Particularly in the case where the oxide semiconductor 230 is formed by an ALD method, carbon included in a precursor is sometimes taken into the oxide semiconductor 230; thus, carbon is preferably removed by the microwave treatment.

Note that in the case where the insulator 250 has a stacked-layer structure, the microwave treatment is not necessarily performed after all the insulators included in the insulator 250 are formed. For example, in the case of the structure illustrated in FIG. 4A and FIG. 4B, microwave treatment may be performed after the insulator 250a is formed, and then the insulator 250b may be formed. Alternatively, for example, microwave treatment may be performed after the insulator 250a is formed, and then microwave treatment may be performed after the insulator 250b is formed. In this manner, the microwave treatment in an oxygen-containing atmosphere may be performed multiple times.

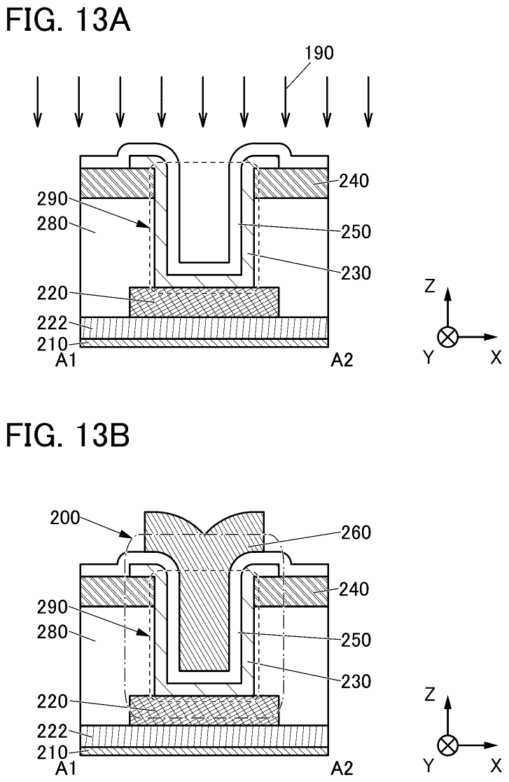

Next, treatment for supplying the impurity 190 to the oxide semiconductor 230 through the insulator 250 is performed (see FIG. 13A). As the impurity 190, one or more of the impurities that can be included in the region 230na and the region 230nb described with reference to FIG. 2A, such as hydrogen, boron, carbon, nitrogen, phosphorus, sulfur, arsenic, aluminum, magnesium, silicon, and a noble gas can be given. Note that typical examples of a noble gas include helium, neon, argon, krypton, and xenon. It is particularly preferable to use one or more of boron, phosphorus, aluminum, magnesium, and silicon as the impurity 190. The impurity 190 can be supplied by, for example, an ion implantation method, an ion doping method, a plasma immersion ion implantation method, plasma treatment, or the like.

Note that supply of the impurity 190 is performed in order to reduce the resistance of the source region and the drain region (the region 230na and the region 230nb illustrated in FIG. 2A) of the oxide semiconductor 230. For this reason, it is preferable that the impurity 190 be supplied only to the source region and the drain region but not to the channel formation region (the region 230cd illustrated in FIG. 2A). Thus, unlike the case where the impurity 160 is supplied to the oxide semiconductor film 230f, the impurity 190 is preferably supplied in the direction substantially perpendicular to the substrate plane. Accordingly, the impurities can be supplied mainly to the source region and the drain region of the oxide semiconductor 230, so that the resistance of these regions can be selectively reduced.

For example, the treatment for supplying the impurity 190 to the structure under manufacturing is preferably performed by an ion doping method in the direction substantially perpendicular to the substrate plane. In the ion doping method in which the ionized source gas is supplied to an object without mass separation, in the case where hydrogen is contained in the source gas, all the source gas containing hydrogen can be supplied to the oxide semiconductor 230 as the impurity 190. Hydrogen supplied to the oxide semiconductor 230 forms VoH in the oxide semiconductor 230 and thus the resistance of the oxide semiconductor 230 is easily reduced. Thus, the resistance of the source region and the drain region of the oxide semiconductor 230 can be easily reduced.

For example, in the case where the treatment for supplying the impurity 190 to the structure under manufacturing is performed by an ion doping method in the direction substantially perpendicular to the substrate plane using diborane (B₂H₆) as a source gas, both boron (B) and hydrogen (H) described above can be supplied to the oxide semiconductor 230 as the impurity 190 at the same time. In that case, the resistance of the source region and the drain region in the oxide semiconductor 230 can be sometimes reduced more efficiently than in the case of using an ion implantation method in which an ionized source gas is subjected to mass separation and then supplied to an object.

Note that an ion implantation method may be used as a method for supplying the impurity 190. For example, in the case where the sidewall of the opening portion 290 in the structure under manufacturing is inclined with respect to the bottom portion (in the case where the opening portion has a tapered shape), when an ion doping method is used for the treatment for supplying the impurity 190, impurities such as hydrogen are supplied not only to the source region and the drain region but also to the channel formation region even in the case where the impurity 190 is supplied in the direction substantially perpendicular to the substrate plane. As described above, hydrogen in the channel formation region is preferably reduced as much as possible. Thus, depending on the shape of the opening portion 290, an ion implantation method in which a source gas is subjected to mass separation and only a desired element can be supplied is preferably used in some cases.

For example, in an ion implantation method, even in the case where diborane (B₂H₆) containing hydrogen (H) is used as a source gas, only boron (B) can be supplied to the oxide semiconductor 230 as the impurity 190 by mass separation. In that case, the resistance of the source region and the drain region can be reduced while supply of impurities such as hydrogen to the channel formation region is prevented.

Note that as a source gas that can be used when the impurity 190 is supplied, a source gas that does not contain hydrogen (H) such as boron trifluoride (BF₃) may be used, for example, without being limited to diborane (B₂H₆).

Note that in the case where the source region and the drain region of the oxide semiconductor 230 have sufficiently low resistance, the treatment for supplying the impurity 190 is not necessarily performed.

Next, a conductive film to be the conductor 260 is formed to fill the depressed portion of the insulator 250. Any of the above-described conductive materials can be used for the conductive film as appropriate. The conductive film may be formed by a sputtering method, a CVD method, an MBE method, a PLD method, an ALD method, or the like as appropriate. Here, the conductive film is preferably formed in contact with the insulator 250 provided in the opening portion 290. Thus, the conductive film is preferably formed by a film formation method providing favorable coverage or a good filling property, and is further preferably formed by a CVD method, an ALD method, or the like. For example, as the conductive film, a titanium nitride film may be formed by a CVD method or an ALD method and a tungsten film can be formed over the titanium nitride by a CVD method.

Although the conductive film to be the conductor 260 is provided to fill the opening portion 290 in the above description, the present invention is not limited thereto. For example, a depressed portion reflecting the shape of the opening portion 290 is formed in a center portion of the conductive film in some cases. The depressed portion may be filled with an inorganic insulating material or the like.

Next, the conductive film to be the conductor 260 is processed to form the conductor 260 (see FIG. 13B). The conductor 260 can be formed by a lithography method. A dry etching method or a wet etching method can be employed for the processing. Processing by a dry etching method is suitable for microfabrication.

Note that the treatment for supplying the impurity 190 may be performed not after the formation of the insulator 250 but after the formation of the conductor 260. In that case, the impurity 190 is supplied only to the region that is of the source region and the drain region of the oxide semiconductor 230 and does not overlap with the conductor 260 (the region 230nb illustrated in FIG. 2A) and supply of the impurity 190 to the channel formation region overlapping with the conductor 260 (the region 230cd illustrated in FIG. 2A) can be prevented. Accordingly, even when the opening portion 290 has a tapered shape whose angle formed by the sidewall and the bottom portion is less than 90°, the risk of the impurity 190 being supplied to the channel formation region is eliminated. Note that the treatment for supplying the impurity 190 may be performed both after the formation of the insulator 250 and after the formation of the conductor 260.

Next, the insulator 283 is formed to cover the conductor 260 and the insulator 250. Any of the above-described insulating materials can be used as the insulator 283 as appropriate. The insulator 283 can be formed by a sputtering method, a CVD method, an MBE method, a PLD method, an ALD method, or the like as appropriate. As illustrated in FIG. 4A or FIG. 4B, the insulator 283 may have a stacked-layer structure of the insulator 283a and the insulator 283b.

The microwave treatment and the heat treatment may be performed after the formation of the insulator 283. For example, in the case where the insulator 283 has a stacked-layer structure of the insulator 283a and the insulator 283b, silicon nitride is used for the insulator 210 and the insulator 283b, and hafnium silicate is used for the insulator 222 and the insulator 283a, heat treatment can be performed in a state where the insulator 222 and the insulator 283a are provided in a closed system formed of the insulator 210 and the insulator 283b. Accordingly, hydrogen in the closed system can be captured or fixed by the insulator 222 and the insulator 283a. Thus, the hydrogen concentration in the channel formation region of the oxide semiconductor 230 can be reduced. Therefore, the transistors can have favorable electrical characteristics and higher reliability. Also, a semiconductor device with a small variation in electrical characteristics of the transistors can be provided.

Through the above process, the transistor 200 illustrated in FIG. 1A to FIG. 1C and the like can be fabricated.

This embodiment can be combined with the other embodiments as appropriate. In this specification, in the case where a plurality of structure examples are shown in one embodiment, the structure examples can be combined as appropriate.

### Embodiment 2

A semiconductor device 900 of one embodiment of the present invention is described in this embodiment. Thus, the semiconductor device 900 can function as a memory device.

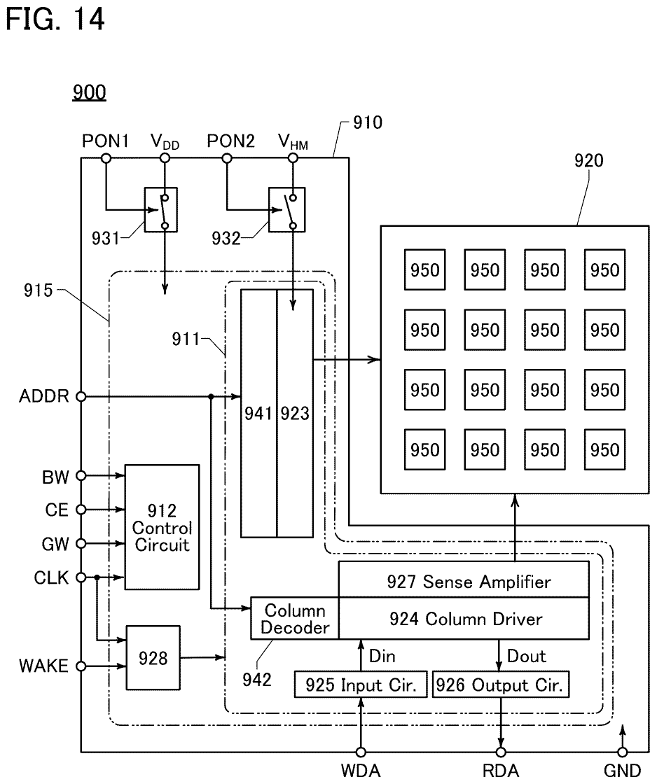

FIG. 14 illustrates a block diagram illustrating a structure example of the semiconductor device 900. The semiconductor device 900 illustrated in FIG. 14 includes a driver circuit 910 and a memory array 920. The memory array 920 includes one or more of a memory cell 950. FIG. 14 illustrates an example in which the memory array 920 includes a plurality of memory cells 950 arranged in a matrix.

The transistor described as an example in the above embodiment can be used for the memory cell 950. The use of the transistor allows miniaturization and high integration of the memory device. In addition, the capacity per area of the memory device can be increased.

The driver circuit 910 includes a PSW 931 (power switch), a PSW 932, and a peripheral circuit 915. The peripheral circuit 915 includes a peripheral circuit 911, a control circuit 912, and a voltage generation circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating a negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates a negative voltage.

The peripheral circuit 911 is a circuit for performing writing and reading of data to/from the memory cell 950. The peripheral circuit 911 includes a row decoder 941, a column decoder 942, a row driver 923, a column driver 924, an input circuit 925 (Input Cir.), an output circuit 926 (Output Cir.), and a sense amplifier 927.

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting the row specified by the row decoder 941. The column driver 924 has a function of writing data to the memory cell 950, a function of reading data from the memory cell 950, a function of retaining the read data, and the like.

The input circuit 925 has a function of retaining the signal WDA. Data retained by the input circuit 925 is output to the column driver 924. Data output from the input circuit 925 is data (Din) to be written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling the supply of V_{DD} to the peripheral circuit 915. The PSW 932 has a function of controlling supply of V_{HM} to the row driver 923. Here, in the semiconductor device 900, a high power supply voltage is V_{DD} and a low power supply voltage is GND (a ground potential). In addition, V_{HM} is a high power supply voltage used to set the word line at a high level and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 14 but can be plural. In that case, a power switch can be provided for each power domain.

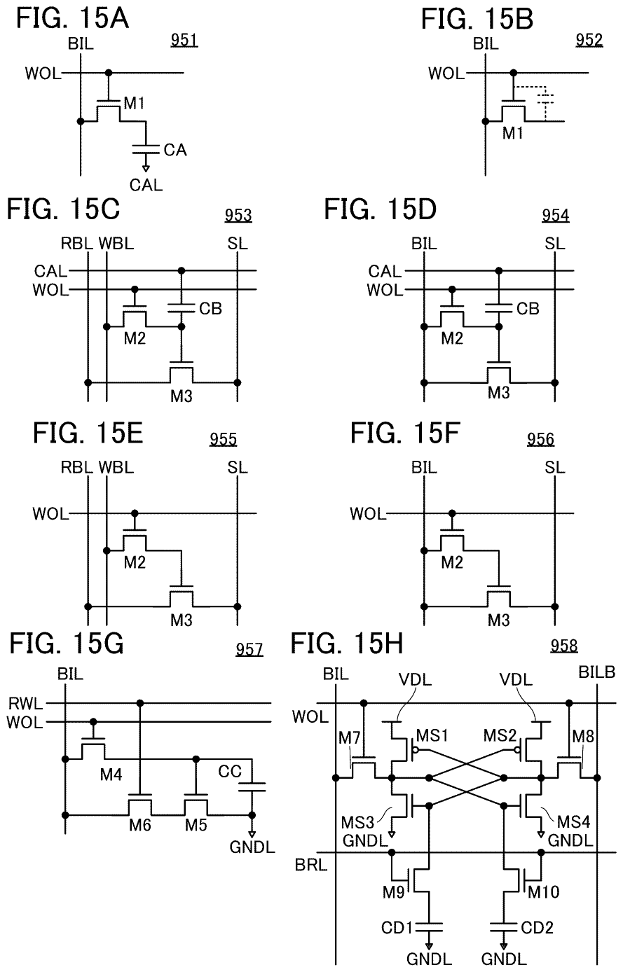

Structure examples of other memory cells that can be used as the memory cell 950 are described with reference to FIG. 15A to FIG. 15H.

### [DOSRAM]

FIG. 15A illustrates a circuit structure example of a memory cell of DRAM. In this specification and the like, a DRAM using an OS transistor is referred to as a DOSRAM (Dynamic Oxide Semiconductor Random Access Memory). A memory cell 951 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA, a second terminal of the transistor M1 is connected to a wiring BIL, and a gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. In data writing and reading, a low-level potential (referred to as reference potential in some cases) is preferably applied to the wiring CAL.

Data writing and reading are performed in such a manner that a high-level potential is applied to the wiring WOL to turn on the transistor M1 so that the wiring BIL is electrically connected to the first terminal of the capacitor CA.

The memory cell that can be used as the memory cell 950 is not limited to the memory cell 951, and the circuit structure can be changed. For example, the structure of a memory cell 952 illustrated in FIG. 15B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. With such a structure, the structure of the memory cell can be greatly simplified.

It is preferable to use, as the transistors M1, the OS transistor described in the above embodiment. With use of the OS transistor described in the above embodiment, the area occupied by a memory cell can be reduced. OS transistors have characteristics of having an extremely low off-state current. The use of an OS transistor as the transistor M1 enables the leakage current of the transistor M1 to be extremely low. That is, with the use of the transistor M1, written data can be retained for a long time, and thus the frequency of the refresh operation for the memory cell can be decreased. Alternatively, refresh operation for the memory cell can be unnecessary. In addition, extremely low leakage current allows multi-level data or analog data to be retained in the memory cell 951 and the memory cell 952.

### [NOSRAM]

FIG. 15C illustrates a circuit structure example of a gain-cell-type memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a NOSRAM (Nonvolatile Oxide Semiconductor Random Access Memory).

A first terminal of the transistor M2 is connected to a first terminal of the capacitor CB, a second terminal of the transistor M2 is connected to the wiring WBL, and a gate of the transistor M2 is connected to the wiring WOL. A second terminal of the capacitor CB is connected to the wiring CAL. A first terminal of the transistor M3 is connected to the wiring RBL, a second terminal of the transistor M3 is connected to a wiring SL, and a gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In data writing and data retention, a low-level potential (referred to as a reference potential in some cases) is preferably applied to the wiring CAL.

Data writing is performed in such a manner that a high-level potential is applied to the wiring WOL to turn on the transistor M2, so that the wiring WBL is electrically connected to the first terminal of the capacitor CB. Specifically, when the transistor M2 is in a conduction state, a potential corresponding to information stored in the wiring WBL is applied, whereby the potential is written to the first terminal of the capacitor CB and the gate of the transistor M3. After that, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. The current flowing between a source and a drain of the transistor M3 and the potential of the first terminal of the transistor M3 are determined by the potential of the gate of the transistor M3 and the potential of the second terminal of the transistor M3; therefore, the potential of the wiring RBL electrically connected to the first terminal of the transistor M3 is read out, so that the potential retained in the first terminal of the capacitor CB (or the gate of the transistor M3) can be read out. In other words, data written into this memory cell can be read out from the potential retained in the first terminal of the capacitor CB (or the gate of the transistor M3).

Alternatively, for example, the wiring WBL and the wiring RBL may be collectively connected to be one as the wiring BIL. FIG. 15D illustrates a circuit structure example of the memory cell. In a memory cell 954, one wiring BIL corresponds to the wiring WBL and the wiring RBL in the memory cell 953, and the second terminal of the transistor M2 and the first terminal of the transistor M3 are connected to the wiring BIL. In other words, the memory cell 954 has a structure in which one wiring BIL operates as a write bit line and a read bit line.

A memory cell 955 illustrated in FIG. 15E is an example in which the capacitor CB and the wiring CAL in the memory cell 953 are omitted. A memory cell 956 illustrated in FIG. 15F is an example in which the capacitor CB and the wiring CAL in the memory cell 954 are omitted. With such a structure, the integration degree of the memory cells can be increased.

Note that the OS transistor described in the above embodiment is preferably used at least as the transistor M2. The OS transistor described in the above embodiment is particularly preferably used as each of the transistor M2 and the transistor M3. With use of the OS transistor described in the above embodiment, the area occupied by a memory cell can be reduced.

Since the OS transistor has a characteristic of an extremely low off-state current, written data can be retained for a long time with the transistor M2, and thus the frequency of refresh operation for the memory cell can be decreased. Alternatively, refresh operation for the memory cell can be unnecessary. In addition, the extremely low leakage current allows multi-level data or analog data to be retained in the memory cell 953, the memory cell 954, the memory cell 955, and the memory cell 956.

The memory cell 953, the memory cell 954, the memory cell 955, and the memory cell 956 each using the OS transistor as the transistor M2 are embodiments of a NOSRAM.

Note that a Si transistor may be used as the transistor M3. The Si transistor can have high field-effect mobility and can be a p-channel transistor, so that circuit design flexibility can be increased.

In the case where an OS transistor is used as the transistor M3, the memory cell can be composed of a single-polarity circuit.

FIG. 15G illustrates a gain-cell memory cell 957 including three transistors and one capacitor. The memory cell 957 includes a transistor M4 to a transistor M6 and a capacitor CC.

A first terminal of the transistor M4 is connected to a first terminal of the capacitor CC, a second terminal of the transistor M4 is connected to the wiring BIL, and a gate of the transistor M4 is connected to the wiring WOL. A second terminal of the capacitor CC is electrically connected to a first terminal of the transistor M5 and a wiring GNDL. A second terminal of the transistor M5 is connected to a first terminal of the transistor M6, and a gate of the transistor M5 is connected to the first terminal of the capacitor CC. A second terminal of the transistor M6 is connected to the wiring BIL, and a gate of the transistor M6 is connected to the wiring RWL.

The wiring BIL functions as a bit line, the wiring WOL functions as a write word line, and the wiring RWL functions as a read word line. The wiring GNDL is a wiring for applying a low-level potential.

Data writing is performed in such a manner that a high-level potential is applied to the wiring WOL to turn on the transistor M4 so that the wiring BIL is connected to the first terminal of the capacitor CC. Specifically, when the transistor M4 is in a conduction state, a potential corresponding to information stored in the wiring BIL is applied, whereby the potential is written to the first terminal of the capacitor CC and the gate of the transistor M5. After that, the low-level potential is applied to the wiring WOL to turn off the transistor M4, so that the potential of the first terminal of the capacitor CC and the potential of the gate of the transistor M5 are retained.

Data reading is performed in such a manner that after a predetermined potential is precharged to the wiring BIL, the wiring BIL is brought into an electrically floating state, and a high-level potential is applied to the wiring RWL. Since the wiring RWL has the high-level potential, the transistor M6 is turned on, which electrically connects the wiring BIL and the second terminal of the transistor M5. At this time, the potential of the wiring BIL is supplied to the second terminal of the transistor M5; however, the potential of the second terminal of the transistor M5 and the potential of the wiring BIL are fluctuated in accordance with the potential retained in the first terminal of the capacitor CC (or the gate of the transistor M5). Here, by reading out the potential of the wiring BIL, the potential retained in the first terminal of the capacitor CC (or the gate of the transistor M5) can be read out. In other words, information written into the memory cell can be read out from the potential retained in the first terminal of the capacitor CC (the gate of the transistor M5).

Note that the OS transistor described in the above embodiment is preferably used at least as the transistor M4. With use of the OS transistor described in the above embodiment, the area occupied by a memory cell can be reduced.

Note that Si transistors may be used as the transistor M5 and the transistor M6. As described above, a Si transistor has a higher field-effect mobility than an OS transistor in some cases depending on the crystal state of silicon used in a semiconductor layer, for example.

In the case where OS transistors are used as the transistors M5 and the transistor M6, the memory cell can be composed of a single-polarity circuit.

### [OS-SRAM]

FIG. 15H illustrates an example of an SRAM (Static Random Access Memory) using an OS transistor. In this specification and the like, an SRAM using an OS transistor is referred to as an OS-SRAM (Oxide Semiconductor-SRAM). Note that a memory cell 958 illustrated in FIG. 15H is a memory cell of an SRAM capable of backup.

The memory cell 958 includes a transistor M7 to a transistor M10, a transistor MS1 to a transistor MS4, a capacitor CD1, and a capacitor CD2. Note that the transistor MS1 and a transistor MS2 are p-channel transistors, and a transistor MS3 and the transistor MS4 are n-channel transistors.

A first terminal of the transistor M7 is connected to the wiring BIL, and a second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB, and a second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1 and a gate of the transistor M9 is connected to the wiring BRL. A second terminal of the transistor M10 is connected to a first terminal of the capacitor CD2 and a gate of the transistor M10 is connected to the wiring BRL.

A second terminal of the capacitor CD1 is connected to the wiring GNDL, and a second terminal of the capacitor CD2 is connected to the wiring GNDL.

The wiring BIL and the wiring BILB each function as a bit line, the wiring WOL functions as a word line, and the wiring BRL controls the conduction state and the non-conduction state of the transistor M9 and the transistor M10.

The wiring VDL is a wiring supplying a high-level potential, and the wiring GNDL is a wiring supplying a low-level potential.

Data writing is performed by applying a high-level potential to the wiring WOL and applying a high-level potential to the wiring BRL. Specifically, when the transistor M10 is in a conduction state, a potential corresponding to information to be stored is applied to the wiring BIL, whereby the potential is written to the second terminal side of the transistor M10.

In the memory cell 958, an inverter loop is constructed by the transistor MS1 to the transistor MS2; thus, an inverted signal of a data signal corresponding to the potential is input to the second terminal side of the transistor M8. Since the transistor M8 is in a conduction state, the signal input to the wiring BIL, that is, an inverted signal of the potential applied to the wiring BIL is output to the wiring BILB. Since the transistor M9 and the transistor M10 are in a conduction state, the potentials of the second terminal of the transistor M7 and the second terminal of the transistor M8 are respectively retained in the first terminal of the capacitor CD2 and the first terminal of the capacitor CD1. Then, a low-level potential is applied to the wiring WOL and a low-level potential is applied to the wiring BRL to turn off the transistor M7 to the transistor M10, whereby the potential of the first terminal of the capacitor CD1 and the potential of the first terminal of the capacitor CD2 are retained.

Data reading is performed in such a manner that after the wiring BIL and the wiring BILB are precharged at a predetermined potential in advance, a high-level potential is applied to the wiring WOL and a high-level potential is applied to the wiring BRL, whereby the potential of the first terminal of the capacitor CD1 is refreshed by the inverter loop in the memory cell 958 and is output to the wiring BILB. Moreover, the potential of the first terminal of the capacitor CD2 is refreshed by the inverter loop in the memory cell 958 and is output to the wiring BIL. Since the potentials of the wiring BIL and the wiring BILB are changed from the precharged potentials to the potential of the first terminal of the capacitor CD2 and the potential of the first terminal of the capacitor CD1, respectively, the potential retained in the memory cell can be read out from the potential of the wiring BIL or the wiring BILB.

Note that OS transistors are preferably used as the transistor M7 to the transistor M10. Thus, written data can be retained for a long time by the transistor M7 to the transistor M10; thus, the frequency of refresh operations of the memory cell can be reduced. Alternatively, refresh operation for the memory cell can be unnecessary. With use of the OS transistors described in the above embodiment as the transistor M7 to the transistor M10, the area occupied by the memory cell can be reduced.

As the transistor MS1 to the transistor MS4, Si transistors may be used.

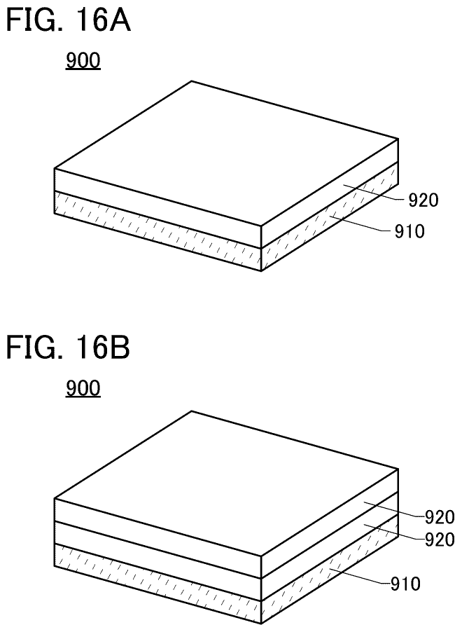

The driver circuit 910 and the memory array 920 that are included in the semiconductor device 900 may be provided on the same plane. As illustrated in FIG. 16A, the driver circuit 910 and the memory array 920 may be provided to overlap with each other. When the driver circuit 910 and the memory array 920 are provided to overlap with each other, the signal transmission distance can be shortened. Alternatively, a plurality of memory arrays 920 may be provided over the driver circuit 910 as illustrated in FIG. 16B.

Next, an example of an arithmetic processing unit that can include the semiconductor device such as the above-described memory device is described.

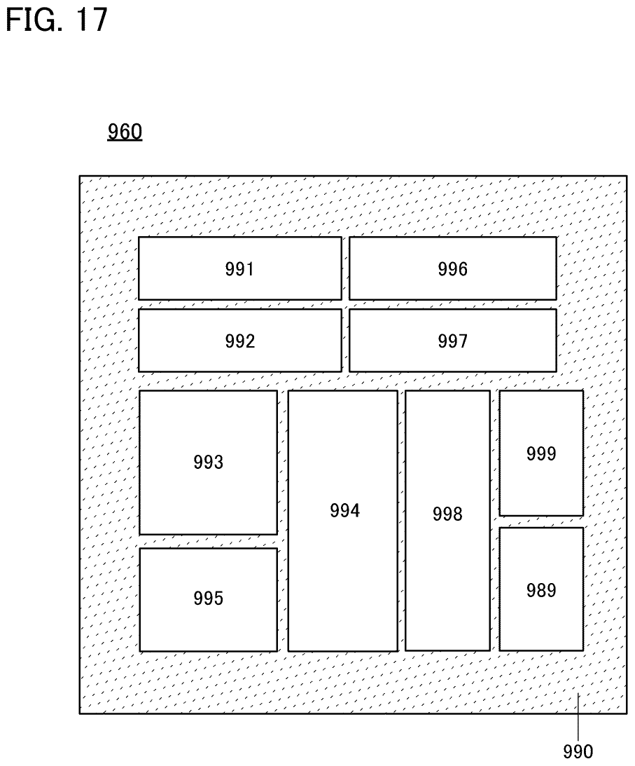

FIG. 17 illustrates a block diagram of an arithmetic device 960. The arithmetic device 960 illustrated in FIG. 17 can be used for a CPU (Central Processing Unit), for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic processing unit 960 illustrated in FIG. 17 includes, over a substrate 990, an ALU 991 (Arithmetic Logic Unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic processing unit 960 may include a rewritable ROM and a ROM interface. In addition, the cache 999 and the cache interface 989 may be provided in a separate chip.

The cache 999 is connected through the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic processing unit 960 illustrated in FIG. 17 is only an example with a simplified structure, and the actual arithmetic processing unit 960 has a variety of structures depending on the application. For example, what is called a multicore structure is preferably employed in which a plurality of cores each including the arithmetic device 960 illustrated in FIG. 17 operate in parallel. The larger number of cores can further enhance the arithmetic performance. The number of cores is preferably larger; for example, the number is preferably 2, further preferably 4, still further preferably 8, yet still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can process in an internal arithmetic circuit, a data bus, or the like can be 8, 16, 32, or 64, for example.

An instruction that is input to the arithmetic device 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 judges an interrupt request from an external input/output device, a peripheral circuit, or the like on the basis of its priority or a mask state, and processes the request. The register controller 997 generates an address of the register 996, and reads or writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic processing unit 960 illustrated in FIG. 17, the register controller 997 selects a retention operation in the register 996 in accordance with an instruction from the ALU 991. That is, the register 996 selects whether data is stored by a flip-flop or by a capacitor in the memory cell included in the register 996. When data storing by the flip-flop is selected, a power supply voltage is supplied to the memory cell in the register 996. When data retention by the capacitor is selected, the data is rewritten into the capacitor, and supply of power supply voltage to the memory cell in the register 996 can be stopped.

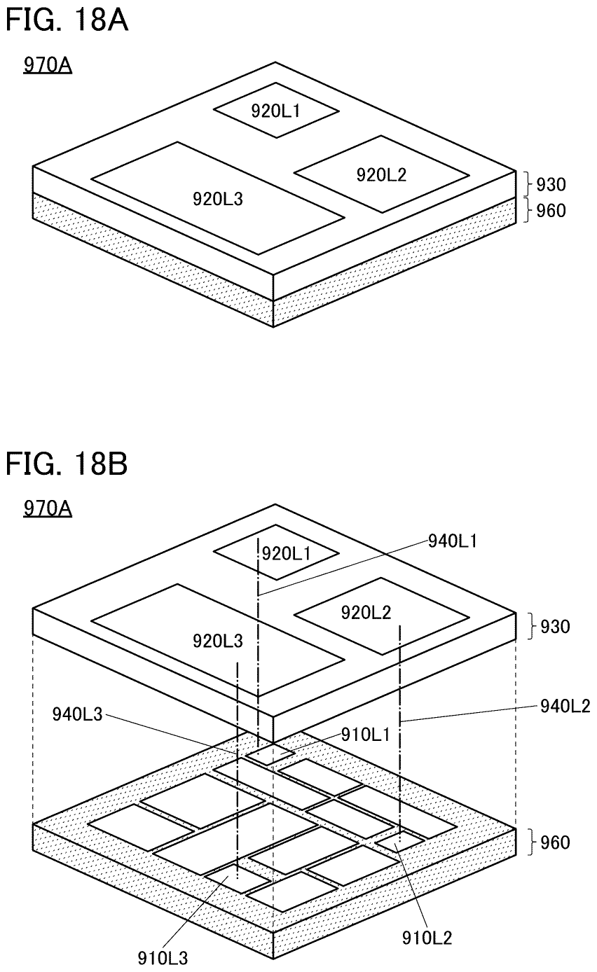

The memory array 920 and the arithmetic device 960 can be provided to overlap with each other. FIG. 18A and FIG. 18B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays include overlap regions. For easy understanding of the structure of the semiconductor device 970A, the arithmetic device 960 and the layer 930 are separately illustrated in FIG. 18B.

Providing the layer 930 including the memory arrays and the arithmetic device 960 to overlap with each other can shorten the connection distance therebetween. Accordingly, the communication speed therebetween can be increased. Moreover, since the connection distance is short, power consumption can be reduced.

As a method for stacking the layer 930 including the memory arrays and the arithmetic device 960, either of the following methods may be employed: a method in which the layer 930 including the memory arrays is stacked directly on the arithmetic device 960 (also referred to as monolithic stacking), and a method in which the arithmetic device 960 and the layer 930 are formed over two different substrates, and the two substrates are bonded and connected to each other using a through via or a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory array 920L1, the memory array 920L2, and the memory array 920L3 provided in the layer 930 are each used as a cache. In this case, for example, the memory array 920L1 can be used as an L1 cache (also referred to as a level 1 cache), the memory array 920L2 can be used as an L2 cache (also referred to as a level 2 cache), and the memory array 920L3 can be used as an L3 cache (also referred to as a level 3 cache). Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 18B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or be connected thereto.

Whether the memory array 920 functions as the cache or the main memory is determined by the control circuit 912 included in each of the driver circuits 910. The control circuit 912 can make some of the plurality of memory cells 950 included in the semiconductor device 900 function as RAM in accordance with a signal supplied from the arithmetic device 960.

In the semiconductor device 900, some of the plurality of memory cells 950 can function as the caches and other memory cells 950 can function as the main memory. That is, the semiconductor device 900 can have both the function of the cache and the function of the main memory. The semiconductor device 900 of one embodiment of the present invention can function as a universal memory, for example.

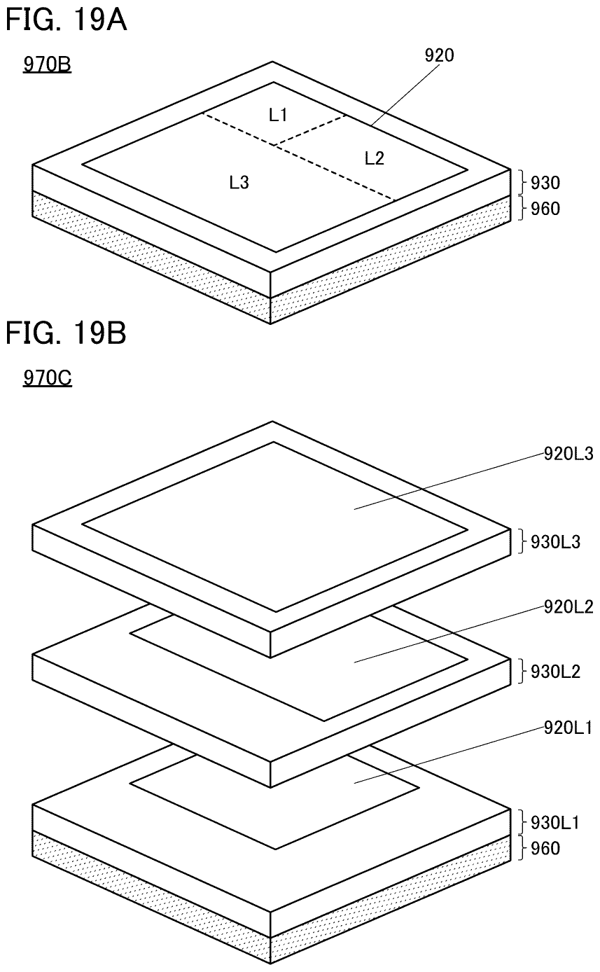

The layer 930 including one memory array 920 may be provided to overlap with the arithmetic device 960. FIG. 19A illustrates a perspective view of a semiconductor device 970B.

In the semiconductor device 970B, one memory array 920 can be divided into a plurality of areas having different functions. FIG. 19A illustrates an example in which a region L1 is used as the L1 cache, a region L2 is used as the L2 cache, and a region L3 is used as the L3 cache.

In the semiconductor device 970B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 19B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, thereby improving processing capability.

Note that this embodiment can be combined with any of the other embodiments in this specification as appropriate.

### Embodiment 3

In this embodiment, application examples of the memory device of one embodiment of the present invention is described.

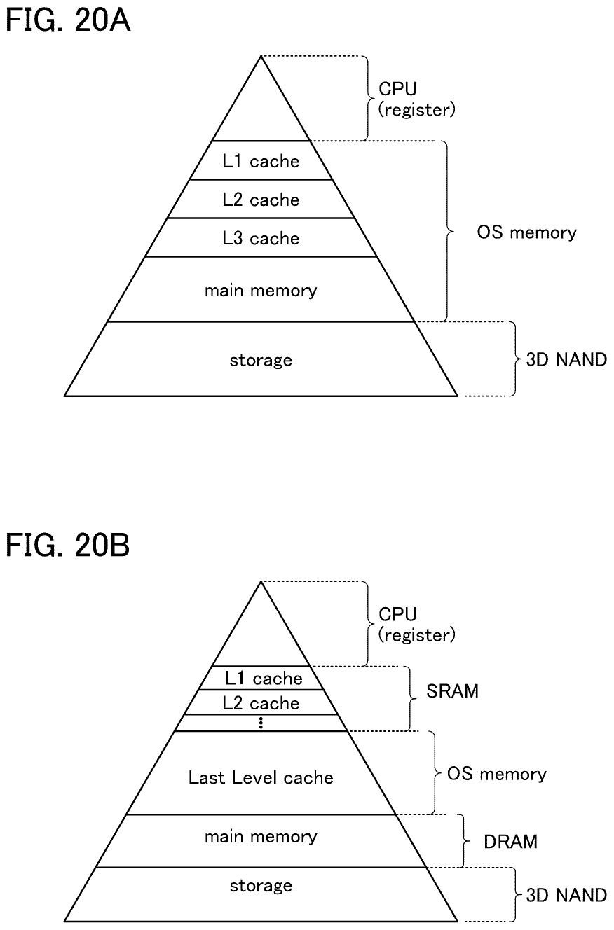

In general, a variety of memory devices are used in semiconductor devices such as computers in accordance with the intended use. FIG. 20A illustrates the hierarchy of various memory devices used in a semiconductor device. The memory devices at the upper levels require a higher operating speed, whereas the memory devices at the lower levels require a larger memory capacity and a higher memory density. FIG. 20A illustrates, for example, a memory included as a register in an arithmetic processing device such as a CPU, the L1 cache, the L2 cache, the L3 cache, the main memory, and a storage in this order from the uppermost layer. Although the caches up to the L3 cache are included in this example, a lower-level cache may further be included.

A memory included as a register in an arithmetic processing unit such as a CPU is used for temporary storage of arithmetic operation results, for example, and thus is frequently accessed by the arithmetic processing unit. Accordingly, high operation speed is required rather than memory capacity. In addition, the register also has a function of retaining settings information of the arithmetic processing unit, for example.

The cache has a function of duplicating and retaining part of data retained in a main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be retained for a long time and programs used in an arithmetic processing device, for example. Therefore, a storage needs to have high memory capacity and high memory density rather than operating speed. For example, a high-capacity nonvolatile memory device such as a 3D NAND memory device can be used.

The memory device including an oxide semiconductor (the OS memory) of one embodiment of the present invention operates at high speed and can retain data for a long time. Thus, as illustrated in FIG. 20A, the memory device of one embodiment of the present invention can be suitably used at both the level where the cache is positioned and the level where the main memory is positioned. The memory device of one embodiment of the present invention can also be used at the level where the storage is positioned.

FIG. 20B illustrates an example in which an SRAM is used as some caches and the OS memory of one embodiment of the present invention is used as the other cache.

Among the caches, the lowest-level cache can be referred to as an LLC (Last Level Cache). The LLC does not require a higher operating speed than a higher-level cache, but desirably has a large memory capacity. The OS memory of one embodiment of the present invention operates at high speed and can retain data for a long time, and thus can be suitably used as the LLC. Note that the OS memory of one embodiment of the present invention can also be used as an FLC (Final Level Cache).

For example, as illustrated in FIG. 20B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 20B.

Note that this embodiment can be combined with any of the other embodiments in this specification as appropriate.

### Embodiment 4

This embodiment describes an electronic component, an electronic appliance, a large computer, space equipment, and a data center (also referred to as a DC) that can use the semiconductor device described in the above embodiment. An electronic appliance, a large computer, space equipment, and a data center each using the semiconductor device of one embodiment of the present invention are effective in achieving high performance, e.g., reducing power consumption.

### [Electronic Appliance]

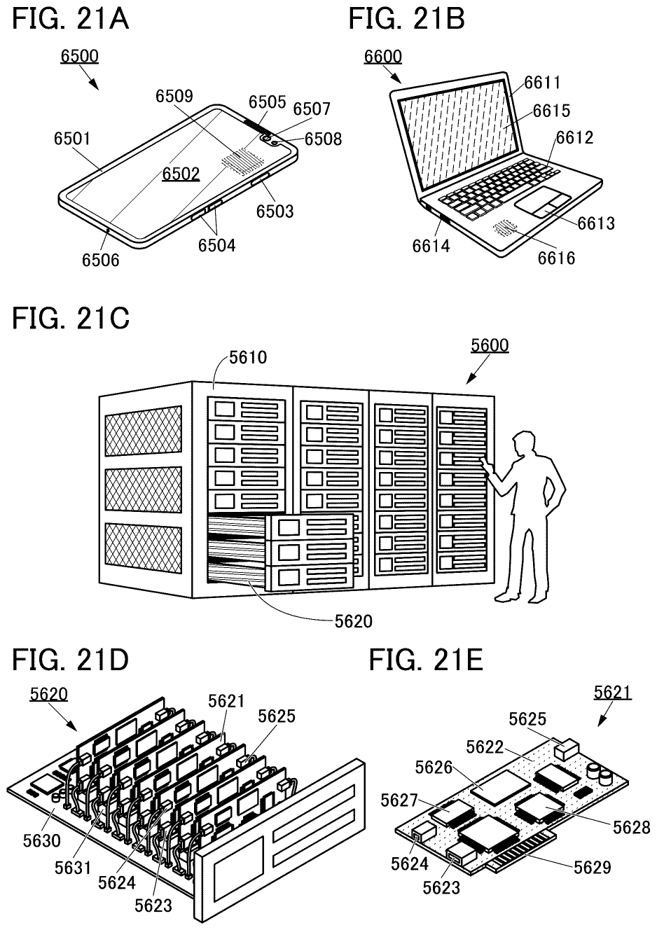

Next, FIG. 21A illustrates a perspective view of an electronic appliance 6500. An electronic appliance 6500 illustrated in FIG. 21A is a portable information terminal that can be used as a smartphone. The electronic appliance 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic appliance 6600 illustrated in FIG. 21B is an information terminal that can be used for a laptop personal computer. The electronic appliance 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

Next, FIG. 21C illustrates a perspective view of a large computer 5600. In the large computer 5600 illustrated in FIG. 21C, a plurality of rack mount computers 5620 are stored in a rack 5610. Note that the large computer 5600 may be referred to as a supercomputer.

The computer 5620 can have a structure in a perspective view illustrated in FIG. 21D, for example. In FIG. 21D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 21E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 21E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation, and thus can be suitably used in an environment where radiation can enter. For example, the OS transistor can be suitably used in outer space.

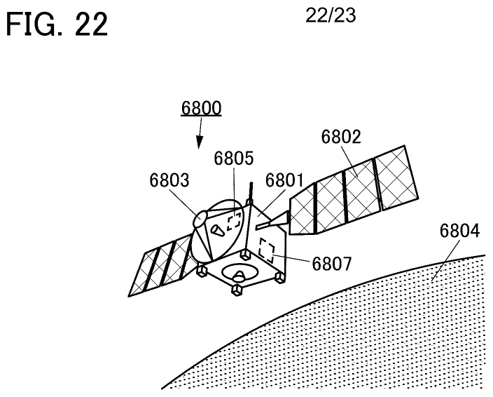

FIG. 22 illustrates an artificial satellite 6800 as an example of space equipment. The artificial satellite 6800 includes a body 6801, a solar panel 6802, an antenna 6803, a secondary battery 6805, and a control device 6807. Note that FIG. 22 illustrates a planet 6804 in outer space, for example. Note that outer space refers to, for example, space at an altitude greater than or equal to 100 km, and outer space in this specification may also include thermosphere, mesosphere, and stratosphere.

In addition, although not illustrated in FIG. 22, a battery management system (also referred to as a BMS) or a battery control circuit may be provided in the secondary battery 6805. An OS transistor is suitably used in the battery management system or the battery control circuit because low power consumption and high reliability even in outer space are achieved.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited thereto. The semiconductor device of one embodiment of the present invention can be suitably used for space equipment, such as a spacecraft, a space capsule, or a space probe, for example.

As described above, the OS transistor has excellent effects of achieving a wide memory bandwidth and being highly resistant to radiation as compared with the Si transistor.

### [Data Center]

The semiconductor device of one embodiment of the present invention can be suitably used for, for example, a storage system in a data center or the like. Long-term management of data, such as guarantee of data immutability, is required for the data center. The long-term data management needs increasing the scale of the data center, such as installing a storage and a server for storing an enormous amount of data, ensuring a stable power source for data retention, and ensuring cooling equipment required for data retention.

With the use of the semiconductor device of one embodiment of the present invention for a storage system employed in a data center, electric power required for data retention can be reduced and a semiconductor device that retains data can be downsized. Thus, downsizing of the storage system, downsizing of the power supply for retaining data, downscaling of the cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

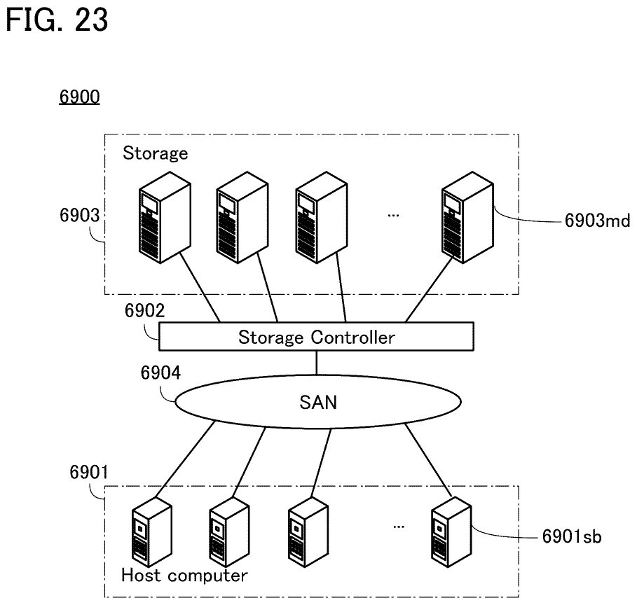

FIG. 23 illustrates a storage system that can be used for a data center. A storage system 6900 illustrated in FIG. 23 includes a plurality of servers 6901 sb as a host 6901 (indicated as “Host Computer” in the diagram). In addition, the storage system 6900 includes a plurality of memory devices 6903md as a storage 6903 (indicated as “Storage” in the diagram). In the illustrated mode, the host 6901 and the storage 6903 are connected through a storage area network 6904 (indicated as “SAN” in the diagram) and a storage control circuit 6902 (indicated as “Storage Controller” in the diagram).

The host 6901 corresponds to a computer that accesses data stored in the storage 6903. The hosts 6901 may be connected to each other through a network.

The data access speed, i.e., the time taken for storing and outputting data, of the storage 6903 is shortened by using a flash memory, but is considerably longer than the data access speed of a DRAM that can be used as a cache memory in a storage. In the storage system, in order to solve the problem of low access speed of the storage 6903, a cache memory is usually provided in the storage to shorten the time for storing and outputting data.

The cache memories are used in the storage control circuit 6902 and the storage 6903. The data transmitted between the host 6901 and the storage 6903 is stored in the cache memories in the storage control circuit 6902 and the storage 6903 and then output to the host 6901 or the storage 6903.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic appliance, a large computer, a device for space, and a data center can be expected to produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

The configurations, structures, methods, and the like described in this embodiment can be used in an appropriate combination with any of the configurations, structures, methods, and the like described in the other embodiments and the like.

### REFERENCE NUMERALS

160: impurity, 190: impurity, 200: transistor, 210: insulator, 220a: conductor, 220b: conductor, 220: conductor, 221: insulator, 222: insulator, 223: insulator, 230a: oxide semiconductor, 230b: oxide semiconductor, 230c: oxide semiconductor, 230cd: region, 230na: region, 230nb: region, 230f: oxide semiconductor film, 230: oxide semiconductor, 240a: conductor, 240b: conductor, 240f: conductive film, 240s: conductor, 240: conductor, 242: conductor, 243: conductor, 250a: insulator, 250b: insulator, 250: insulator, 260a: conductor, 260b: conductor, 260: conductor, 280a: insulator, 280b: insulator, 280c: insulator, 280: insulator, 283a: insulator, 283b: insulator, 283: insulator, 290: opening portion, 300: transistor, 900: semiconductor device, 910L1: driving circuit, 910L2: driving circuit, 910L3: driving circuit, 910: driving circuit, 911: peripheral circuit, 912: control circuit, 915: peripheral circuit, 920L1: memory array, 920L2: memory array, 920L3: memory array, 920: memory array, 923: column driver, 924: row driver, 925: input circuit, 926: output circuit, 927: sense amplifier, 928: voltage generation circuit, 930L1: layer, 930L2: layer, 930L3: layer, 930: layer, 931: PSW, 932: PSW, 940L1: connection electrode, 940L2: connection electrode, 940L3: connection electrode, 941: column decoder, 942: row decoder, 950: memory cell, 951: memory cell, 952: memory cell, 953: memory cell, 954: memory cell, 955: memory cell, 956: memory cell, 957: memory cell, 958: memory cell, 960: arithmetic device, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power button, 6504: button, 6505: speaker, 6506: microphone, 6507: camera, 6508: light source, 6509: control device, 6600: electronic appliance, 6611: housing, 6612: keyboard, 6613: pointing device, 6614: external connection port, 6615: display device, 6616: control device, 6800: artificial satellite, 6801: body, 6802: solar panel, 6803: antenna, 6804: planet, 6805: secondary battery, 6807: control device, 6900: storage system, 6901sb: server, 6901: host, 6902: storage control circuit, 6903md: memory device, 6903: storage

1. A semiconductor device comprising a transistor and an insulator,
wherein the transistor comprises a first electrode, a second electrode, an oxide semiconductor, a gate insulator, and a gate electrode,
wherein the first electrode is configured to be one of a source electrode or a drain electrode,
wherein the second electrode is configured to be the other of the source electrode and the drain electrode,
wherein the first electrode and the second electrode are provided at different levels,
wherein the insulator is provided over the first electrode,
wherein the second electrode is provided over the insulator,
wherein an opening portion reaching the first electrode is provided in the insulator and the second electrode,
wherein the oxide semiconductor is provided in contact with a top surface of the first electrode in the opening portion, a side surface of the insulator in the opening portion, and a side surface of the second electrode in the opening portion,
wherein the gate insulator is provided over the oxide semiconductor,
wherein the gate electrode is provided over the gate insulator to fill the opening portion,
wherein the oxide semiconductor comprises a first region in contact with the first electrode, a second region in contact with the insulator, and a third region in contact with the second electrode,
wherein the first region and the third region have lower resistance than the second region,
wherein the second region comprises a halogen element, and
wherein the transistor has a threshold voltage higher than 0 V.

2. The semiconductor device according to claim 1,
wherein the halogen element is one or more selected from chlorine, fluorine, bromine, and iodine.

3. The semiconductor device according to claim 1,
wherein the halogen element is chlorine or fluorine.

4. The semiconductor device according to claim 1,
wherein the first region and the third region comprise higher concentrations of one or more of hydrogen, boron, carbon, nitrogen, phosphorus, sulfur, arsenic, aluminum, magnesium, silicon, and a noble gas than the second region.

5. The semiconductor device according to claim 1,
wherein the insulator comprises silicon and oxygen.

6. A method for manufacturing a semiconductor device, the method comprising:
forming a first conductor;
forming a first insulator over the first conductor;
forming a first conductive film over the first insulator;
processing the first conductive film and the first insulator to form a second conductor and an opening portion reaching the first conductor;
forming an oxide semiconductor film in contact with a top surface of the first conductor in the opening portion, a side surface of the first insulator in the opening portion, and a side surface of the second conductor in the opening portion; and
performing treatment for supplying chlorine or fluorine to a first region of the oxide semiconductor film, the first region being in contact with the side surface of the first insulator in the opening portion.

7. The method for manufacturing a semiconductor device according to claim 6,
wherein the treatment for supplying chlorine or fluorine is performed by an ion implantation method in a state where the semiconductor device under manufacturing is inclined at an angle greater than or equal to 15° and less than or equal to 80° with one point in a substrate plane as a supporting point.

8. The method for manufacturing a semiconductor device according to claim 6, the method further comprising the step of:
performing, after the treatment for supplying chlorine or fluorine, heat treatment at higher than or equal to 250° C. and lower than or equal to 650° C.

9. The method for manufacturing a semiconductor device according to claim 6, the method further comprising the steps of:
processing the oxide semiconductor film to form an oxide semiconductor after the treatment for supplying chlorine or fluorine;
processing the second conductor to form a third conductor;
forming a second insulator over the oxide semiconductor; and
performing treatment for supplying one or more of hydrogen, boron, carbon, nitrogen, fluorine, phosphorus, sulfur, arsenic, aluminum, magnesium, silicon, and a noble gas to a second region and a third region of the oxide semiconductor, the second region being in contact with the first conductor in the opening portion, the third region being in contact with the third conductor outside the opening portion through the second insulator.

10. The semiconductor device according to claim 1,
wherein a side end portion of the oxide semiconductor is positioned inward from a side end portion of the second electrode.

11. The semiconductor device according to claim 1,
wherein the gate insulator covers a side end portion of the oxide semiconductor.

12. The method for manufacturing a semiconductor device according to claim 6, the method further comprising the step of:
processing the oxide semiconductor film to form an oxide semiconductor after the treatment for supplying chlorine or fluorine,
wherein a side end portion of the oxide semiconductor is positioned inward from a side end portion of the second conductor.

13. The method for manufacturing a semiconductor device according to claim 6, the method further comprising the step of:
processing the oxide semiconductor film to form an oxide semiconductor after the treatment for supplying chlorine or fluorine; and
forming a second insulator to cover a side end portion of the oxide semiconductor.
